(19) United States
(12) Patent Application Publication
(10) Pub. No.: US 2016/0033870 A1
(43) Pub. Date: Feb. 4, 2016

(54) PATTERN FORMATION METHOD, ELECTRONIC-DEVICE MANUFACTURING METHOD, AND ELECTRONIC DEVICE

(71) Applicant: FUJIFILM CORPORATION, Tokyo (JP)

(72) Inventors: Takashi NAKAMURA, Shizuoka (JP); Tsukasa YAMANAKA, Shizuoka (JP)

(73) Assignee: FUJIFILM CORPORATION, Tokyo (JP)

(21) Appl. No.: 14/884,345

(22) Filed: Oct. 15, 2015

Related U.S. Application Data
(63) Continuation of application No. PCT/JP2014/060631, filed on Apr. 14, 2014.

(30) Foreign Application Priority Data
Apr. 17, 2013 (JP) 2013-086755

(51) Int. Cl. G03F 7/38; G03F 7/20; G03F 7/32; G03F 7/16

(52) U.S. Cl. CPC G03F 7/38; G03F 7/16; G03F 7/2041; G03F 7/325; G03F 7/168

(57) ABSTRACT

A pattern formation method which includes a process of forming an actinic ray sensitive or radiation sensitive film by coating a substrate with an actinic ray sensitive or radiation sensitive resin composition which contains a resin where the degree of solubility with respect to a developer which includes one or more types of organic solvents decreases due to an effect of an acid, a compound which generates an acid by irradiation with actinic rays or radiation, and a solvent, a process of exposing the actinic ray sensitive or radiation sensitive film via an immersion liquid, a process of heating the actinic ray sensitive or radiation sensitive film, and a process of developing the actinic ray sensitive or radiation sensitive film using the developer which includes an organic solvent in this order, in which a process of cleaning the actinic ray sensitive or radiation sensitive film is included after the film forming process and before the exposing process and/or after the exposing process and before the heating process.

### CROSS-REFERENCE TO RELATED APPLICATIONS

This application is Continuation Application of PCT Application No. PCT/JP2014/060631, filed Apr. 14, 2014 and based upon and claiming the benefit of priority from Japanese Patent Application No. 2013-086755, filed Apr. 17, 2013, the entire contents of which are incorporated herein by reference.

### BACKGROUND OF THE INVENTION

1. Field of the Invention

The present invention relates to a pattern formation method, an electronic-device manufacturing method, and an electronic device which are favorably used for a semiconductor manufacturing process such as IC, manufacturing circuit boards such as liquid crystals and thermal heads, and other photofabrication lithography processes.

2. Description of the Related Art

In semiconductor lithography, a pattern formation method in which chemical amplification is used after applying a resist for a KrF excimer laser (248 nm) is used.

In order to refine semiconductor elements, the wavelength of the exposure light source is being shortened and the numerical aperture (high NA) of the projection lens is being increased and, currently, an exposure apparatus in which an ArF excimer laser which has a wavelength of 193 nm is a light source is being developed. As a technique for further increasing resolving power, a method (that is, a liquid immersion method) which fills a liquid with a high refractive index (also referred to below as a “immersion liquid”) between a projection lens and a sample has been proposed. In addition, EUV lithography which performs exposure with ultraviolet light with an even shorter wavelength (13.5 nm) has also been proposed.

In recent years, a pattern formation method in which a developer which includes an organic solvent (also referred to below as an “organic solvent-based developer”) is used has also been developed and, for example, JP2008-292975A, JP2008-281975A, JP2010-139996A, JP2010-164958A, JP2009-25707A, JP2011-221513A, JP2012-208431A, JP1992-39665A (JP-H4-39665A), JP2009-25723A, and JP2011-209520A disclose pattern formation methods which have a process of developing using an organic solvent-based developer with respect to a resist composition which contains a resin which includes a repeating unit which has a group which performs decomposition due to an effect of an acid and generates a polar group.

In the liquid immersion method, it is known that it is possible to aggravate defects which are caused by an immersion liquid (liquid immersion water) which remains on a resist surface according to liquid immersion exposure, that is, defects in the line width uniformity in the resist pattern and the pattern shape and development defects (also referred to below as “residual water defects”), caused by an acid of a resist exposure section being diffused in the liquid immersion water which remains on the resist film, the catalyst reaction rate of deprotection decreasing due to the acid in the exposure section, the acid which is diffused in the liquid immersion water causing a deprotection reaction in the unexposed sections, and unevenness in temperature being generated in a heating process after the exposure. With respect to this, in the related art, the influence of the residual liquid immersion water on the resist film is suppressed by forming a top coat layer on the resist layer or the liquid immersion water which remains on the resist film is reduced by improving the water repellency of the resist surface using an additive. In addition, JP2011-209520A described above discloses a technique for suppressing residual water defects at the time of liquid immersion exposure by using a specific resin as a resin where the degree of solubility with respect to an organic solvent-based developer decreases due to the effect of an acid.

### SUMMARY OF THE INVENTION

As a result of intensive research by the present inventors et al, it is understood that in a case of performing liquid immersion exposure and carrying out developing using an organic solvent-based developer, fine defects, which are not seen in a case of normal exposure which does not use an immersion liquid, are generated in specific portions in the vicinity of a wafer edge as shown in FIG. 1. The defects are visible as small dots in FIG. 1. It is assumed that the fine defects are residual water defects which are caused by minute liquid droplets of liquid immersion water remaining on the wafer after exposure due to a level difference between the wafer edge and the exposure stage, problems with the immersion hood, or the like; however, it is also clear as a result of the research by the present inventors et al that there are cases where it is not always possible to completely suppress the fine defects with the techniques in the prior art described above such as improving the water repellency of the resist surface. In addition, finer and finer defects have been detected by increases in the sensitivity of detecting apparatuses; however, such fine defects have been overlooked and not recognized as defects until now and the reality is that up to now there has not been a pattern formation method which is able to form a pattern without fine residual water defects and which carries out developing using an organic solvent-based developer.

Thus, the present invention has an object of providing a pattern formation method which is able to form a pattern without fine residual water defects which are caused by an immersion liquid which remains on a resist film after liquid immersion exposure in a case of applying liquid immersion exposure in a pattern formation method which uses an organic solvent-based developer, an electronic-device manufacturing method which includes this pattern formation method, and an electronic device.

One aspect of the present invention is as follows.

[1] A pattern formation method which includes: a process of forming an actinic ray sensitive or radiation sensitive film by coating a substrate with an actinic ray sensitive or radiation sensitive resin composition which contains a resin where the degree of solubility with respect to a developer which includes one or more types of organic solvents decreases due to an effect of an acid, a compound which generates an acid when irradiated with actinic rays or radiation, and a solvent; a process of exposing the actinic ray sensitive or radiation sensitive film via an immersion liquid; a process of heating the actinic ray sensitive or radiation sensitive film; and a process of developing the actinic ray sensitive or radiation sensitive film using the developer which includes an organic solvent in this order, in which a process of cleaning the actinic ray sensitive or radiation sensitive film is included after the film forming process and before the exposing process and/or after the exposing process and before the heating process.

[2] The pattern formation method according to [1], in which the cleaning process is included after the exposing process and before the heating process, or both after the film forming process and before the exposing process and after the exposing process and before the heating process.

[3] The pattern formation method according to [1] or [2], in which the cleaning process includes cleaning the actinic ray sensitive or radiation sensitive film using pure water.

[4] The pattern formation method according to [3], in which the cleaning process includes removing the pure water from the actinic ray sensitive or radiation sensitive film after cleaning using pure water.

[5] The pattern formation method according to [3] or [4], in which the removing the pure water is performed by inert gas blowing and/or spin drying.

[6] The pattern formation method according to any one of [1] to [5], in which the actinic ray sensitive or radiation sensitive resin composition further includes a hydrophobic resin.

[7] The pattern formation method according to any one of [1] to [6], in which a content ratio of the organic solvent in the developer is 90 mass % to 100 mass % with respect to a total amount of the developer.

[8] An electronic-device manufacturing method which includes the pattern formation method according to any one of [1] to [7].

[9] An electronic device which is manufactured by the electronic-device manufacturing method according to [8].

According to the present invention, it is possible to provide a pattern formation method in which an organic solvent-based developer is used which is able to form a pattern where fine residual water defects which are caused by an immersion liquid which remains on a resist film after liquid immersion exposure are reduced, an electronic-device manufacturing method which includes the pattern formation method, and an electronic device.

### BRIEF DESCRIPTION OF THE DRAWINGS

FIG. 1 is a diagram which shows an example of a defect map which shows positions of fine defects generated on a surface of a wafer which is obtained by performing liquid immersion exposure and heating after forming an actinic ray sensitive or radiation sensitive film and carrying out developing using an organic solvent-based developer.

FIG. 2 is a SEM photograph with a FOV of 2 μm which shows an example of a residual water bridge defect.

FIG. 3 is a SEM photograph with a FOV of 2 μm which shows another example of a residual water bridge defect.

### DESCRIPTION OF THE PREFERRED EMBODIMENTS

Detailed description will be given below of embodiments of the present invention. In the notation of the groups (atomic groups) in the present specification, notation which does not indicate whether a group is substituted or unsubstituted encompasses having a substituent as well as not having a substituent. For example, an “alkyl group” encompasses not only an alkyl group which does not have a substituent (an unsubstituted alkyl group), but also an alkyl group which has a substituent (a substituted alkyl group).

Here, the “actinic ray” or “radiation” has the meaning of, for example, the bright line spectrum of a mercury lamp, far ultraviolet rays which are represented by an excimer laser, extreme ultraviolet (EUV) rays, X-rays, soft X-rays, electron beams (EB), and the like. In addition, light in the present invention has the meaning of actinic rays or radiation.

In addition, unless otherwise stated, “exposure” here includes not only exposure using a mercury lamp, far ultraviolet rays which are represented by an excimer laser, X-rays, EUV light, and the like, but also drawing using particle beams such as electron beams and ion beams.

Firstly, description will be given of the pattern formation method according to the present invention and, subsequently, description will be given of an actinic ray sensitive or radiation sensitive resin composition which is used in the pattern formation method.

<Pattern Formation Method>

The pattern formation method according to the present invention includes film forming process of forming an actinic ray sensitive or radiation sensitive film by coating a substrate with an actinic ray sensitive or radiation sensitive resin composition, exposing process of exposing the actinic ray sensitive or radiation sensitive film via an immersion liquid, heating process of heating the actinic ray sensitive or radiation sensitive film after the exposure, and developing process of developing the actinic ray sensitive or radiation sensitive film using a developer which includes an organic solvent in this order, in which cleaning process of cleaning the actinic ray sensitive or radiation sensitive film is included after the film forming process and before the exposing process and/or after the exposing process and before the heating process after the exposing process.

The pattern formation method according to the present invention is able to form a pattern without fine residual water defects which are caused by an immersion liquid which remains on the actinic ray sensitive or radiation sensitive film in the liquid immersion exposure by including the cleaning process of cleaning the actinic ray sensitive or radiation sensitive film.

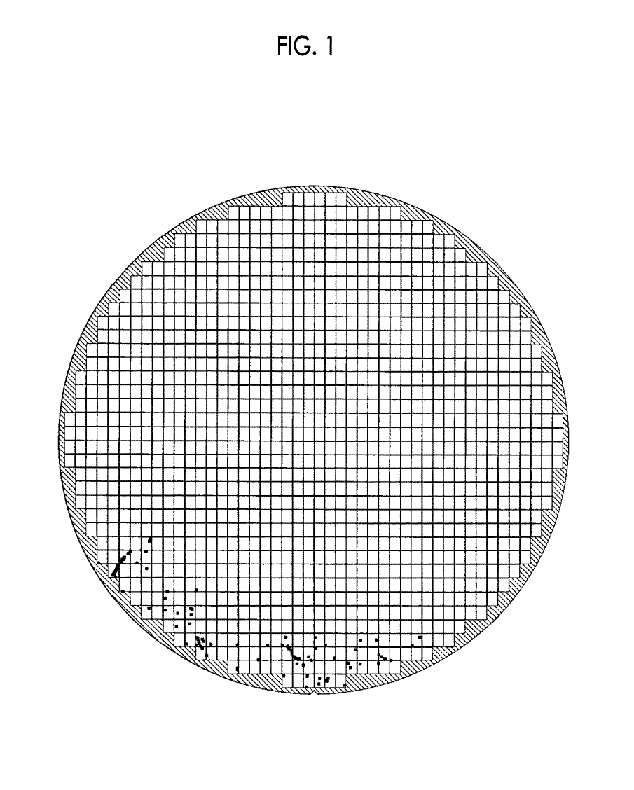

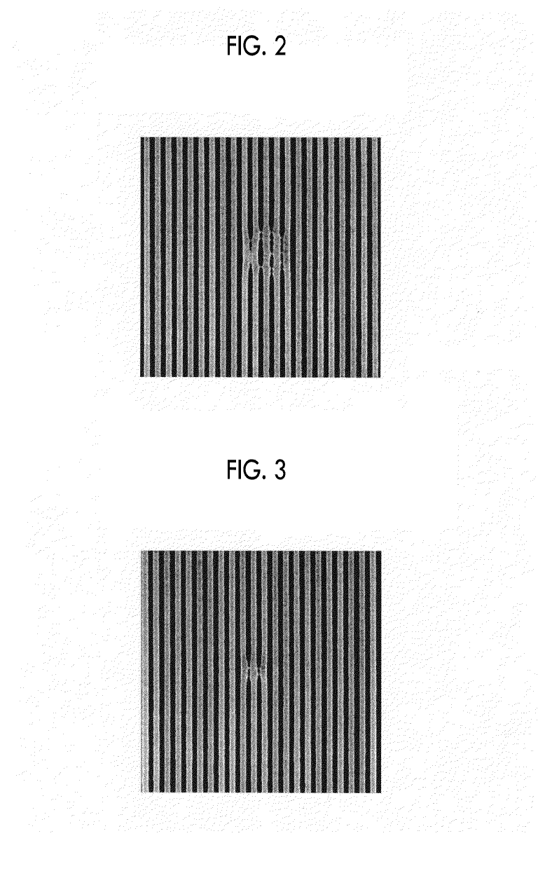

The fine residual water defects are fine defects which are seen in specific portions in the vicinity of a wafer edge as shown in FIG. 1 in a case of performing liquid immersion exposure and carrying out developing using an organic solvent-based developer, for example, fine bridge defects as shown in FIG. 2 and FIG. 3 (referred to below as “residual water bridge defects”). Until now, it was not recognized that fine residual water bridge defects are generated in specific portions in the vicinity of a wafer edge in this manner in a case of applying liquid immersion exposure in a pattern formation method which uses an organic solvent-based developer.

<Cleaning Process>

The pattern formation method according to the present invention includes the cleaning process in at least either one of after the film forming process and before the exposing process or after the exposing process and before the heating process after the exposing process (PEB; Post Exposure Bake). Below, the cleaning which is performed after the film forming process and before the exposing process is referred to as “cleaning before the exposure” and the cleaning which is performed after the exposing process and before the PEB process is referred to as “cleaning after the exposure”.

The uppermost layer of the actinic ray sensitive or radiation sensitive film is cleaned in advance by the cleaning before the exposure and, due to this, it is possible to reduce the influence of the elution of acid into an immersion liquid in a case where the immersion liquid remains on the wafer at the time of liquid immersion exposure. In addition, even when the immersion liquid remains on the wafer at the time of the liquid immersion exposure, the immersion liquid is removed by the cleaning after the exposure and it is possible to suppress generation of residual water defects.

One aspect of the pattern formation method according to the present invention preferably includes the cleaning process after the exposure and another aspect preferably includes both the cleaning process before the exposure and the cleaning process after the exposure.

In the cleaning process, it is possible to carry out the cleaning of the actinic ray sensitive or radiation sensitive film, for example, according to cleaning process (A) or (B) below using pure water.

Cleaning Process (A)

While rotating a wafer on which an actinic ray sensitive or radiation sensitive film is formed at a predetermined speed (for example, 5 rpm to 35 rpm, more preferably 7 rpm to 25 rpm), a paddle is formed by discharging a pure water rinse onto the actinic ray sensitive or radiation sensitive film at a predetermined flow rate (for example, 10 ml/second to 70 ml/second, more preferably 15 ml/second to 50 ml/second) and this state is maintained. The total time for maintaining the state where the paddle is formed from the start of the discharging is, for example, 1 second to 60 seconds, more preferably 3 seconds to 40 seconds, and even more preferably 5 seconds to 20 seconds.

Cleaning Process (B)

While rotating a wafer on which the actinic ray sensitive or radiation sensitive film is formed at a predetermined speed (for example, 50 rpm to 300 rpm, more preferably 70 rpm to 250 rpm), a pure water rinse is ejected onto the actinic ray sensitive or radiation sensitive film at a predetermined flow rate (for example, 1 ml/second to 30 ml/second, more preferably 3 ml/second to 20 ml/second, and even more preferably 5 ml/second to 20 ml/second) for a predetermined time (for example, 1 second to 60 seconds, more preferably 3 seconds to 30 seconds, and even more preferably 5 seconds to 20 seconds).

The cleaning process (A) is a cleaning method which uses a paddle and the cleaning effect thereof is greater than the cleaning process (B) which does not use a paddle; however, the usage amount of the pure water rinse is large. On the other hand, the cleaning effect of the cleaning process (B) is slightly inferior to that of the cleaning process (A) which uses a paddle; however, the usage amount of the pure water rinse is small.

The cleaning process may include removing pure water from the actinic ray sensitive or radiation sensitive film after cleaning the actinic ray sensitive or radiation sensitive film. It is possible to perform the removal of the pure water using, for example, inert gas blowing or spin drying or both.

It is possible to perform the removal of the pure water by inert gas blowing, for example, by blowing N₂ gas for a predetermined time while rotating a wafer on which pure water remains at a predetermined speed after cleaning according to the cleaning process (A) or (B) described above.

It is possible to perform the removal of the pure water by spin drying, for example, by rotating the wafer on which the pure water remains after cleaning according to the cleaning process (A) or (B) described above at a predetermined speed (for example, 2000 rpm or more, more preferably 2500 rpm or more, and even more preferably 3000 rpm or more) for a predetermined time (for example, 10 seconds or more, more preferably 12 seconds or more).

In the pattern formation method of the present invention, it is possible to use commonly known methods to perform the process of forming an actinic ray sensitive or radiation sensitive film by coating a substrate with an actinic ray sensitive or radiation sensitive resin composition, the process of exposing the actinic ray sensitive or radiation sensitive film via an immersion liquid, the PEB process of heating the actinic ray sensitive or radiation sensitive film after the exposure, and the process of developing of the actinic ray sensitive or radiation sensitive film using a developer which includes an organic solvent.

In one aspect, the pattern formation method of the present invention may include not only the PEB process as the heating process, but also a prebake (PB) process after the film forming process and before the exposing process.

In addition, the pattern formation method of the present invention may include a plurality of developing processes, and a process of developing using an organic-based developer and a process of developing using an alkali developing liquid may be combined.

In addition, in another aspect, the pattern formation method of the present invention may further include rinsing process of cleaning using a rinsing liquid after the developing process.

<Heating Process>

The heating process is preferably performed at a heating temperature of 70° C. to 130° C. in both the PB and PEB, and more preferably performed at 80° C. to 120° C.

The heating time is preferably 30 seconds to 300 seconds, more preferably 30 seconds to 180 seconds, and even more preferably 30 seconds to 90 seconds.

The heating is able to be performed by means which is provided in an ordinary coating and developing apparatus and may be performed using a hot plate or the like.

The reaction of the exposure section is promoted by the baking and the sensitivity or pattern profile is improved.

<Exposing Process>

The exposing in the present invention is performed via an immersion liquid. The light source wavelength which is used for an exposing apparatus in the present invention is not limited, but is selected from wavelengths which pass through the immersion liquid to be used and examples thereof include infrared light, visible light, ultraviolet light, far ultraviolet light, extreme ultraviolet light, X-ray, electron beams, and the like. Far ultraviolet light with a wavelength of 250 nm or less is preferable, 220 nm or less is more preferable, and 1 nm to 200 nm is particularly preferable, specific examples including a KrF excimer laser (248 nm), an ArF excimer laser (193 nm), an F₂ excimer laser (157 nm), X-rays, EUV (13 nm), electron beams, and the like, of which the ArF excimer laser is preferable.

The exposing in the present invention preferably has an ArF excimer laser with a wavelength of 193 nm as the light source and is performed via an immersion liquid.

It is possible to combine the liquid immersion exposure method with a super-resolution technique such as a phase shift method or a modified lighting method.

The immersion liquid is preferably a liquid which is transparent to exposure wavelength and has a minimum temperature coefficient of refractive index so as to minimize the distortion of an optical image projected on the film; however, in a case where the exposure light source is an ArF excimer laser (wavelength: 193 nm) in particular, it is preferable to use water from the point of ease of availability and ease of handling in addition to the points of view described above.

In a case of using water, along with reducing the surface tension of water, an additive (a liquid) which increases the surface activity may be added at a slight ratio. The additive preferably does not dissolve the resist layer on the wafer and has a negligible influence with respect to the optical coating on the lower surface of a lens element.

Preferable examples of the additive include aliphatic alcohol which has a refractive index which is substantially equal to water and specific examples thereof include methyl alcohol, ethyl alcohol, isopropyl alcohol, and the like. By adding alcohol which has a refractive index which is substantially equal to water, even when the alcohol component in the water evaporates and the content concentration changes, it is possible to obtain an advantage of being able to make the refractive index change throughout the entirety of the liquid extremely small.

On the other hand, in a case where substances which are opaque with respect to 193 nm light or impurities of which the refractive index is greatly different from water are mixed, since this leads to distortion of an optical image which is projected on a resist, distilled water is preferable as the water to be used. Furthermore, pure water which is filtered through an ion exchange filter or the like may also be used.

The electrical resistance of water which is used as the immersion liquid is desirably 18.3 MQcm or more, the organic matter concentration (Total Organic Carbon: TOC) is desirably 20 ppb or less, and a degassing process is desirably carried out thereon.

In addition, by increasing the refractive index of the immersion liquid, it is possible to improve the lithography performance. From this viewpoint, an additive to improve the refractive index may be added to water or heavy water (D₂O) may be used instead of water.

The receding contact angle of a resist film which is formed using the actinic ray sensitive or radiation sensitive resin composition in the present invention is 70° or more at a temperature of 23±3° C. and a humidity of 45±5%, which is favorable in a case of carrying out the exposing via a liquid immersion medium, preferably 75° or more, and more preferably 75° to 85°.

When the receding contact angle is excessively small, it is not possible to favorably use the resist film in a case of exposing via the liquid immersion medium and it is not possible to sufficiently exhibit an effect of reducing residual water (water mark) defects. In order to realize a preferable receding contact angle, the hydrophobic resin (HR) is preferably included in the actinic ray sensitive or radiation sensitive resin composition. Alternatively, the receding contact angle may be improved by forming a coating layer (a so-called “top coat”) on the resist film using a hydrophobic resin composition.

In the liquid immersion exposing process, since it is necessary for the immersion liquid to move on the wafer following the movement of an exposing head scanning on the wafer at high speed and forming an exposing pattern, the contact angle of the immersion liquid with respect to the resist film in a dynamic state is important and a performance which follows a high speed scan of the exposing head without liquid droplets remaining is required for the resist.

<Film forming Process>

The substrate on which a film is formed in the present invention is not particularly limited and it is possible to use substrates which are generally used in semiconductor manufacturing such as IC, in manufacturing circuit boards such as liquid crystal or thermal heads, and in other photofabrication lithography, such as inorganic substrates of silicon, SiN, SiO₂, or TiN, or coated inorganic substrates of SOG or the like. Furthermore, as necessary, an antireflection film may be formed between the resist film and the substrate. It is possible to appropriately use organic and inorganic antireflection films known in the art as antireflection films.

<Developing Process>

The developing in the pattern formation method of the present invention is performed using a developer which includes an organic solvent (also referred to below as an “organic-based developer”). Due to this, a negative type pattern is formed.

It is possible to use polar solvents and hydrocarbon-based solvents such as ketone-based solvents, ester-based solvents, alcohol-based solvents, amide-based solvents, and ether-based solvents as the organic-based developer.

Examples of the ketone-based solvents include 1-octanone, 2-octanone, 1-nonanone, 2-nonanone, acetone, 2-heptanone (methylamyl ketone), 4-heptanone, 1-hexanone, 2-hexanone, diisobutyl ketone, cyclohexanone, methylcyclohexanone, phenylacetone, methylethyl ketone, methylisobutyl ketone, acetylacetone, acetonylacetone, ionone, diacetonyl alcohol, acetylcarbinol, acetophenone, methylnaphthyl ketone, isophorone, propylene carbonate, and the like.

Examples of the ester-based solvents include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and the like.

Examples of the alcohol-based solvents include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol, and the like.

As the ether-based solvents, it is possible to use, for example, dioxane, tetrahydrofuran, and the like other than the glycol ether-based solvents described above.

Examples of the amide-based solvents include N-methyl-2-pyrrolidone, N,N-dimethyl acetamide, N,N-dimethyl formamide, hexamethylphosphoric triamide, 1,3-dimethyl-2-imidazolidinone, and the like.

Examples of the hydrocarbon-based solvents include aromatic hydrocarbon-based solvents such as toluene and xylene and aliphatic hydrocarbon-based solvents such as pentane, hexane, octane, and decane.

In particular, the organic-based developer is preferably a developer which includes at least one type of an organic solvent selected from a group formed of ketone-based solvents and ester-based solvents, and is particularly preferably a developer which includes butyl acetate as an ester-based solvent and methylamyl ketone (2-heptanone) as a ketone-based solvent.

A plurality of solvents may be mixed or the solvents may be used by mixing with solvents other than the solvents described above or water. However, in order to sufficiently exhibit the effects of the present invention, the moisture content for the entirety of the developer is preferably less than 10 mass % and water is more preferably substantially not contained.

That is, the usage amount of the organic solvent with respect to the organic-based developer is preferably 90 mass % to 100 mass % with respect to the total amount of the developer and more preferably 95 mass % to 100 mass %.

The vapor pressure of the organic-based developer at 20° C. is preferably 5 kPa or less, more preferably 3 kPa or less, and particularly preferably 2 kPa or less. By setting the vapor pressure of the organic-based developer to 5 kPa or less, the evaporation of the developer on the substrate or in a developing cup is suppressed, the temperature uniformity in the wafer surface is improved, and as a result, the uniformity of the dimensions in the wafer surface is improved.

It is possible to add an appropriate amount of a surfactant to the organic-based developer as necessary. The surfactant is not particularly limited; however, it is possible to use, for example, ionic or non-ionic fluorine-based and/or silicon-based surfactants or the like. Examples of the fluorine-based and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A and non-ionic surfactants are preferable. The non-ionic surfactant is not particularly limited; however, it is more preferable to use a fluorine-based surfactant or a silicon-based surfactant.

The usage amount of the surfactant is normally 0.001 mass % to 5 mass % with respect to the total amount of the developer, preferably 0.005 mass % to 2 mass %, and more preferably 0.01 mass % to 0.5 mass %.

As the developing method, it is possible to apply, for example, a method for dipping a substrate in a tank which is filled with a developer for a certain time (a dipping method), a method for carrying out developing by raising the developer onto the substrate surface using surface tension and leaving the substrate to stand for a certain time (a paddle method), a method for spraying the developer onto the substrate surface (a spraying method), a method for carrying on the discharging of the developer onto a substrate which is rotating at a certain speed while scanning a developer discharging nozzle at a certain speed (a dynamic dispensing method), and the like.

In a case where the various types of the developing methods described above include ejecting process of ejecting the developer from the developing nozzle of the developing apparatus toward the resist film, the ejection pressure of the ejected developer (the flow rate of the ejected developer per unit area) is, as an example, preferably 2 mL/sec/mm² or less, more preferably 1.5 mL/sec/mm² or less, and even more preferably 1 mL/sec/mm² or less. There is no particular lower limit on the flow rate; however, when considering throughput, 0.2 mL/sec/mm² or more is preferable. In particular, paragraph [0022] to paragraph [0029] in JP2010-232550A and the like disclose the details thereof.

In addition, after a process of developing using a developer which includes an organic solvent, the developing may be stopped while the solvent is replaced with another solvent.

In addition, in a case where the pattern formation method of the present invention includes a plurality of developing processes, a process of developing using an alkali developing liquid and a process of developing using an organic-based developer may be combined. Due to this, it is possible to expect to obtain a pattern with ½ of the spatial frequency of an optical image as illustrated in FIG. 1 to FIG. 11 and the like in U.S. Pat. No. 8,227,183B.

In a case where the pattern formation method of the present invention includes a process of developing using an alkali developing liquid, the usable alkali developing liquids are not particularly limited; however, generally, an aqueous solution of 2.38 mass % of tetramethyl ammonium hydroxide is desirable. In addition, it is also possible to use a solution by adding an appropriate amount of alcohols and a surfactant to an aqueous alkali solution.

The alkali concentration of the alkali developing liquid is normally 0.1 mass % to 20 mass %.

The pH of the alkali developing liquid is normally 10.0 to 15.0. Pure water is used as the rinsing liquid in the rinsing process which is performed after the alkali developing and it is also possible to use a liquid by adding an appropriate amount of a surfactant.

<Rinsing Process>

It is preferable to include a rinsing process of cleaning using a rinsing liquid after the process of developing using the organic-based developer. The rinsing liquid is not particularly limited as long as the liquid does not dissolve the resist pattern and it is possible to use a solution which includes a general organic solvent. As the rinsing liquid, it is preferable to use a rinsing liquid which contains at least one type of an organic solvent selected from a group formed of a hydrocarbon-based solvent, a ketone-based solvent, an ester-based solvent, an alcohol-based solvent, and an amide-based solvent, and an ether-based solvent.

Specific examples of the hydrocarbon-based solvent, the ketone-based solvent, the ester-based solvent, the alcohol-based solvent, and the amide-based solvent, and the ether-based solvent include the same solvents as described in the developer which includes an organic solvent.

In one aspect of the present invention, after the developing process, a process of cleaning using a rinsing liquid which contains at least one type of an organic solvent selected from a group formed of a ketone-based solvent, an ester-based solvent, an alcohol-based solvent, and an amide-based solvent is performed, a process of cleaning using a rinsing liquid which contains an alcohol-based solvent or an ester-based solvent is more preferably performed, a process of cleaning using a rinsing liquid which contains a monovalent alcohol is particularly preferably performed, and a process of cleaning using a rinsing liquid which contains a monovalent alcohol with 5 or more carbon atoms is most preferably performed.

Here, examples of the monovalent alcohol which is used in the rinsing process include straight-chain, branched, and cyclic monovalent alcohols and specifically, it is possible to use 1-hexanol, 2-hexanol, 4-methyl-2-pentanol, 1-pentanol, 3-methyl-1-butanol, and the like.

A plurality of each of the components may be mixed or each of the components may be used by mixing with organic solvents other than ones described above.

The moisture content in the rinsing liquid is preferably 10 mass % or less, more preferably 5 mass % or less, and particularly preferably 3 mass % or less. By setting the moisture content to 10 mass % or less, it is possible to obtain favorable developing characteristics.

The vapor pressure of the rinsing liquid which is used after the process of developing using the developer which includes an organic solvent is preferably 0.05 kPa to 5 kPa at 20° C., more preferably 0.1 kPa to 5 kPa, and most preferably 0.12 kPa to 3 kPa. By setting the vapor pressure of the rinsing liquid to 0.05 kPa to 5 kPa, the temperature uniformity in the wafer surface is improved and, moreover, swelling which is caused by permeation of the rinsing liquid is suppressed and the uniformity of the dimensions in the wafer surface is improved.

It is also possible to use the rinsing liquid by adding an appropriate amount of a surfactant thereto.

In the rinsing process, cleaning is carried out on the wafer, on which the developing which uses the developer which includes an organic solvent was performed, using the rinsing liquid which includes the organic solvent. The cleaning method is not particularly limited; however, for example, it is possible to apply a method of continuously discharging the rinsing liquid onto a substrate which is rotating at a certain speed (a rotary coating method), a method of dipping the substrate in a tank which is filled with the rinsing liquid for a certain time (a dipping method), a method of spraying the rinsing liquid onto the substrate surface (a spraying method), and the like, and it is preferable to perform the cleaning using the rotary coating method among the above, to rotate the substrate at a rotation speed of 2000 rpm to 4000 rpm after the cleaning, and to remove the rinsing liquid from the substrate. In addition, it is also preferable to include heating process (Post Bake) after the rinsing process. The developer and rinsing liquid which remain between the patterns and in the pattern due to the baking are removed. The heating after the rinsing is normally performed at 40° C. to 160° C., preferably at 70° C. to 95° C., normally for 10 seconds to 3 minutes, and preferably for 30 seconds to 90 seconds.

The organic-based developer, the alkali developing liquid, and/or the rinsing liquid which are used in the present invention preferably have few impurities such as various types of fine particles, metal elements, and the like. In order to obtain a liquid medicine with few impurities, it is preferable that the liquid medicine is produced in a clean room and additionally, that impurity reduction is performed by performing filtration using various types of filters such as Teflon (registered trademark) filters, polyolefin-based filters, and ion exchange filters, and the like. With regard to metal elements, the metal element concentration of Na, K, Ca, Fe, Cu, Mg, Mn, Li, Al, Cr, Ni, and Zn is preferably each 10 ppm or less, and more preferably 5 ppm or less.

In addition, the storage container for the developer or the rinsing liquid is not particularly limited and it is possible to appropriately use a container of a polyethylene resin, polypropylene resin, polyethylene-polypropylene resin, and the like which is used for purposes involving electronic materials; however, it is also preferable to select a container in which few components elute from an inner wall of the container to the liquid medicine in order to reduce impurities which elute from the container. Examples of such containers include a container of which the inner wall is a perfluoro resin (for example, a Fluoro Pure PFA Compound Drum manufactured by Entegris Corp. (wetted inner surface; PFA resin lining) and a drum can made of steel manufactured by JFE Corp. (wetted inner surface; tribasic zinc phosphate film)) and the like.

The present invention also relates to an electronic-device manufacturing method which includes the pattern formation method of the present invention described above and to an electronic device which is manufactured by this manufacturing method. The electronic device of the present invention is favorably mounted on electrical and electronic devices (household electrical appliances, OA and media-related devices, optical apparatuses and instruments, telecommunication devices, and the like).

In addition, a pattern which is obtained by the pattern formation method of the present invention is generally favorably used as an etching mask or the like of a semiconductor device, but the pattern is also used for other purposes. Examples of the other purposes include a use for guide pattern forming in a Directed Self-Assembly (DSA) (for example, refer to ACS Nano Vol. 4 No. 8 Page 4815-4823), that is, as a core of a spacer process (for example, refer to JP1991-270227A (JP-H3-270227A), JP2013-164509A, and the like) and the like.

<Actinic Ray Sensitive or Radiation Sensitive Resin Composition>

A actinic ray sensitive or radiation sensitive resin composition which is used in the pattern formation method according to the present invention (also referred to below as a “composition of the present invention”) contains a resin where the degree of solubility with respect to a developer which includes one or more types of organic solvents decreases due to the effect of an acid, a compound which generates an acid when irradiated with actinic rays or radiation, and a solvent as essential components.

[1] Resin where the degree of solubility with respect to a developer which includes one or more types of organic solvents decreases due to the effect of an acid

Examples of resins where the degree of solubility with respect to a developer which includes one or more types of organic solvents decreases due to the effect of an acid include a resin (also referred to below as an “acid decomposable resin” or “resin (A)”) which has a group (also referred to below as an “acid-decomposable group”) which decomposes due to the effect of an acid and generates a polar group in a main chain or side chain of the resin or in both the main chain and side chain.

The acid-decomposable group preferably has a structure which is protected by a group which decomposes and desorbs a polar group due to the effect of an acid. Examples of preferable polar groups include carboxyl groups, phenolic hydroxyl groups, fluorinated alcohol groups (preferably, hexafluoroisopropanol groups), and sulfonic acid groups.

A group which is preferable as an acid-decomposable group is a group where hydrogen atoms of the groups are substituted with groups which are desorbed by an acid.

Examples of the groups which are desorbed by an acid include —C(R₃₆)(R₃₇)(R₃₈), —C(R₃₆)(R₃₇)(OR₃₉), —C(R₀₁)(R₀₂)(OR₃₉), and the like.

In the formula, R₃₆ to R₃₉ each independently represent an alkyl group, a cycloalkyl group, an aryl group, an aralkyl group, or an alkenyl group. R₃₆ and R₃₇ may form a ring by bonding with each other.

R₀₁ and R₀₂ each independently represent a hydrogen atom, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, and the like. The tertiary alkyl ester group is more preferable. In addition, in a case of performing the pattern formation method of the present invention by exposure using KrF light or EUV light or by electron beam irradiation, an acid-decomposable group where a phenolic hydroxyl group is protected by an acid desorbed group may be used.

The resin (A) preferably has a repeating unit which has an acid-decomposable group.

Examples of the repeating unit include the following.

In specific examples, Rx represents a hydrogen atom, CH₃, CF₃, or CH₂OH. Rxa and Rxb each represent an alkyl group with 1 to 4 carbon atoms. Xa₁ represents a hydrogen atom, CH₃, CF₃, or CH₂OH. Z represents a substituent and a plurality of Zs may be the same as or different from each other in a case where a plurality of Zs are present. p represents 0 or a positive integer. Specific examples and preferable examples of Z are the same as the specific examples and preferable examples of the substituent which each group such as Rx₁ to Rx₃ may have.

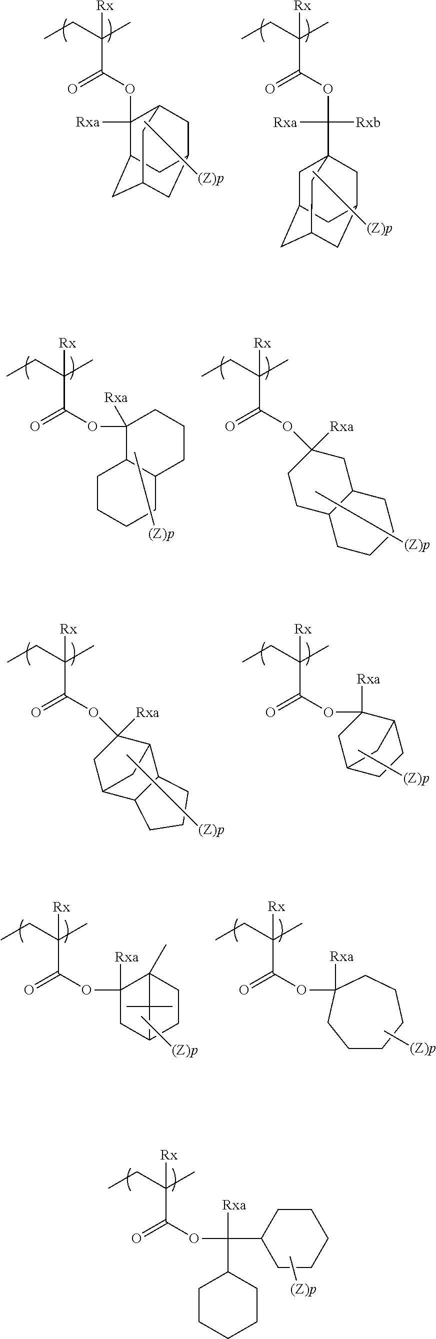

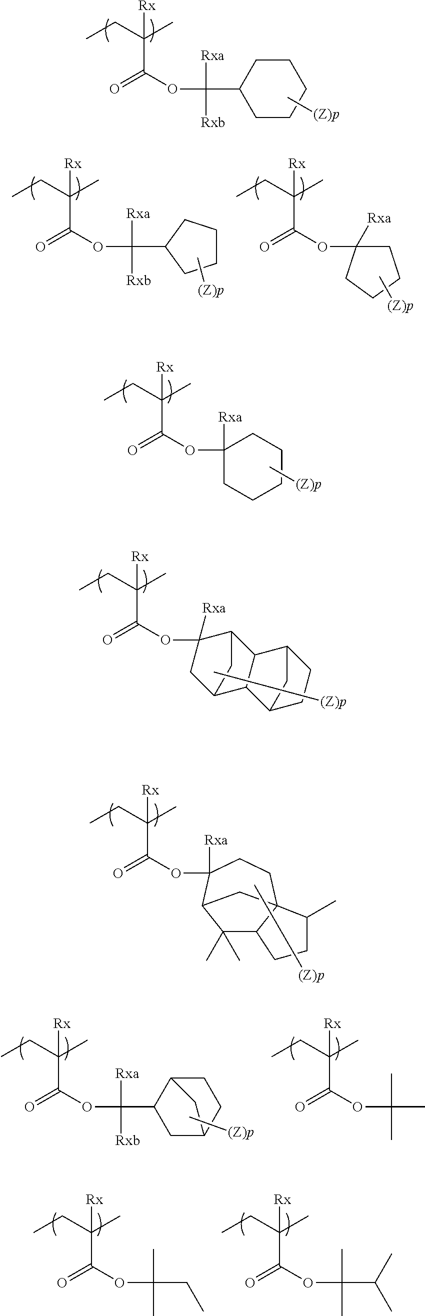

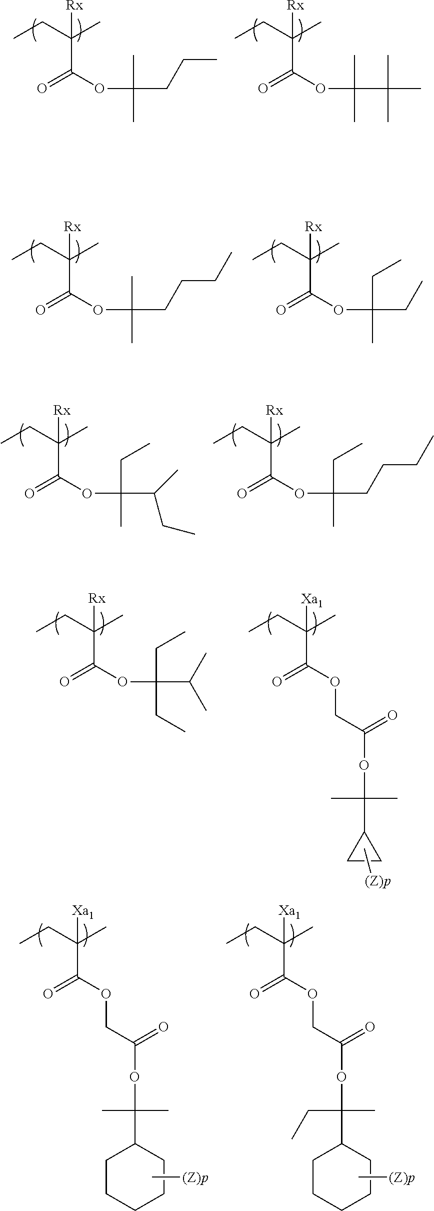

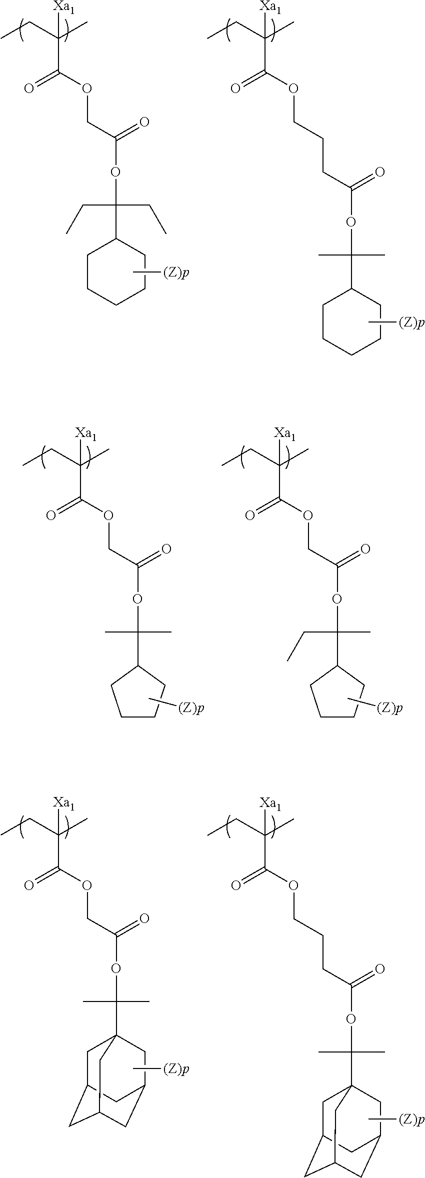

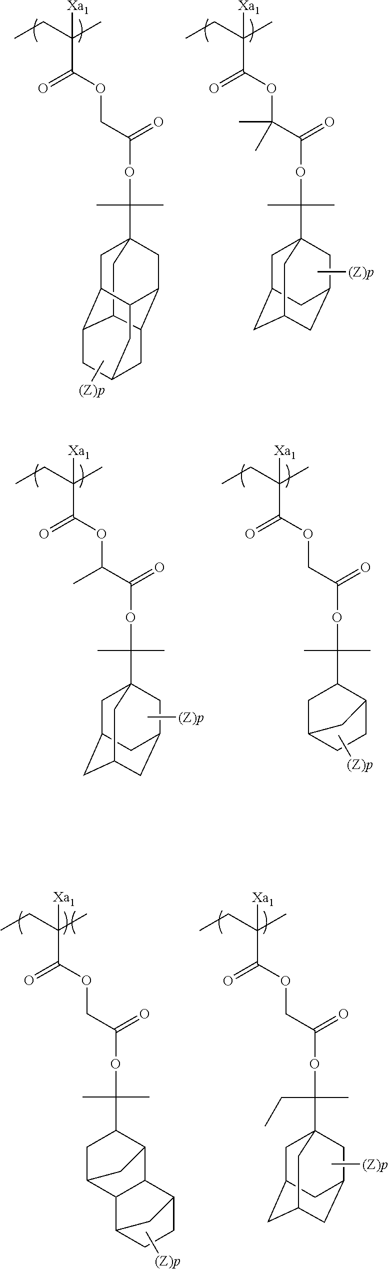

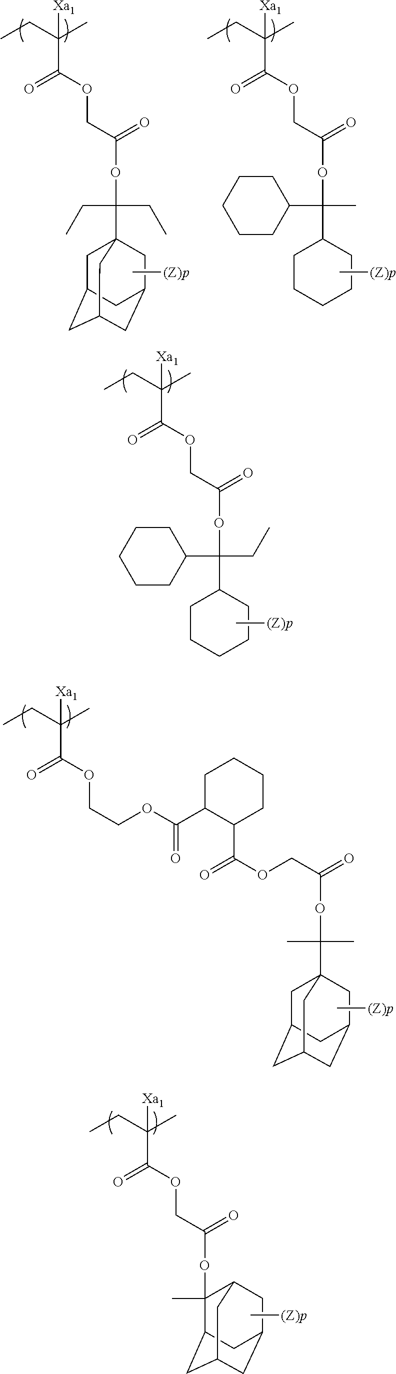

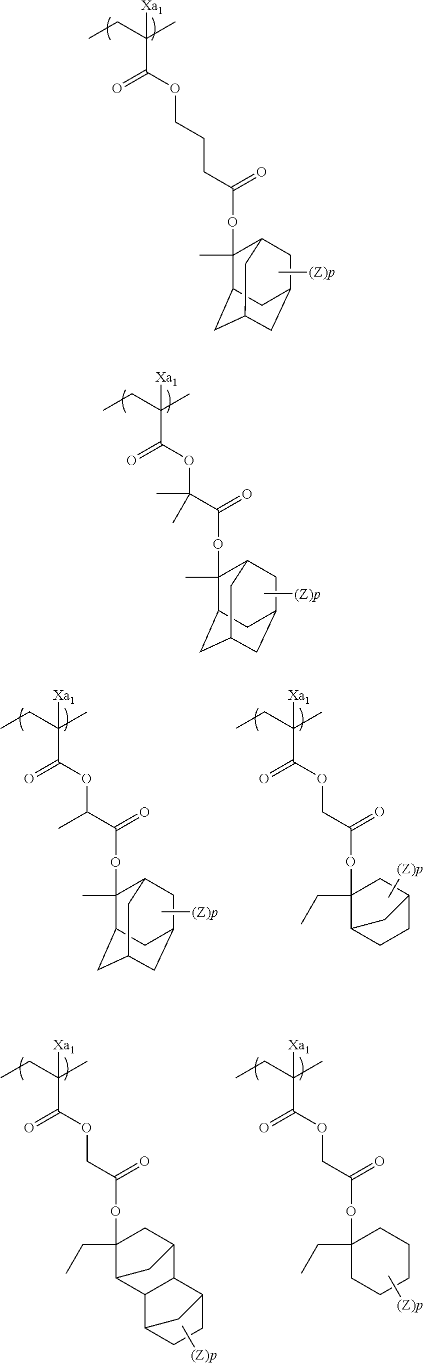

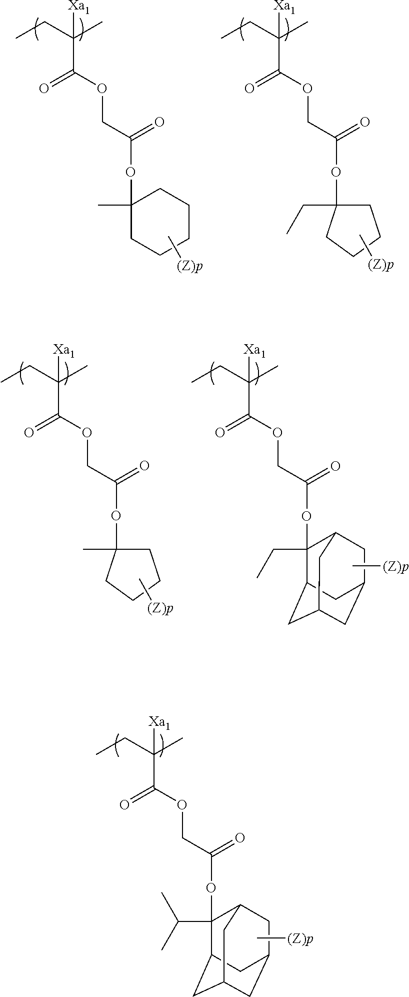

In the specific examples described below, Xa represents a hydrogen atom, an alkyl group, a cyano group, or a halogen atom.

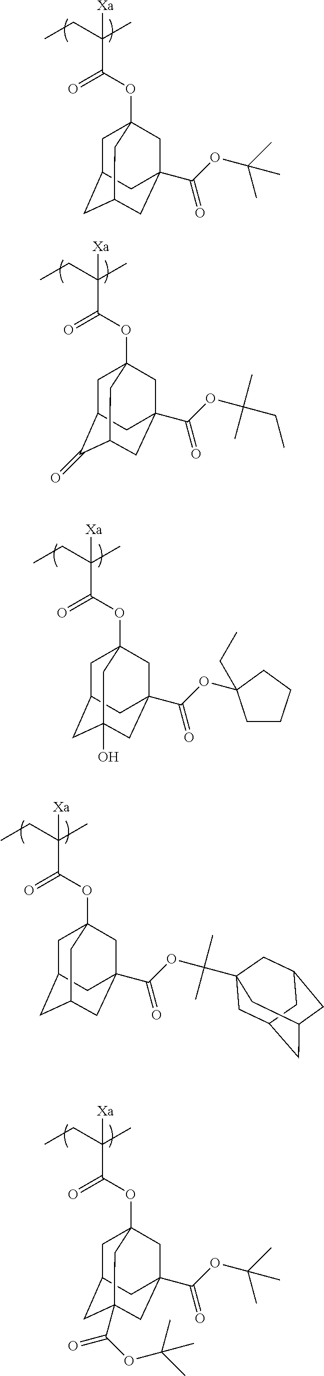

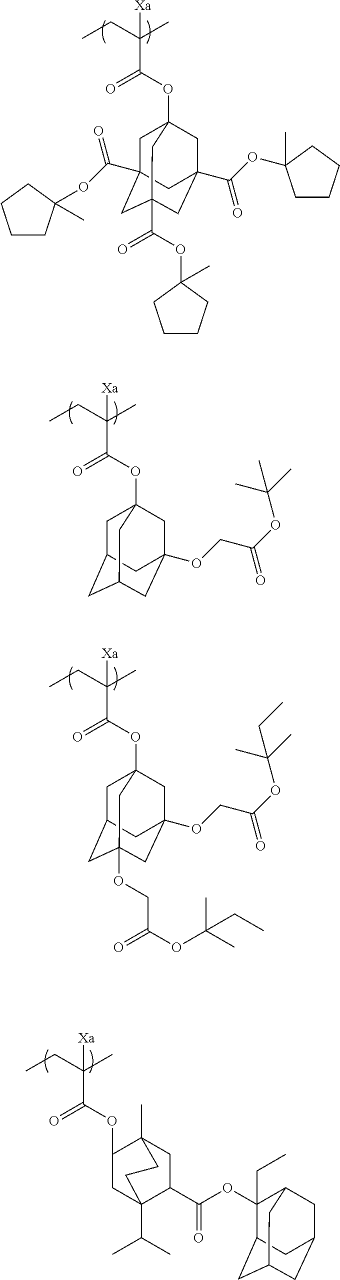

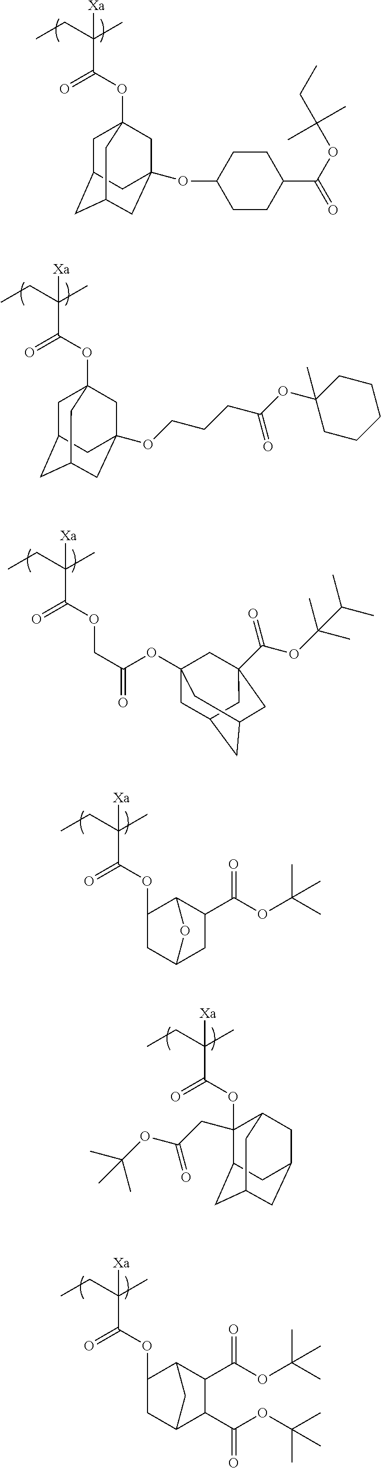

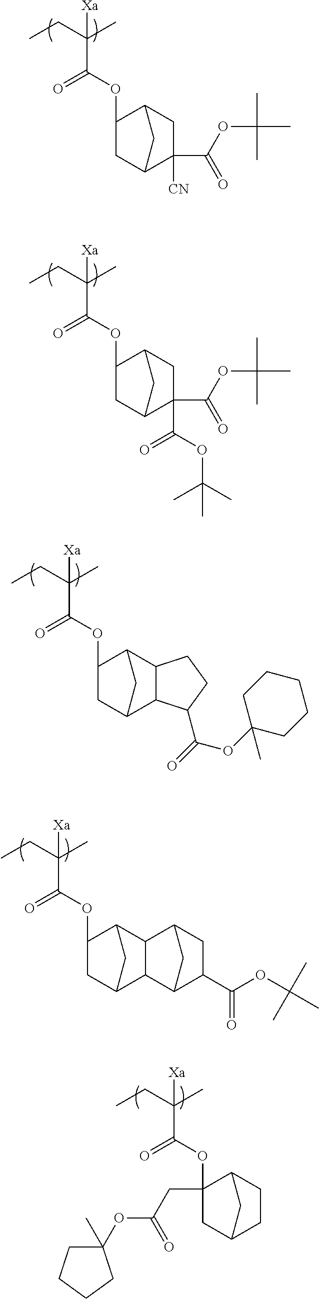

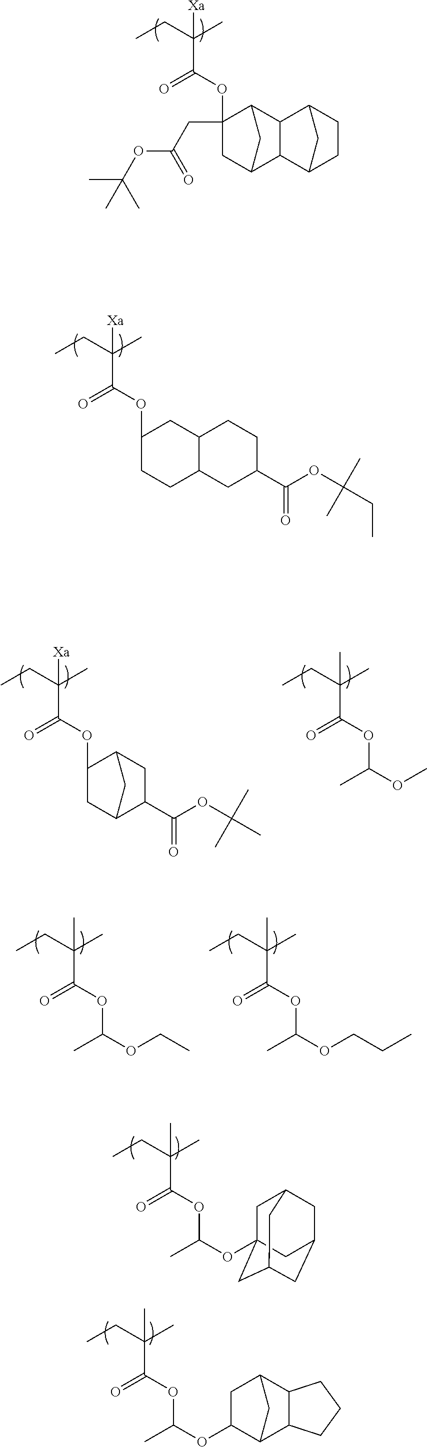

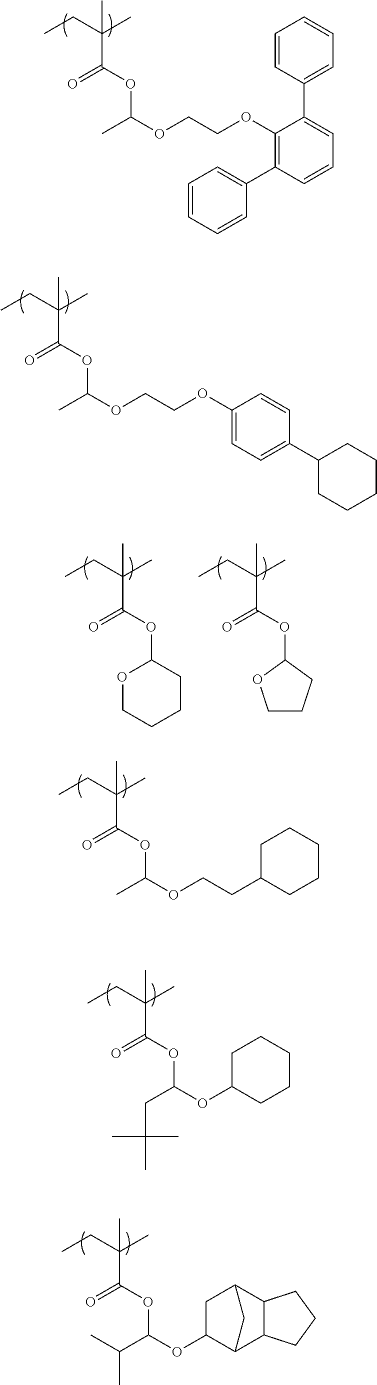

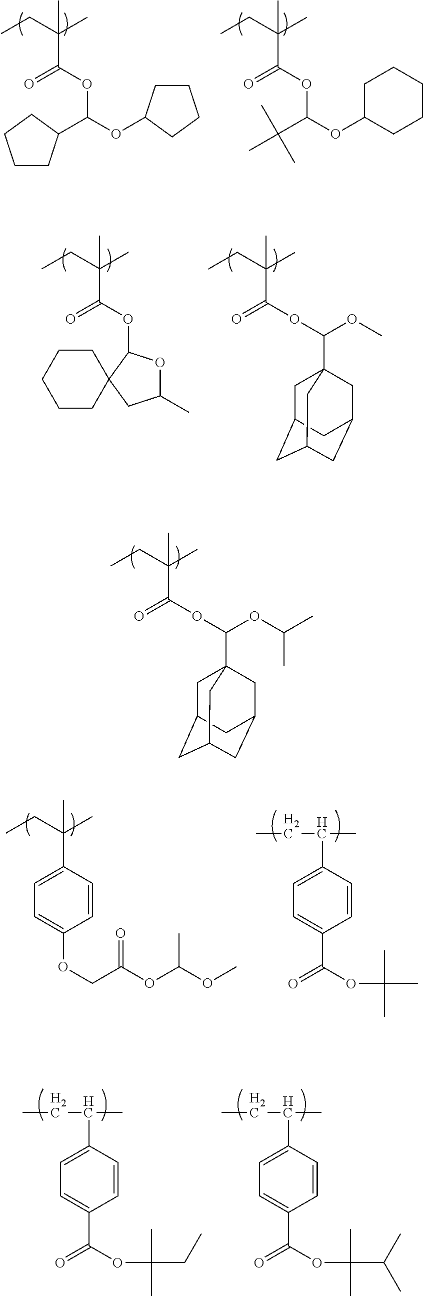

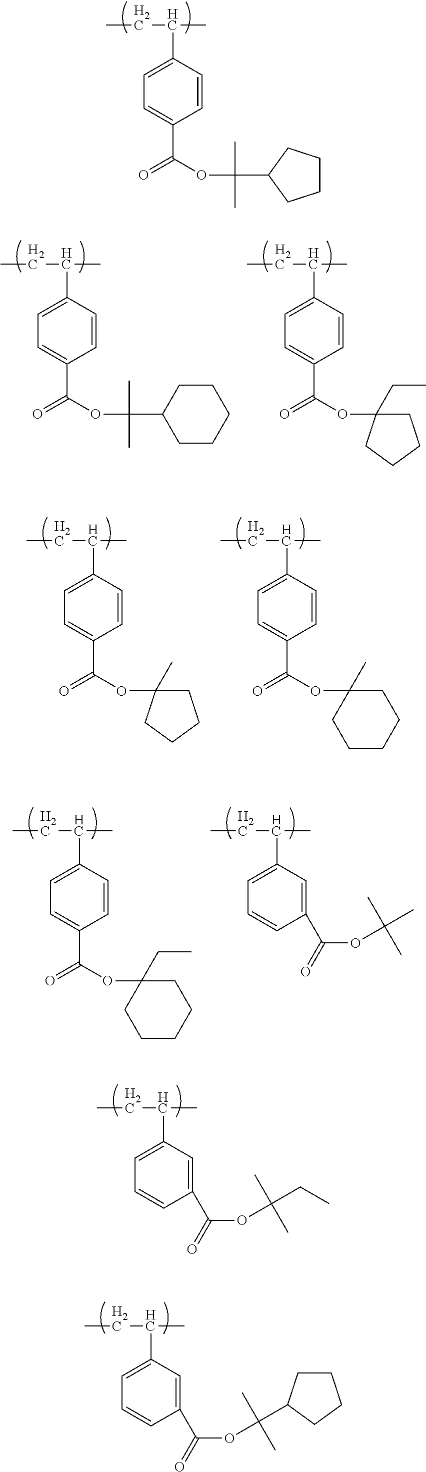

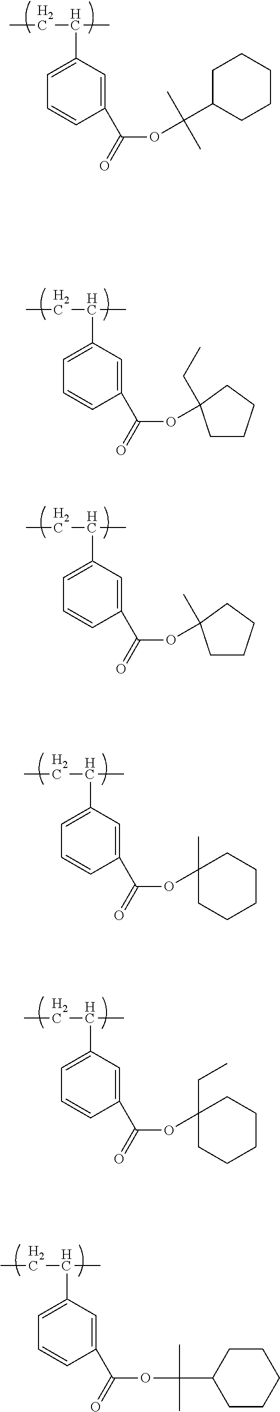

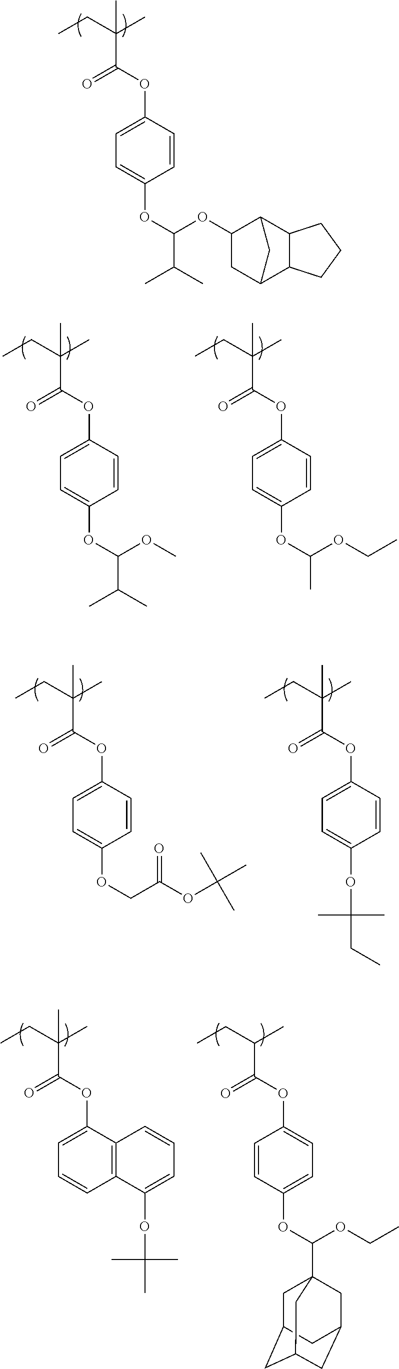

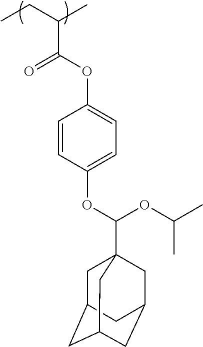

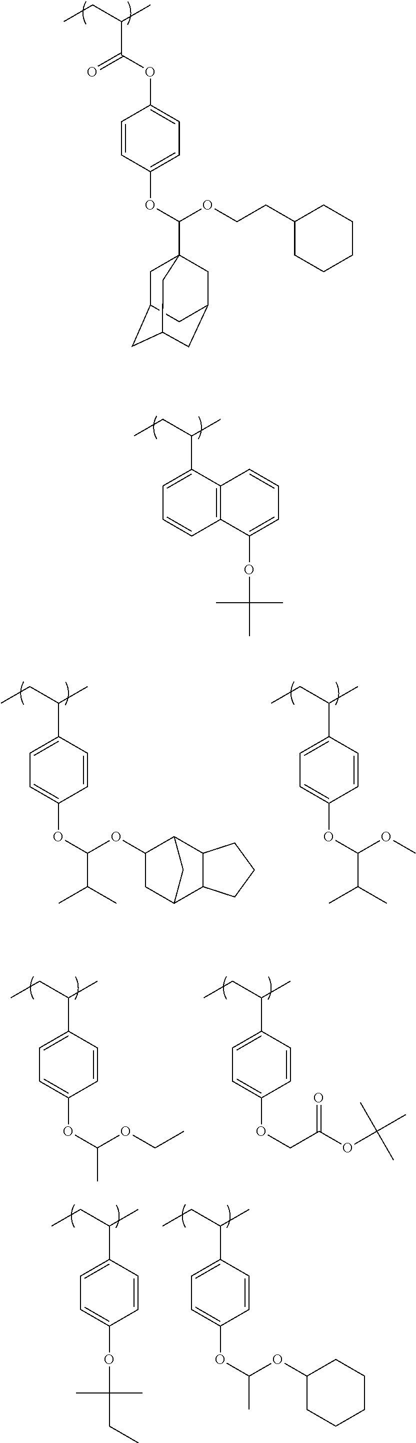

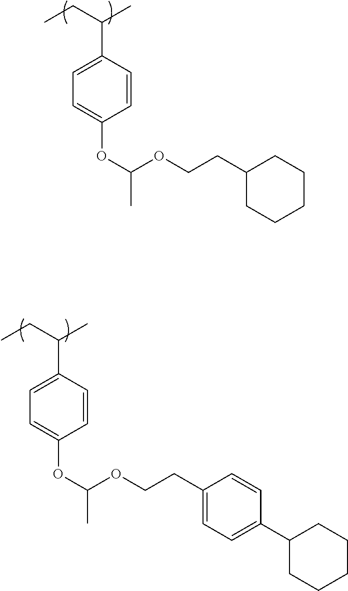

In the specific examples described below, Xa₁ represents a hydrogen atom, CH₃, CF₃, or CH₂OH.

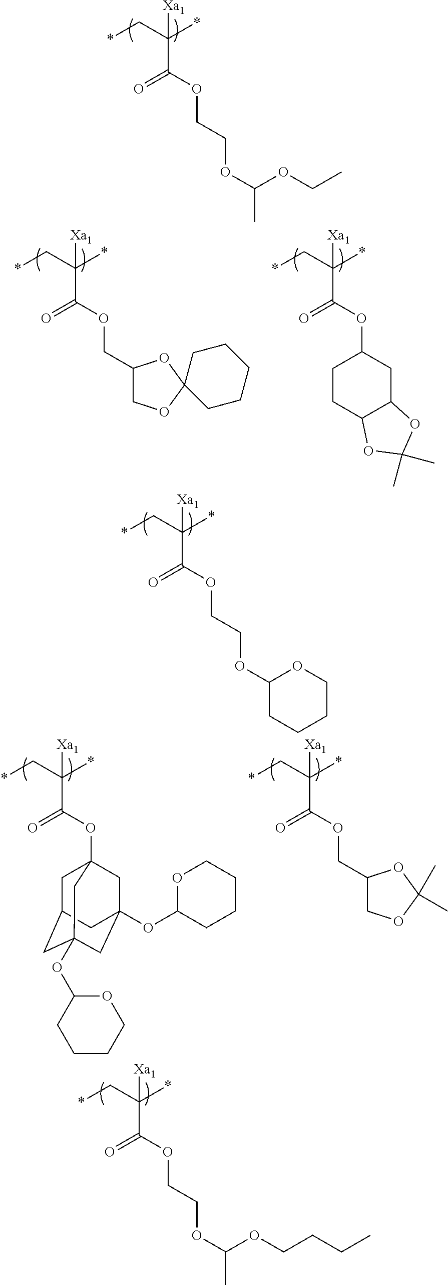

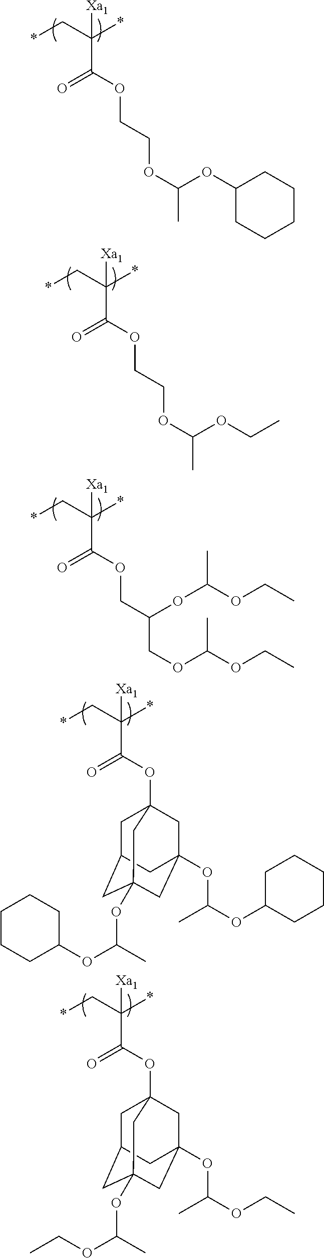

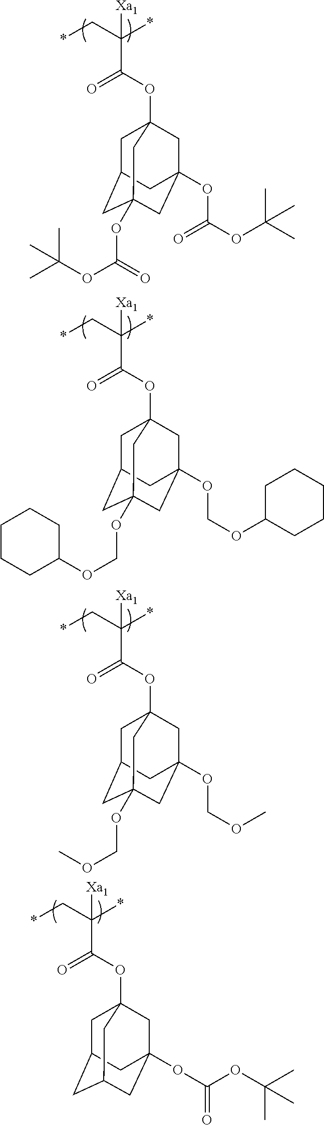

The repeating unit which has an acid-decomposable group may be one type or two or more types may be used together. In a case of using two types, the combination is not particularly limited; however, preferable examples include the combinations below.

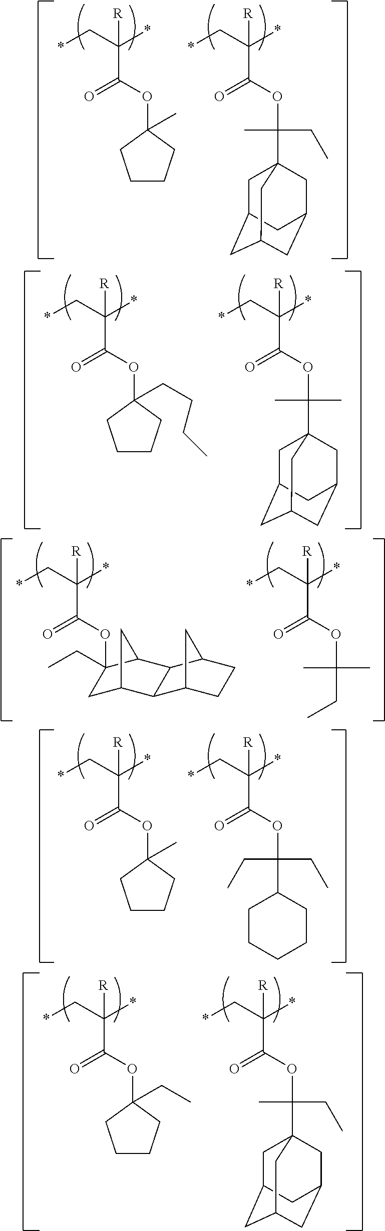

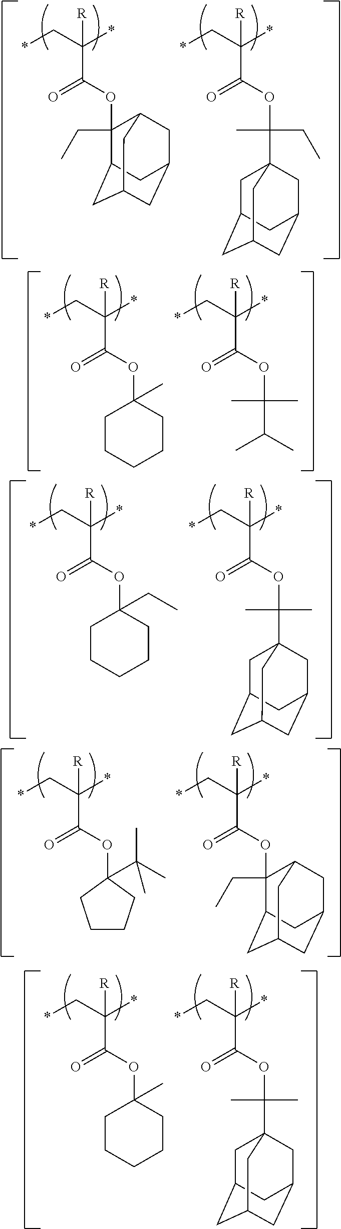

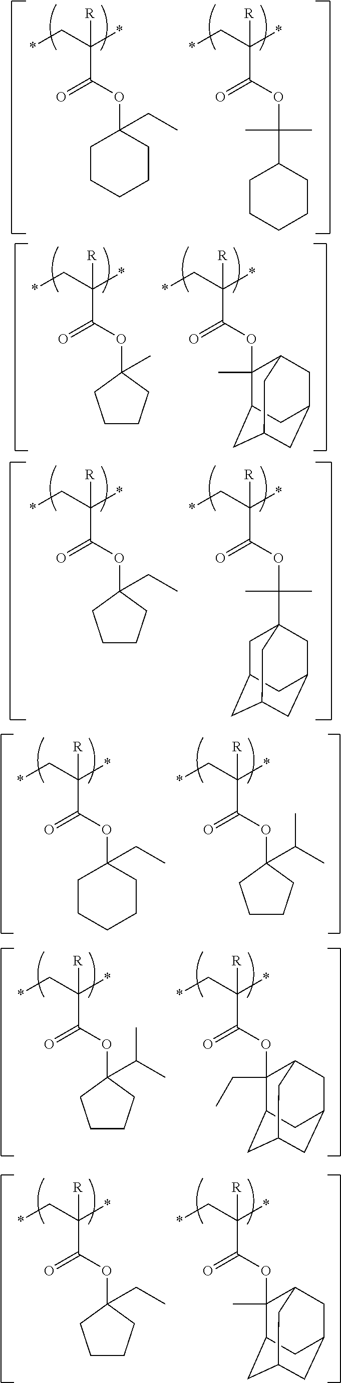

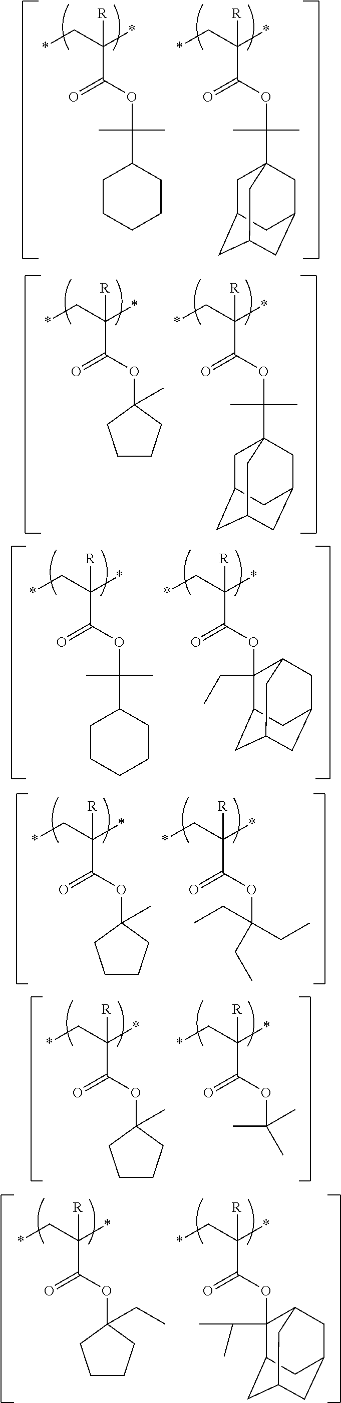

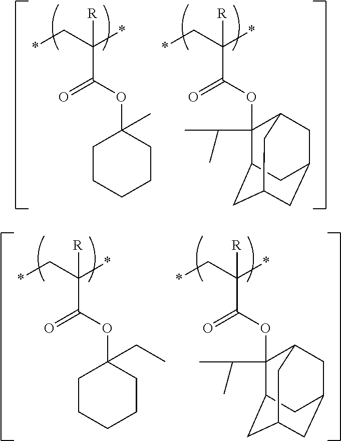

The content of the repeating unit which has an acid-decomposable group which is included in the resin (A) (in a case where there are a plurality of the repeating units which have an acid-decomposable group, the total thereof) is preferably 15 mol % or more with respect to the total amount of the repeating units of the resin (A), more preferably 20 mol % or more, even more preferably 25 mol % or more, and particularly preferably 40 mol % or more.

The resin (A) may contain a repeating unit which has a lactone structure or a sultone structure.

Specific examples of the repeating unit which has a group which has a lactone structure or a sultone structure will be given below; however, the present invention is not limited thereto.

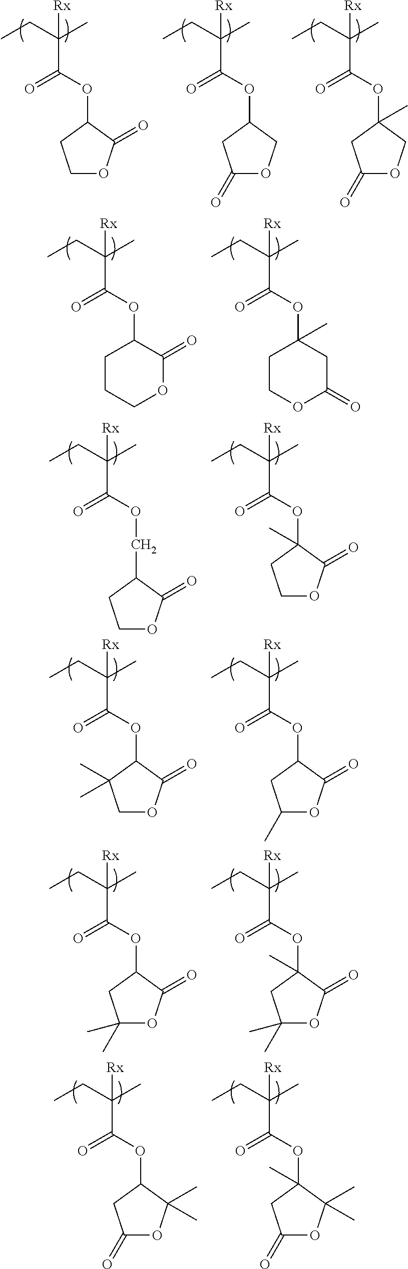

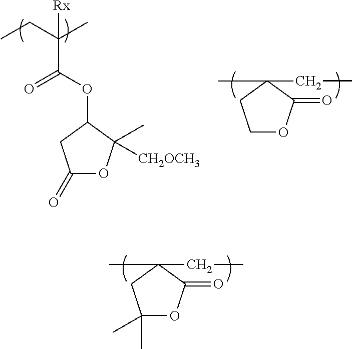

(in the formula, Rx represents H, CH₃, CH₂OH, or CF₃)

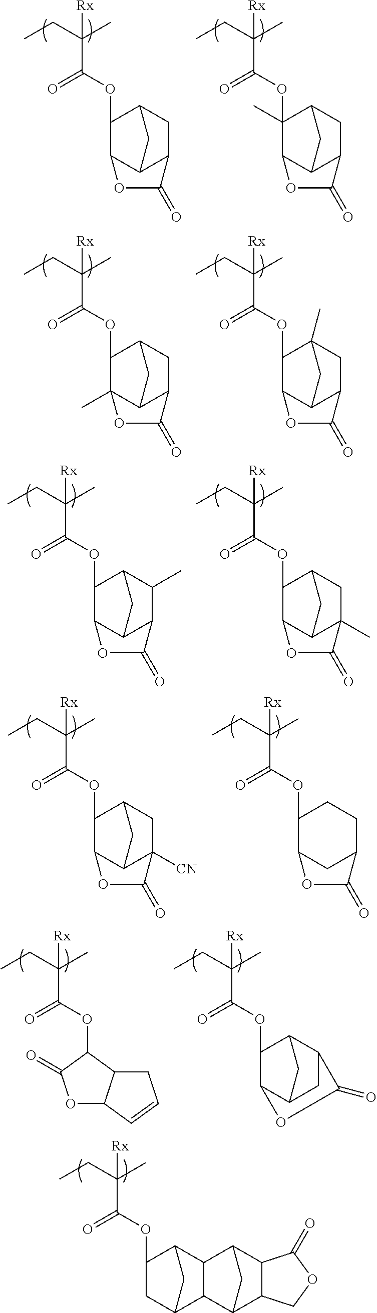

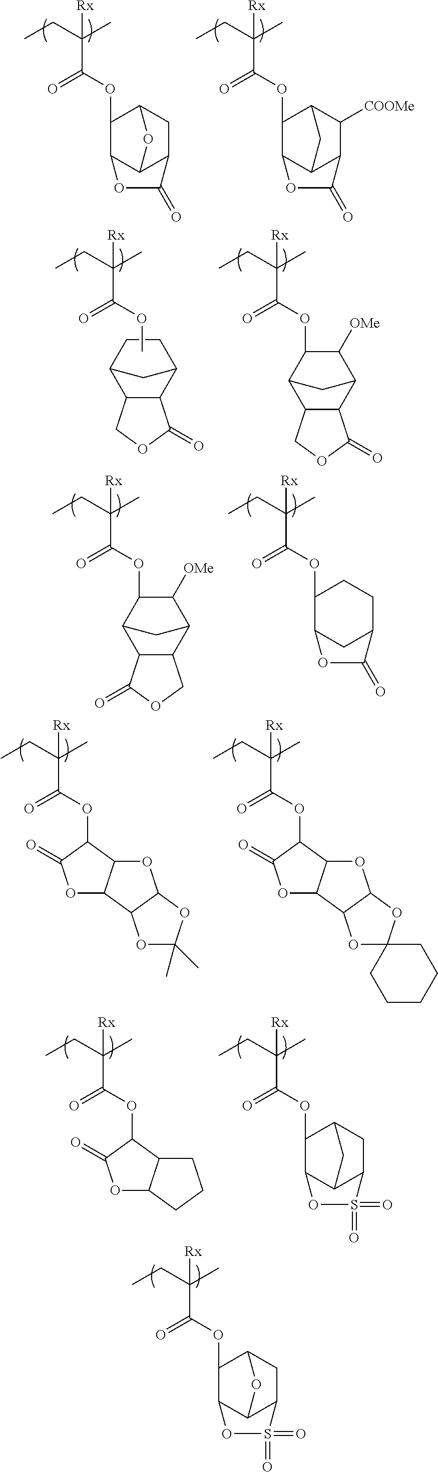

(in the formula, Rx represents H, CH₃, CH₂OH, or CF₃)

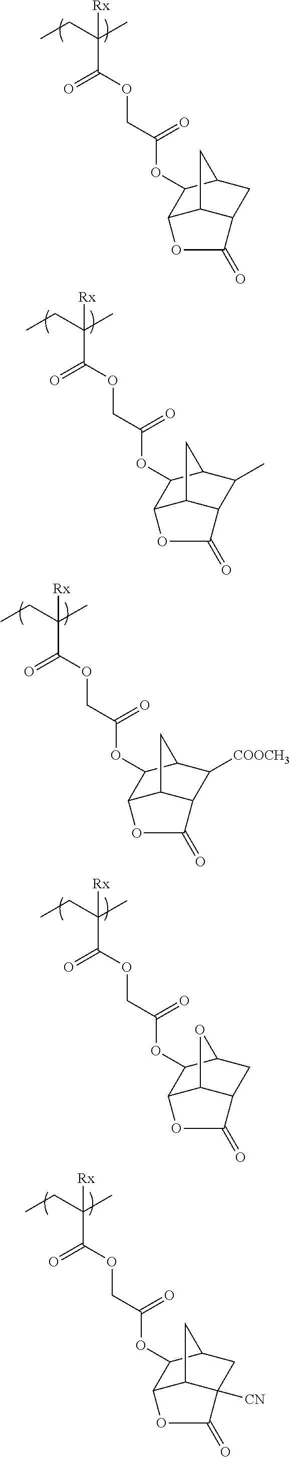

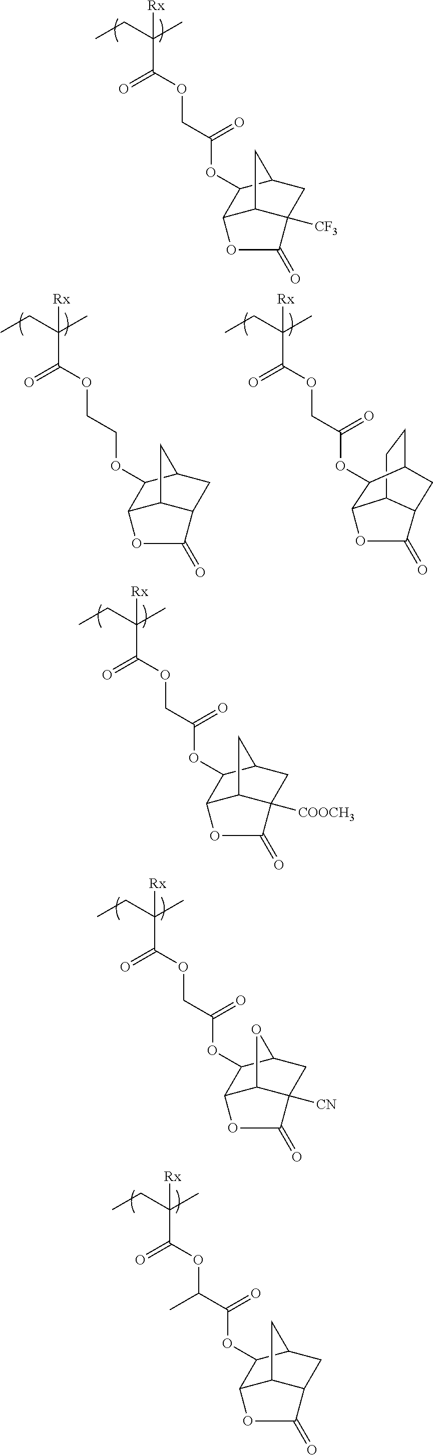

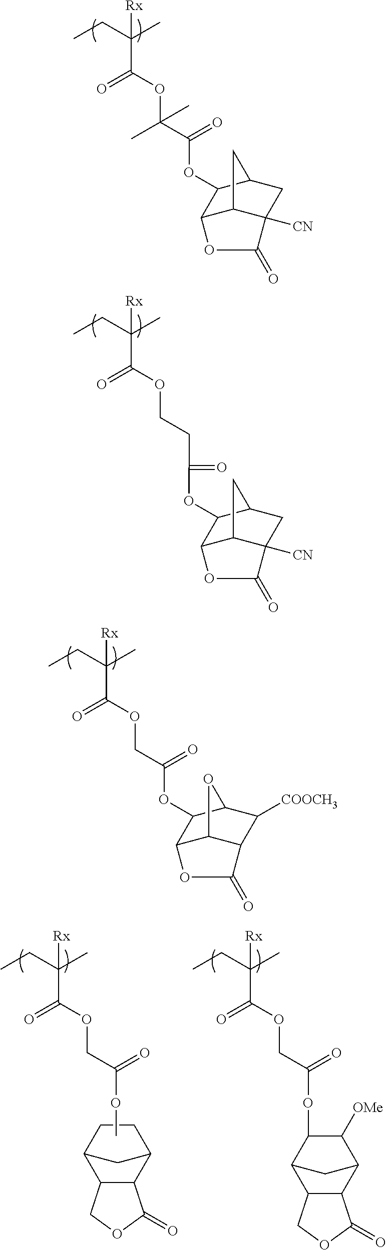

(in the formula, Rx represents H, CH₃, CH₂OH, or CF₃)

It is also possible to use two or more types of repeating units which have a lactone structure or a sultone structure together.

In a case where the resin (A) contains repeating units which have a lactone structure or a sultone structure, the content of the repeating units which have a lactone structure or a sultone structure is preferably 5 mol % to 60 mol % with respect to the total amount of the repeating units in the resin (A), more preferably 5 mol % to 55 mol %, and even more preferably 10 mol % to 50 mol %.

In addition, the resin (A) may have a repeating unit which has a cyclic carbonate ester structure. Specific examples will be given below; however, the present invention is not limited thereto.

Here, R_{A}¹ in the specific examples below represents a hydrogen atom or an alkyl group (preferably, a methyl group).

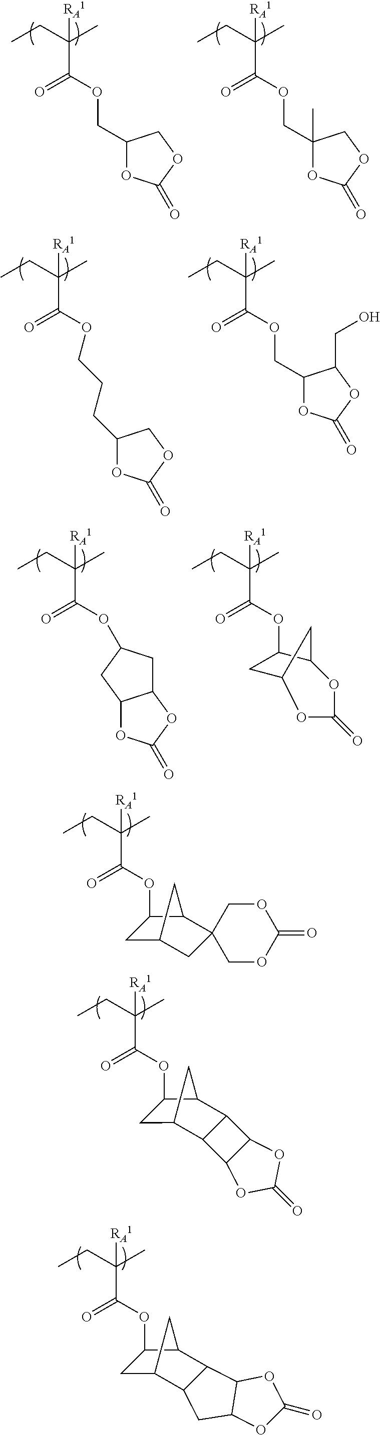

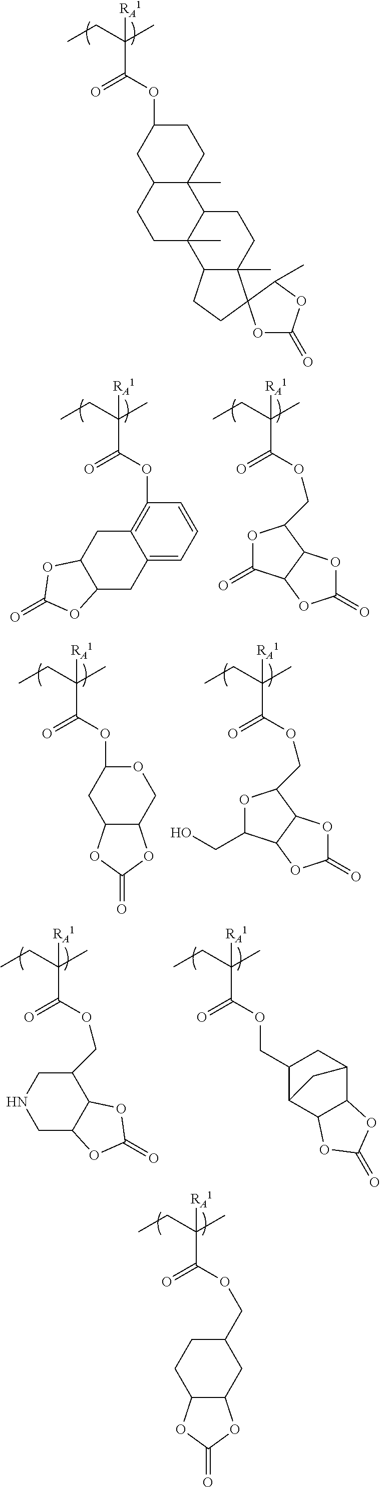

The resin (A) may have a repeating unit which has a hydroxyl group or a cyano group.

Specific examples of the repeating unit which has a hydroxyl group or a cyano group will be given below; however, the present invention is not limited thereto.

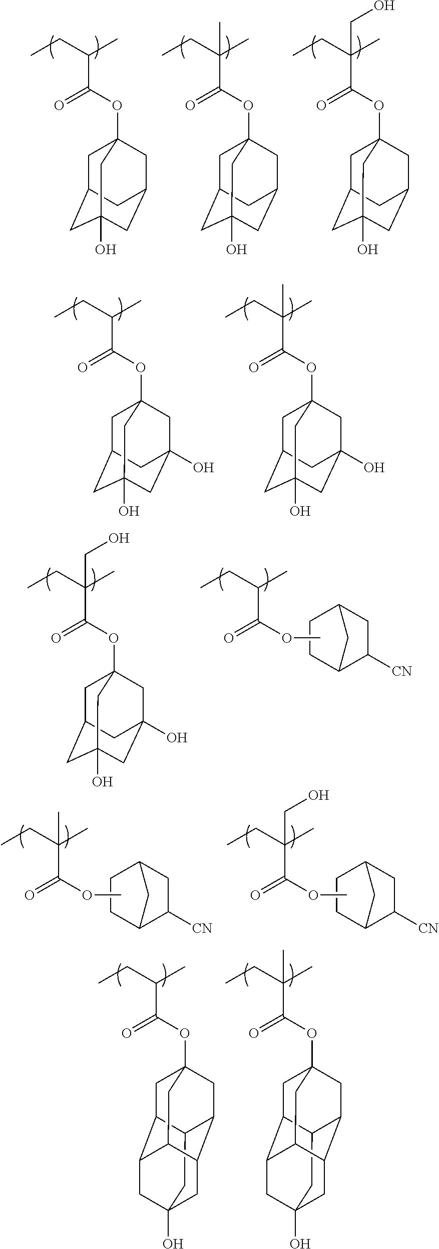

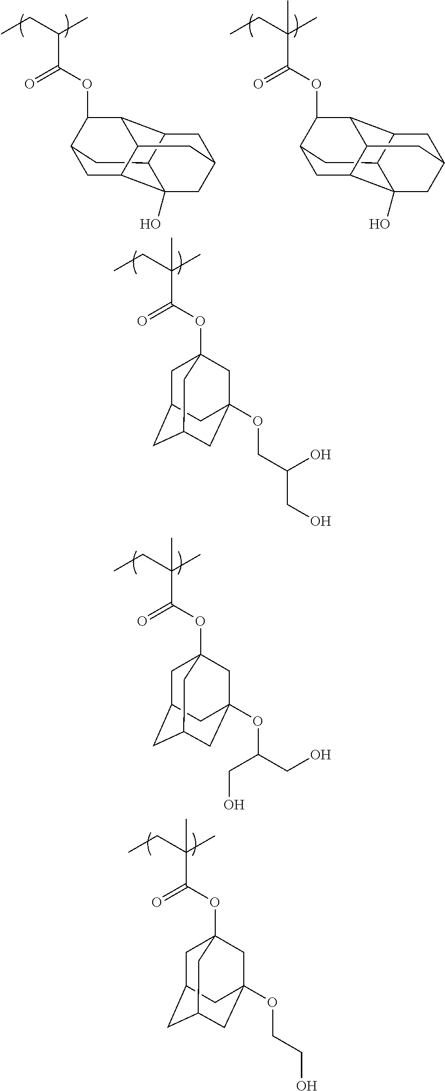

The resin (A) may have a repeating unit which has an acid group.

The resin (A) may or may not contain a repeating unit which has an acid group; however, when contained, the content of the repeating units which have an acid group is preferably 25 mol % or less with respect to the total amount of the repeating units in the resin (A) and more preferably 20 mol % or less. In a case where the resin (A) contains repeating units which have an acid group, the content of the repeating units which have an acid group in the resin (A) is normally 1 mol % or more.

Specific examples of the repeating unit which has an acid group will be given below; however, the present invention is not limited thereto.

In the specific examples, Rx represents H, CH₃, CH₂OH, or CF₃.

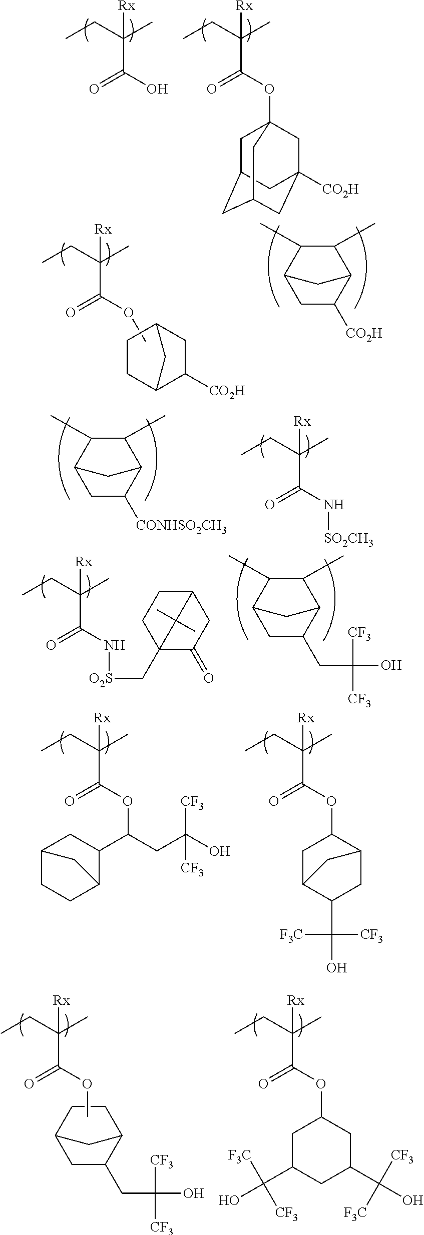

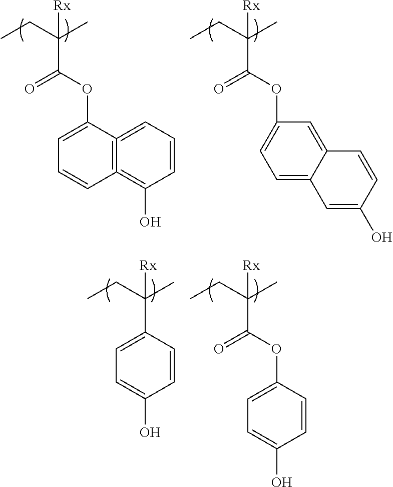

The resin (A) is able to have a repeating unit which also has an alicyclic hydrocarbon structure and/or an aromatic ring structure which does not have a polar group (for example, the acid group, the hydroxyl group, and the cyano group) and does not exhibit acid decomposability. The resin (A) may or may not contain the repeating unit; however, when contained, the content ratio is preferably 5 mol % to 30 mol % with respect to the total amount of the repeating units in the resin (A) and is more preferably 5 mol % to 25 mol %.

Specific examples of the repeating unit which has an alicyclic hydrocarbon structure which does not have a polar group and does not exhibit acid decomposability will be given below; however, the present invention is not limited thereto. In the formulas, Ra represents H, CH₃, CH₂OH, or CF₃.

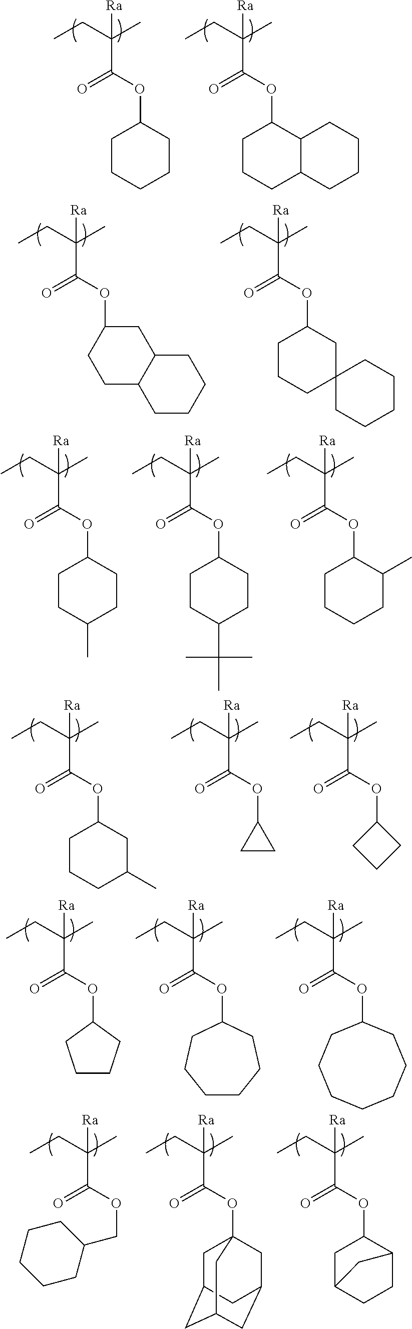

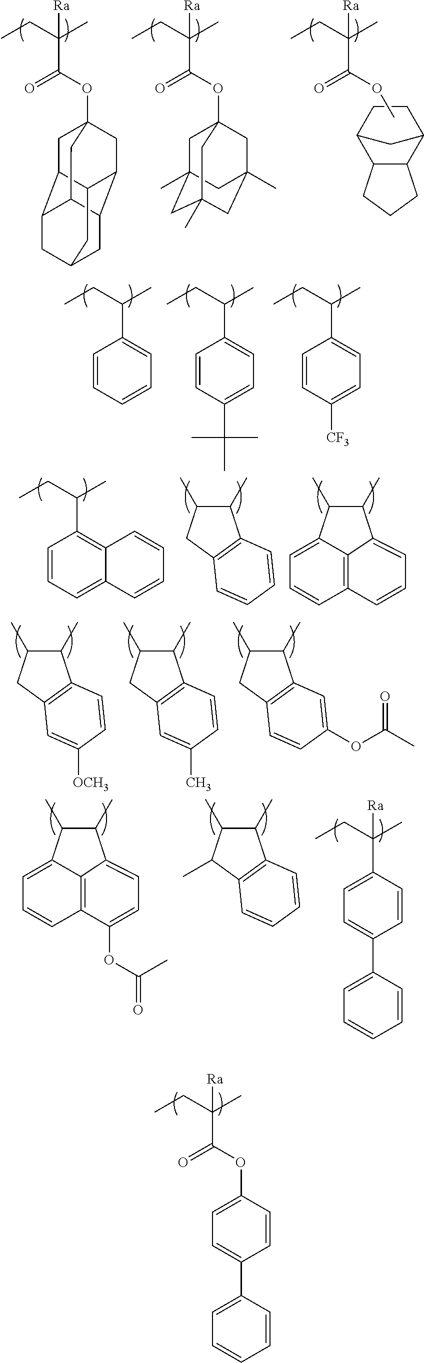

When the composition of the present invention is used for ArF exposure, from the point of the transparency to ArF light, the resin (A) which is used for the composition of the present invention preferably substantially does not have an aromatic ring (in detail, in the resin, the ratio of the repeating units which have an aromatic group is preferably 5 mol % or less, more preferably 3 mol % or less, and ideally 0 mol %, that is, the resin does not have an aromatic group) and the resin (A) preferably has a monocyclic or polycyclic alicyclic hydrocarbon structure.

The form of the resin (A) in the present invention may be any of a random shape, a block shape, a comb shape, or a star shape. It is possible to synthesize the resin (A), for example, by radical, cation, or anion polymerization of unsaturated monomers which correspond to each structure. In addition, it is also possible to obtain a desired resin by performing a polymer reaction after polymerizing using unsaturated monomers which are equivalent to the precursor bodies of each structure.

When the composition of the present invention is used for ArF exposure, from the point of the transparency to ArF light, the resin (A) which is used for the composition of the present invention preferably substantially does not have an aromatic ring (in detail, in the resin, the ratio of the repeating units which have an aromatic group is preferably 5 mol % or less, more preferably 3 mol % or less, and ideally 0 mol %, that is, the resin does not have an aromatic group) and the resin (A) preferably has a monocyclic or polycyclic alicyclic hydrocarbon structure.

In a case where the composition of the present invention includes a resin (D) which will be described below, the resin (A) preferably does not contain fluorine atoms or silicon atoms from the viewpoint of mutual solubility with the resin (D).

As the resin (A) which is used for the composition of the present invention, a resin where all of the repeating units are configured by (meth)acrylate-based repeating units is preferable. In this case, it is possible to use any of a resin where all of the repeating units are methacrylate-based repeating units, a resin where all of the repeating units are acrylate-based repeating units, and a resin where all of the repeating units are formed by methacrylate-based repeating units and acrylate-based repeating units; however, the acrylate-based repeating units are preferably 50 mol % or less of the total amount of the repeating units.

In a case of irradiating the composition of the present invention with KrF excimer laser light, electron beams, X-rays, and high energy rays with a wavelength of 50 nm or less (EUV and the like), the resin (A) may have a repeating unit which has an aromatic ring. The repeating unit which has an aromatic ring is not particularly limited and additionally, although examples are given in the description relating to each of the repeating units, examples thereof include a styrene unit, a hydroxyl styrene unit, a phenyl(meth)acrylate unit, a hydroxyl phenyl(meth)acrylate unit, and the like. In more detail, examples of the resin (A) include a resin which has a hydroxyl styrene-based repeating unit and a hydroxyl styrene-based repeating unit which is protected by an acid-decomposable group, a resin which has a repeating unit which has the aromatic ring described above and a repeating unit where a carbonic acid site of (meth)acrylic acid is protected by an acid-decomposable group, and the like.

It is possible to synthesize and purify the resin (A) of the present invention using typical methods (for example, radical polymerization). For synthesizing methods and purifying methods, refer to, for example, paragraph [0201] and paragraph [0202] in JP2008-292975A.

The weight average molecular weight of the resin (A) in the present invention is 7,000 or more as described above as a polystyrene converted value by a GPC method, preferably 7,000 to 200,000, more preferably 7,000 to 50,000, even more preferably 7,000 to 40,000,000, and particularly preferably 7,000 to 30,000. When the weight average molecular weight is smaller than 7000, the degree of solubility with respect to the organic-based developer is excessively high and there is a concern that it will be not possible to form a precise pattern.

A resin (A) where the dispersity (molecular weight distribution) is normally in the range of 1.0 to 3.0, preferably 1.0 to 2.6, more preferably 1.0 to 2.0, and particularly preferably 1.4 to 2.0. A resin (A) with a smaller molecular weight distribution is excellent in terms of the resolution and the resist shape and the side wall of a resist pattern is smooth and has excellent roughness.

In the chemical amplification resist composition of the present invention, the mixing ratio of the resin (A) in the entire composition is preferably 30 mass % to 99 mass % in the entirety of the solid content and more preferably 60 mass % to 95 mass %.

In addition, in the present invention, the resin (A) may be used as one type or a plurality thereof may be used together.

Specific examples of the resin (A) (the compositional ratio of the repeating units is a molar ratio) will be given below; however, the present invention is not limited thereto. Here, aspects in a case where a structure which corresponds to an acid generating agent (B) which will be described below is supported by the resin (A) will be also exemplified below.

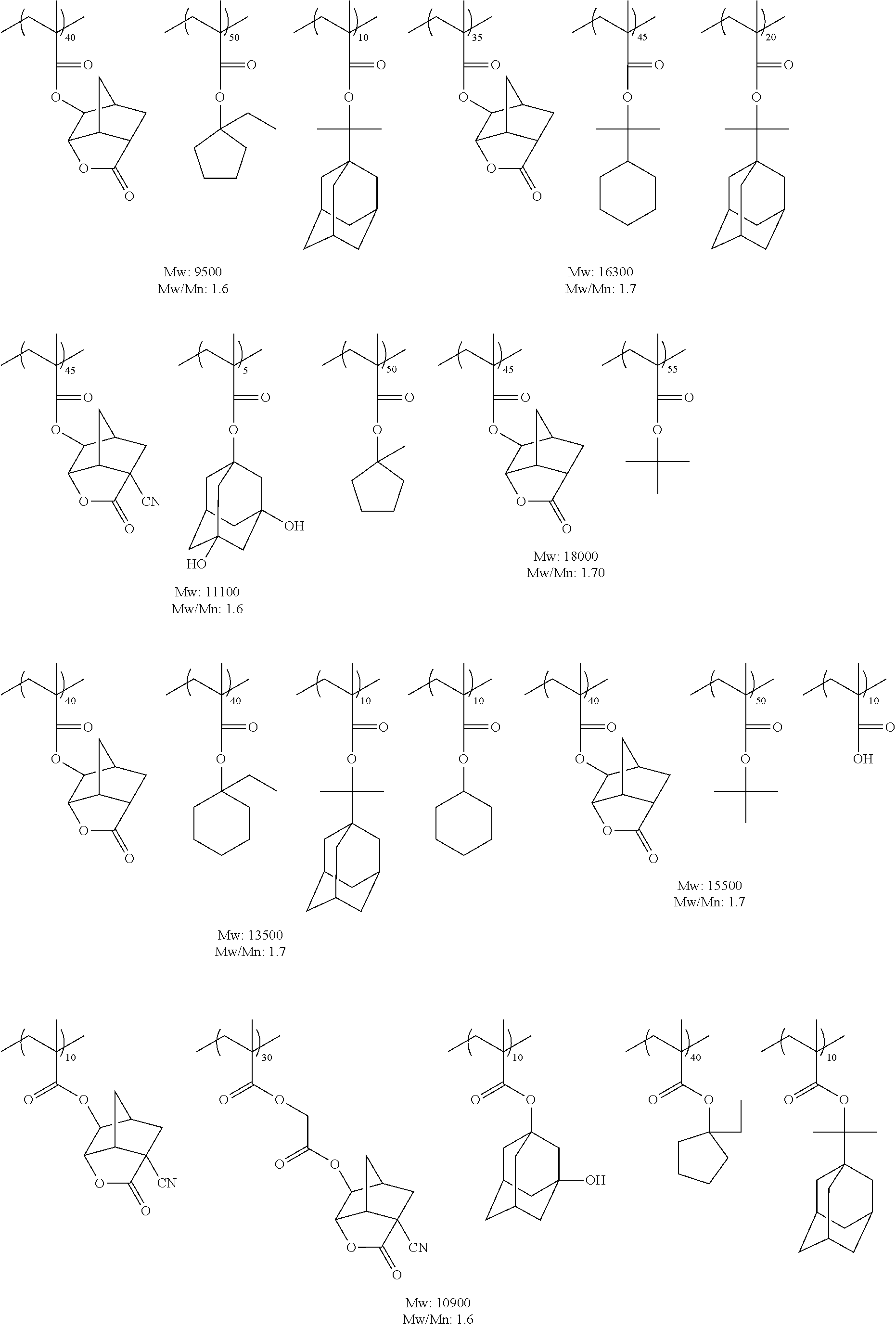

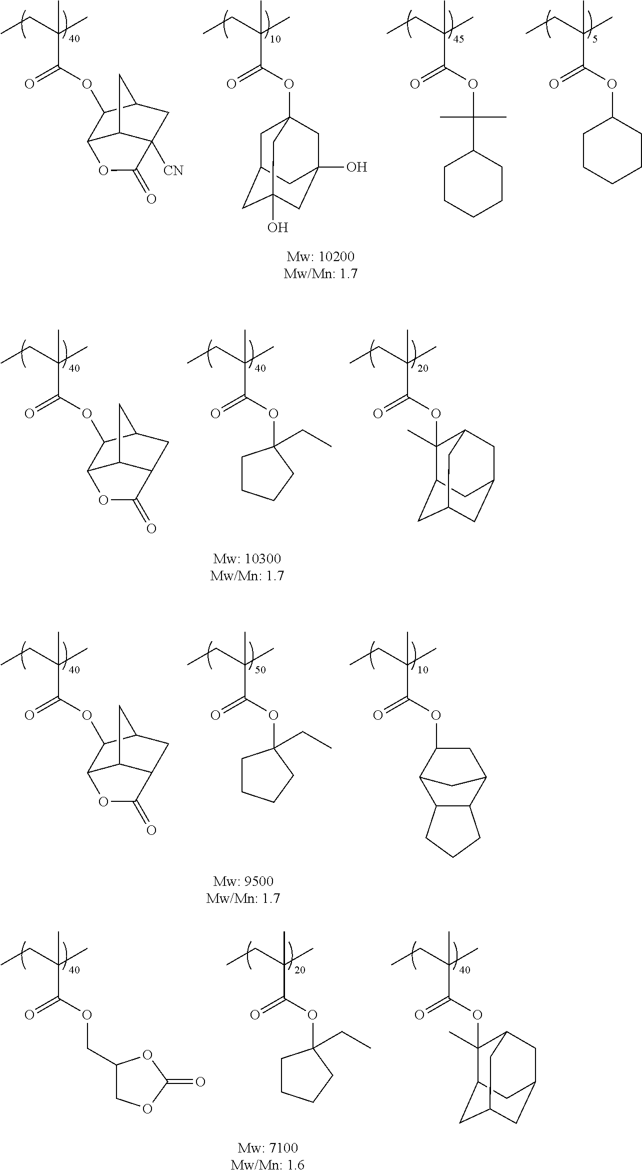

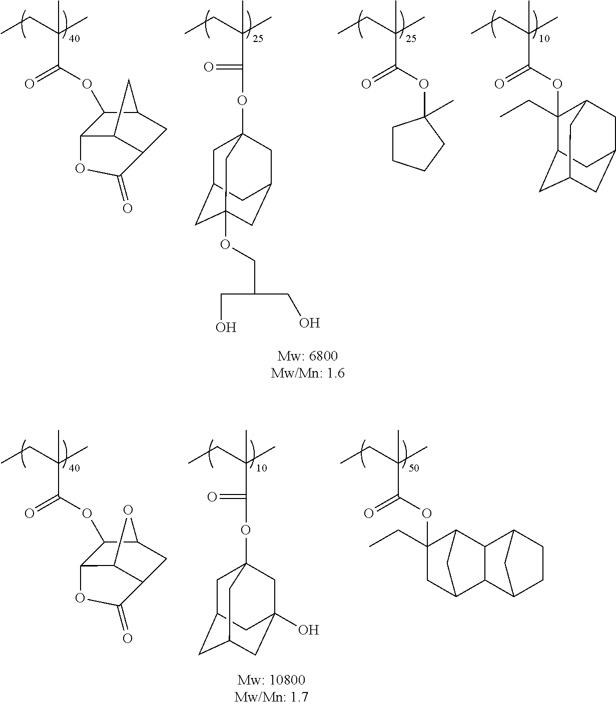

[2] Compound which generates an acid when irradiated with actinic rays or radiation

The composition in the present invention contains a compound (also referred to below as “compound (B)” or an “acid generating agent”) which generates an acid when irradiated with actinic rays or radiation. The compound (B) which generates an acid when irradiated with actinic rays or radiation is preferably a compound which generates an organic acid when irradiated with actinic rays or radiation.

As the acid generating agent, it is possible to appropriately select and use a photo-cationic polymerization photoinitiator, a photo-radical polymerization photoinitiator, a light decolorant for dyes, a photodiscoloration agent, a compound known in the art which generates an acid when irradiated with actinic rays or radiation which is used for microresists and the like, or mixtures thereof.

Examples thereof include diazonium salt, phosphonium salt, sulfonium salt, iodonium salt, imide sulfonate, oxime sulfonate, diazo disulfone, disulfone, and o-nitrobenzyl sulfonate. Among acid generating agents, particularly preferable examples will be given below.

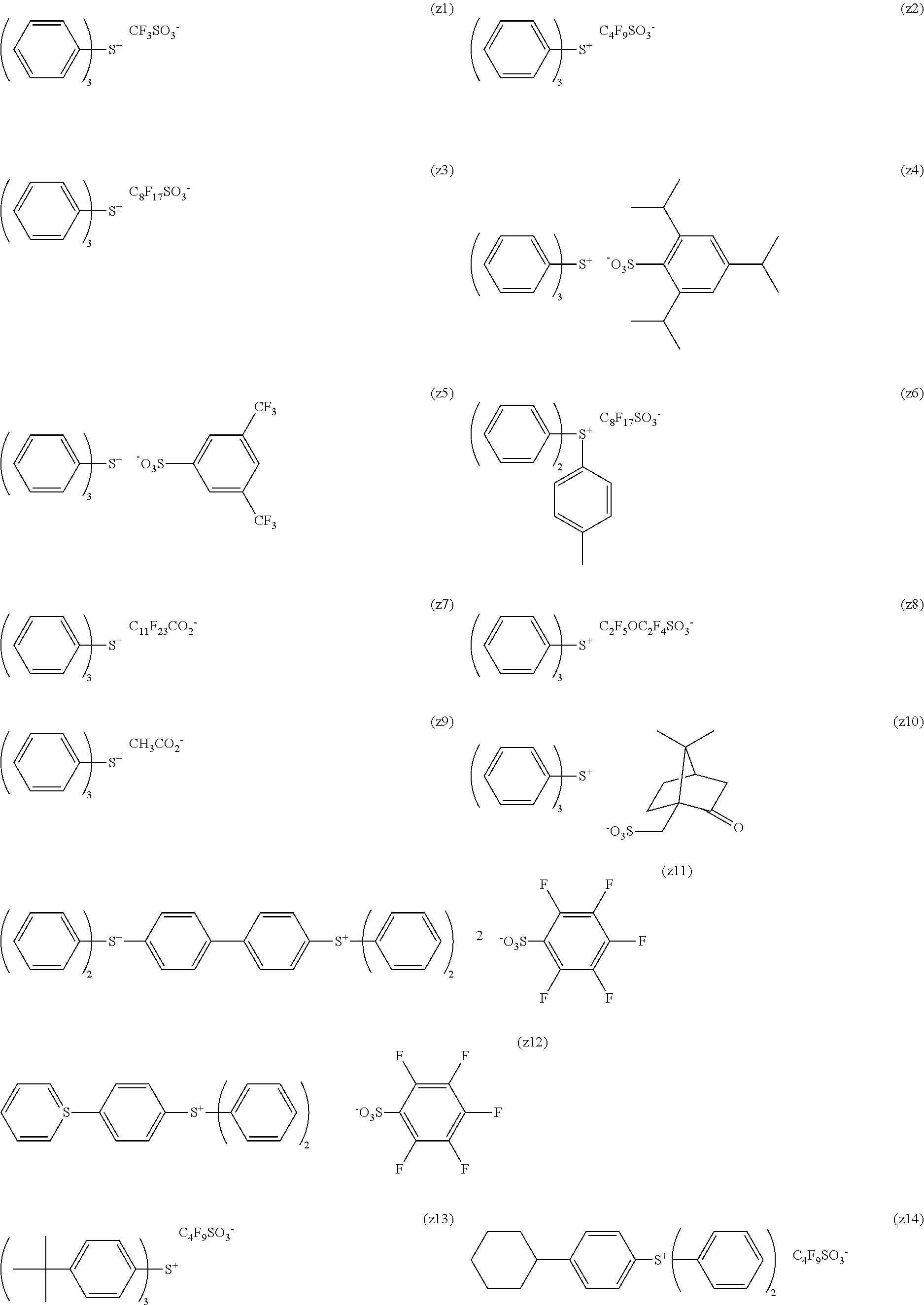

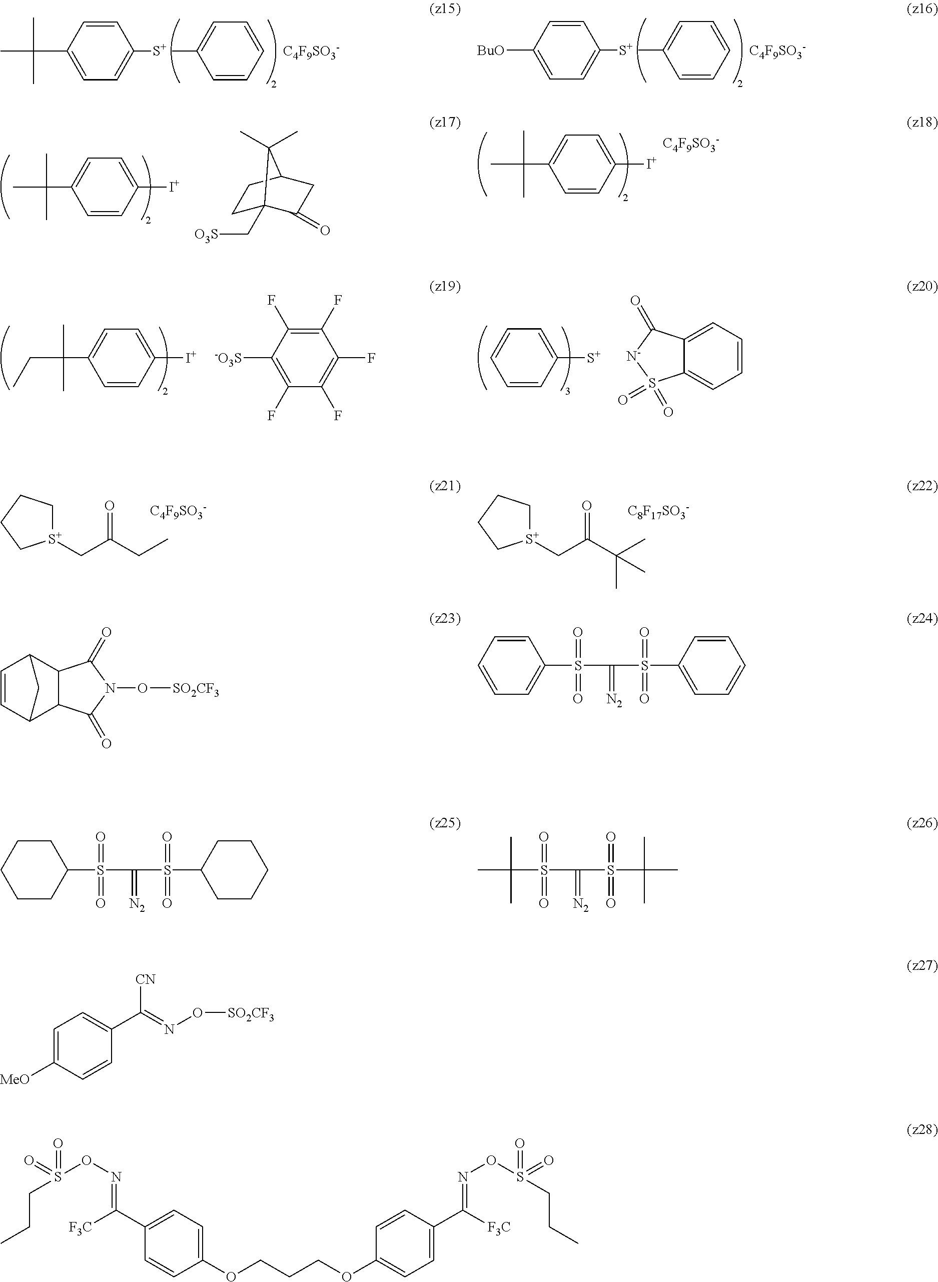

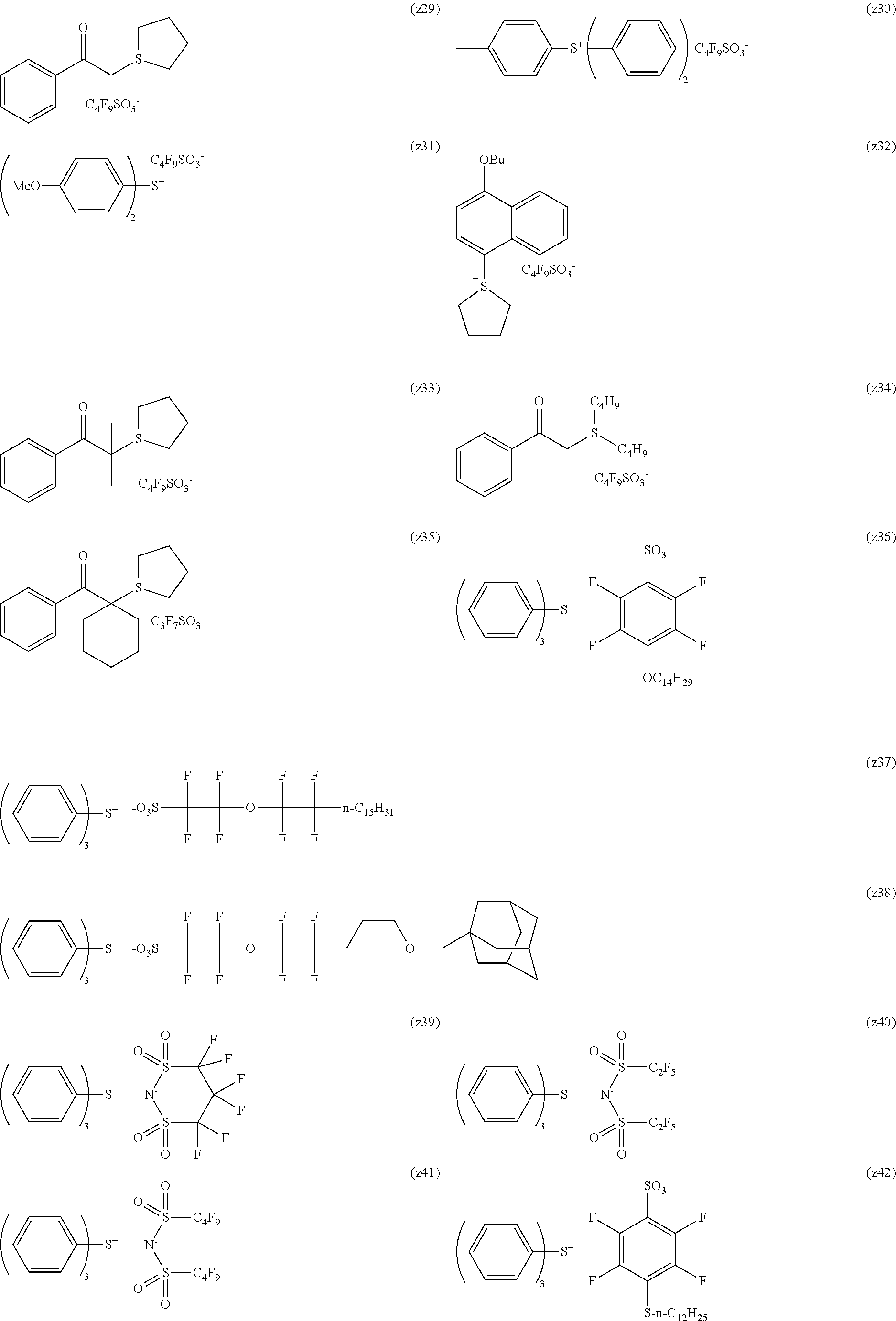

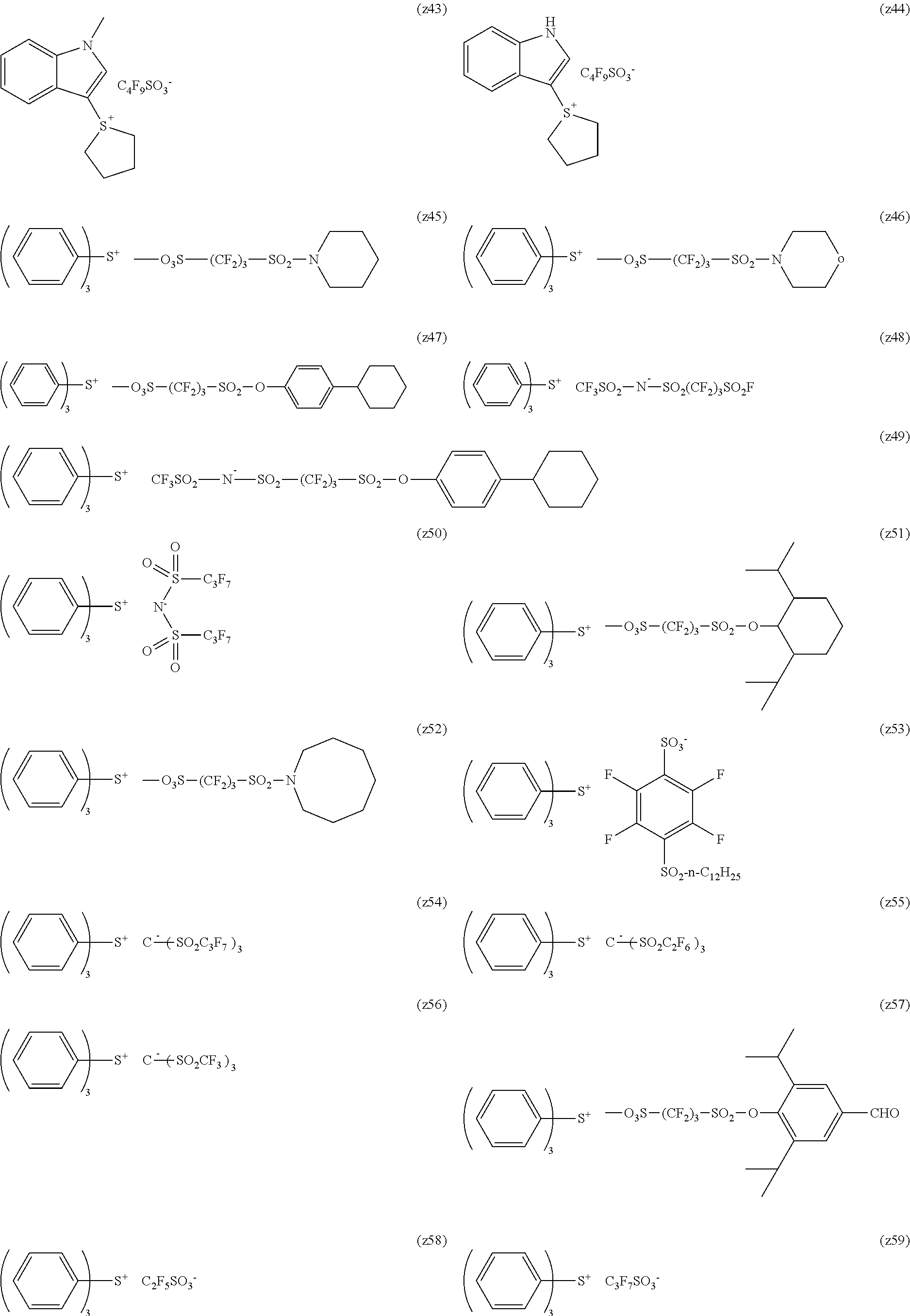

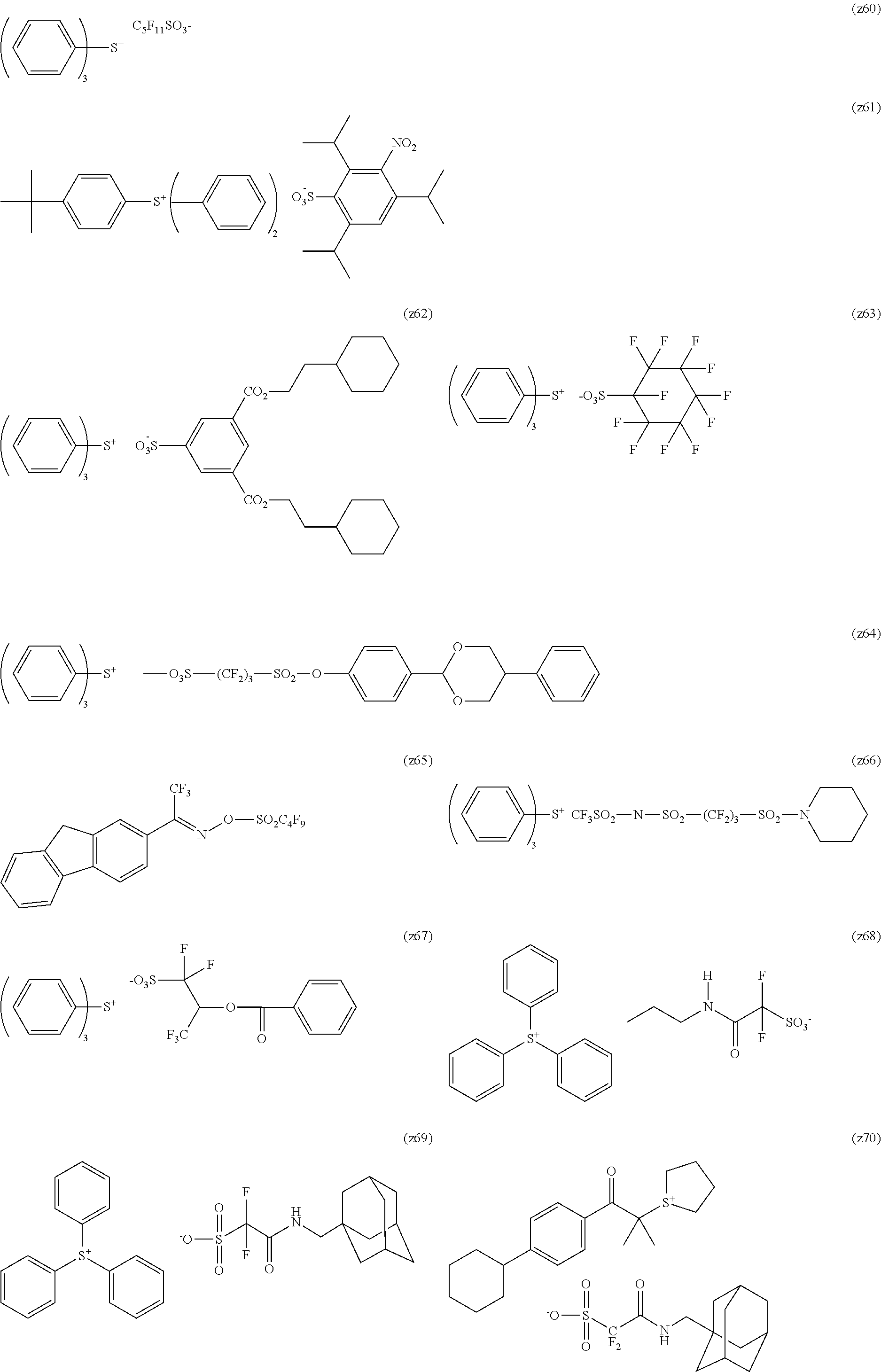

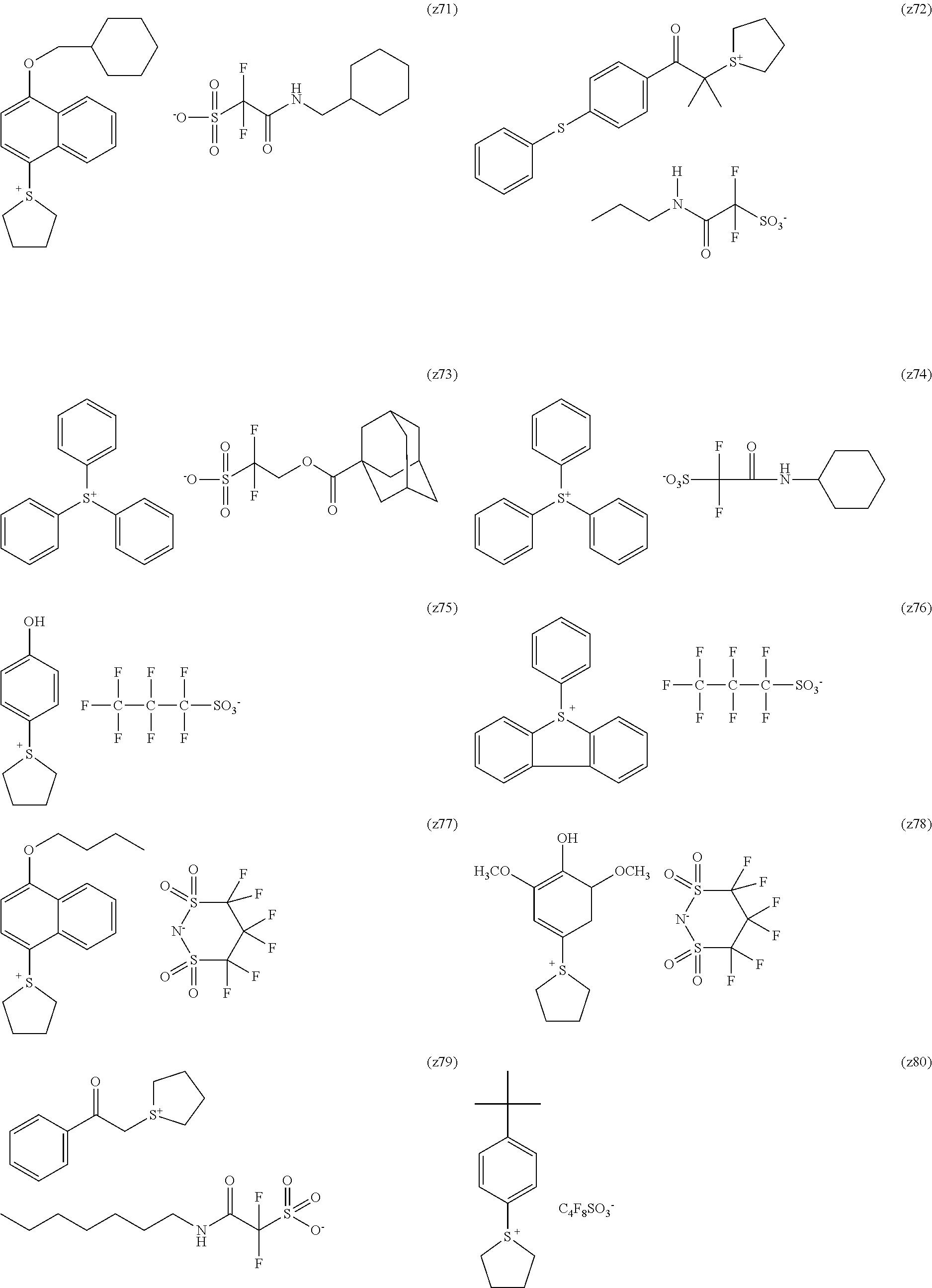

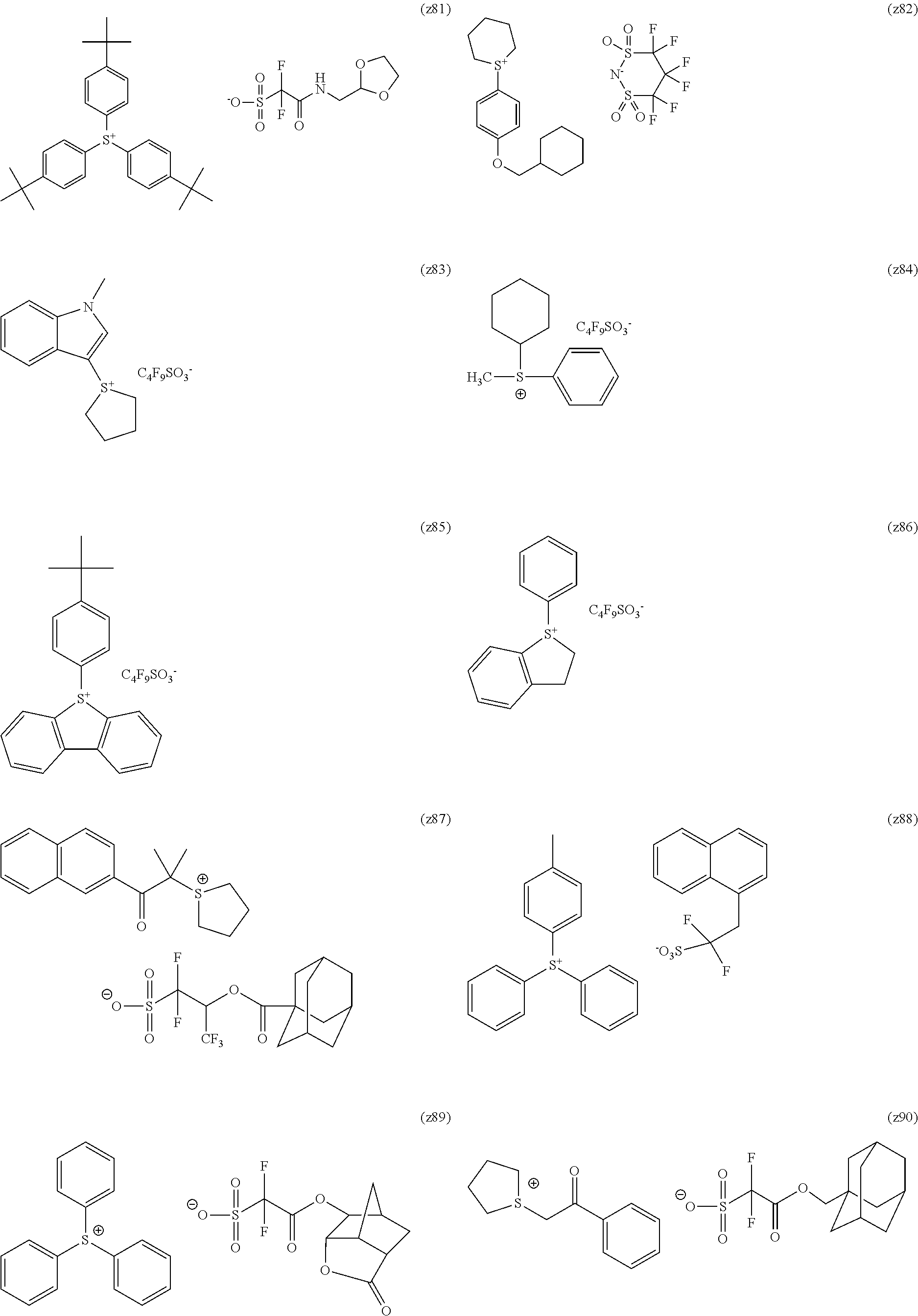

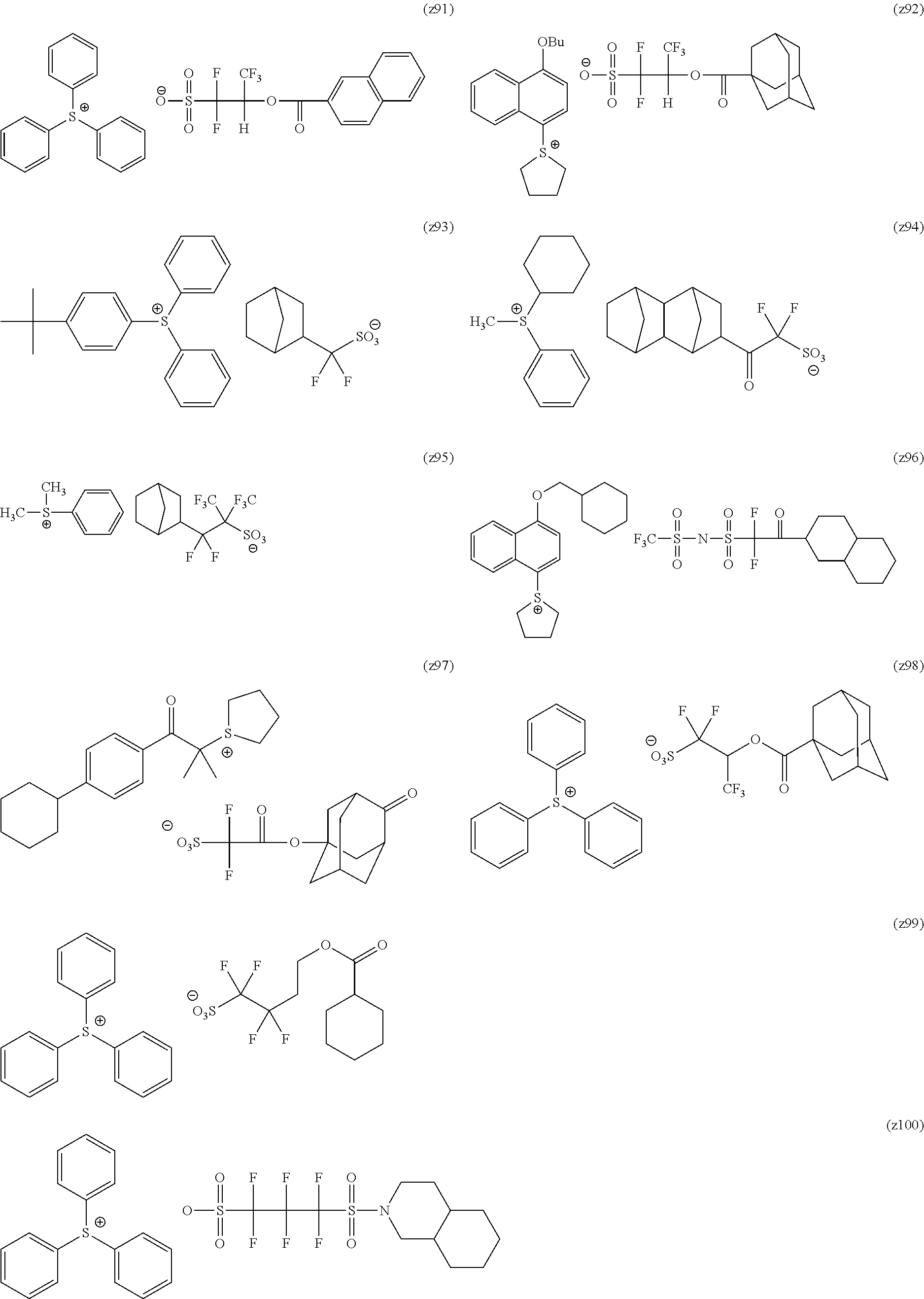

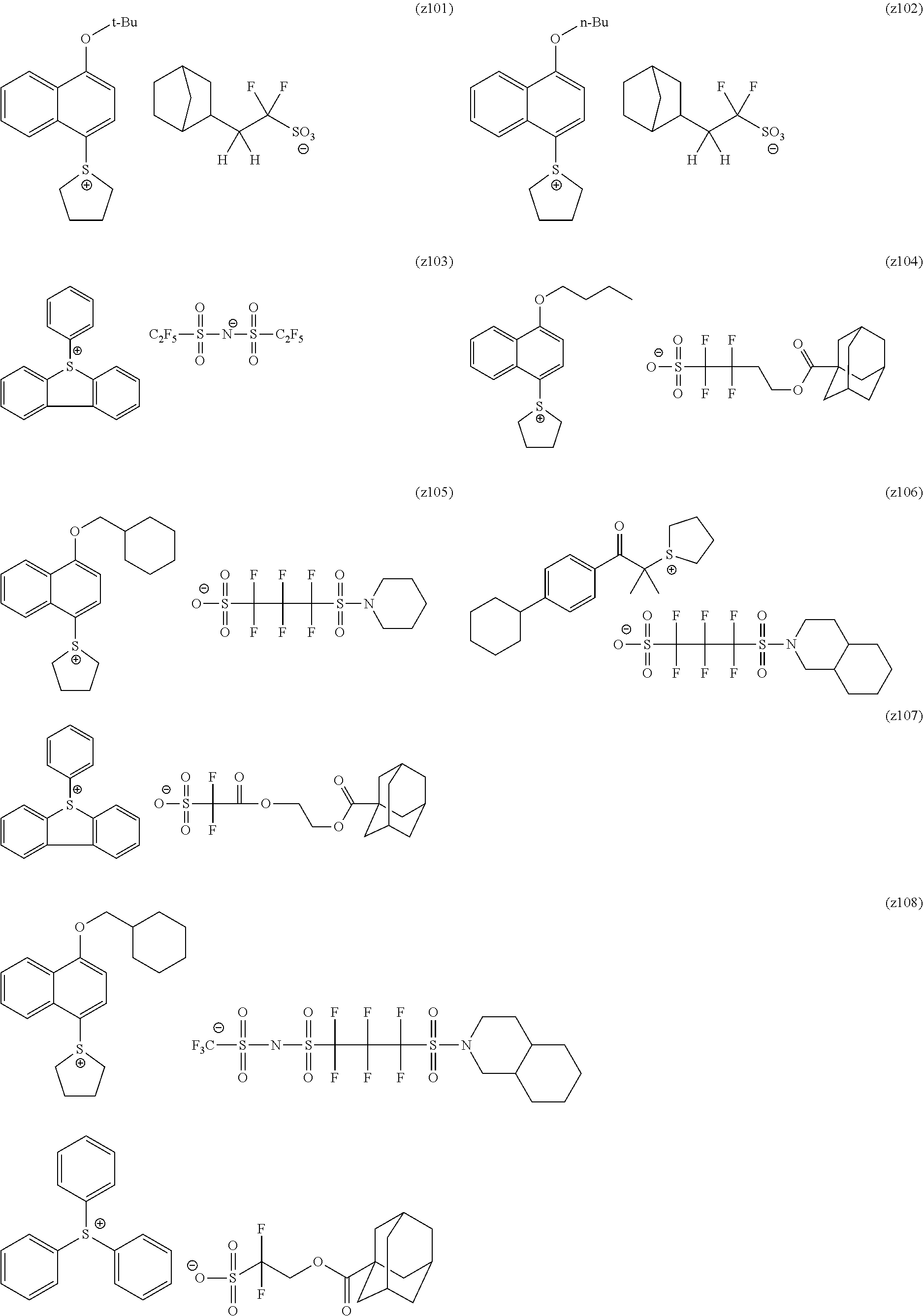

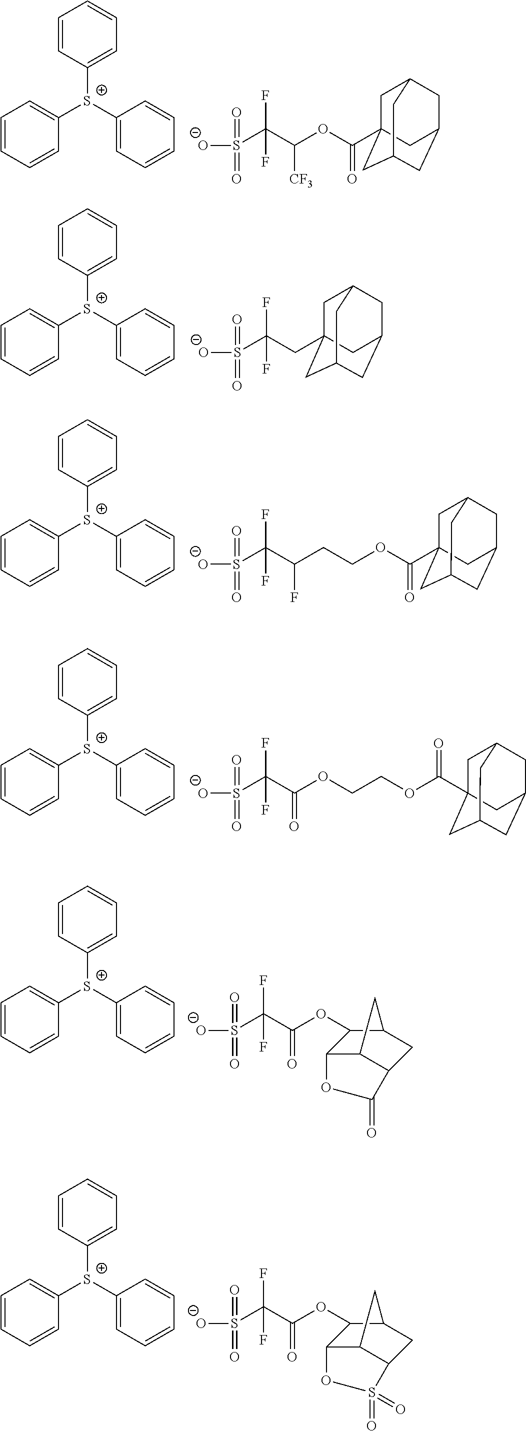

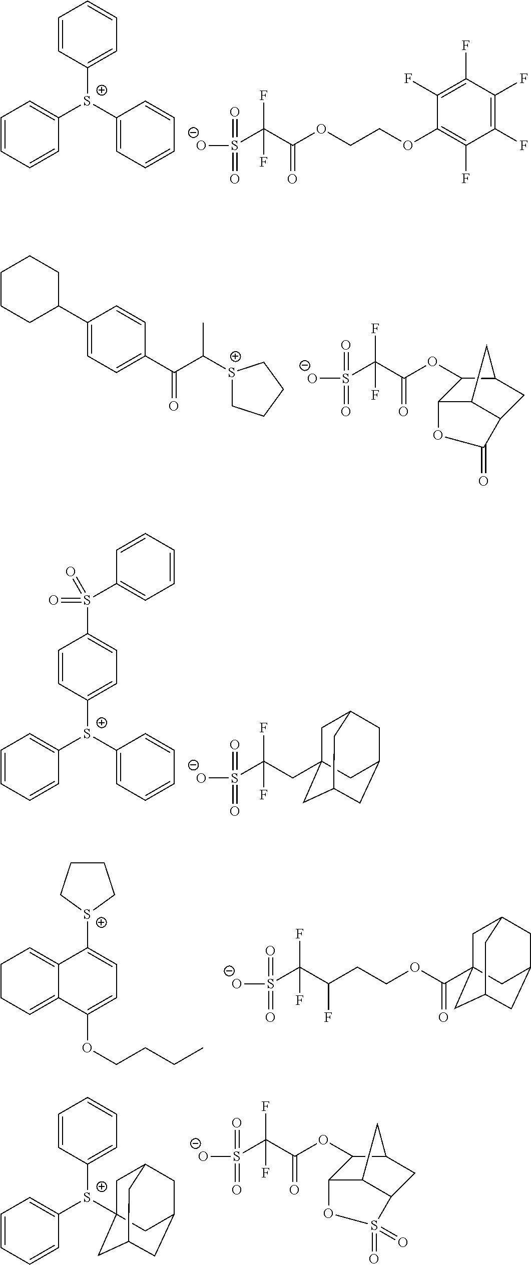

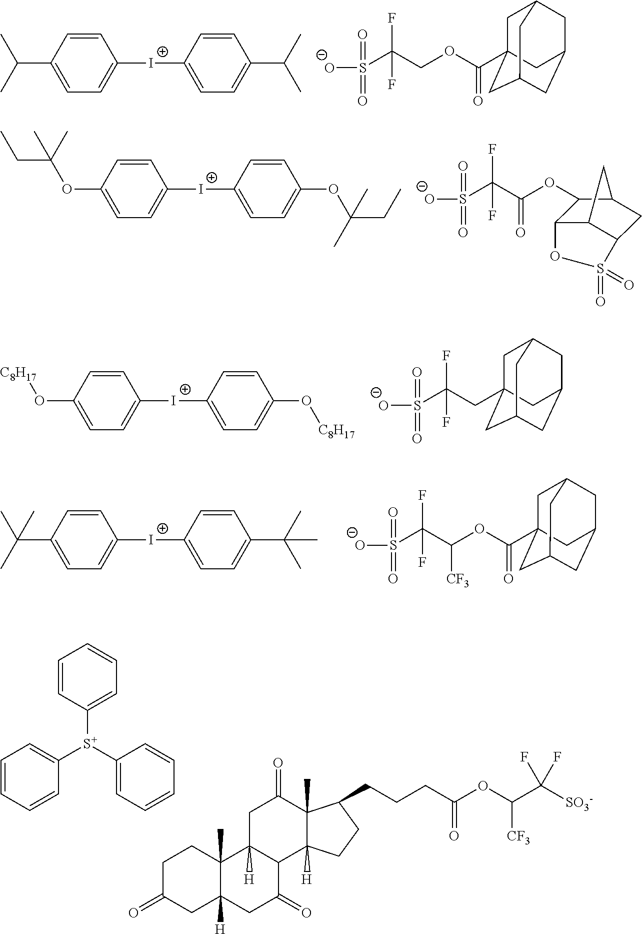

It is possible to synthesize the acid generating agent using a method known in the art and, for example, synthesis is possible on the basis of the methods described in JP2007-161707A, [0200] to [0210] in JP2010-100595A, [0051] to [0058] in WO2011/093280A, [0382] to [0385] in WO2008/153110A, JP2007-161707A, and the like.

It is possible to use the acid generating agent as a one type individually or in a combination of two or more types.

The content ratio of the compounds which generate an acid when irradiated with actinic rays or radiation in the composition is preferably 0.1 mass % to 30 mass % on the basis of the total solid content of the composition of the present invention, more preferably 0.5 mass % to 25 mass %, even more preferably 3 mass % to 20 mass %, and particularly preferably 3 mass % to 15 mass %.

Here, depending on the actinic ray sensitive or radiation sensitive resin composition, there is also an aspect (B′) where a structure which corresponds to an acid generating agent is supported by the resin (A). Specific examples of this aspect include the structure described in JP2011-248019A (in particular, the structure described in paragraph [0164] to paragraph [0191] and the structure which is included in a resin which is described in the examples in paragraph [0555]) and the like. Here, even in an aspect where the structure which corresponds to an acid generating agent is supported by the resin (A), the actinic ray sensitive or radiation sensitive resin composition may additionally include an acid generating agent which is not supported by the resin (A).

Examples of the aspect (B′) include the repeating units as follows; however, the present invention is not limited thereto.

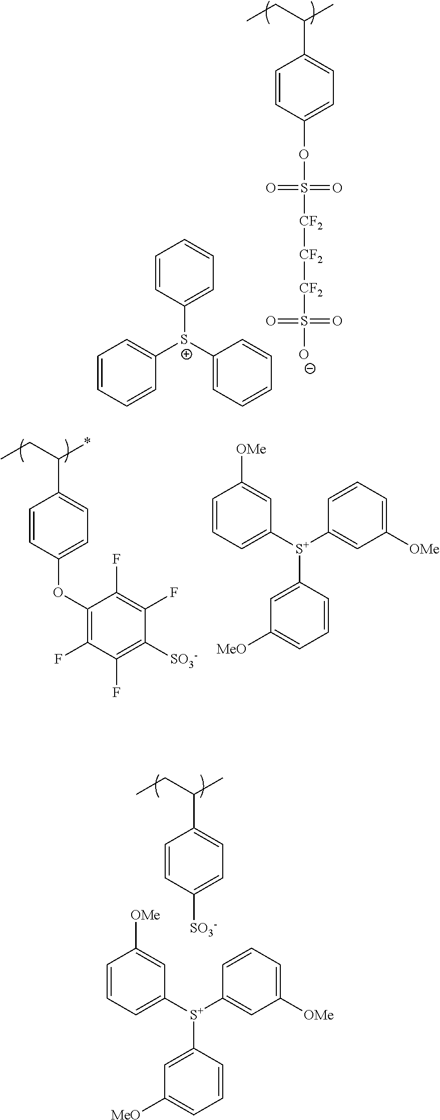

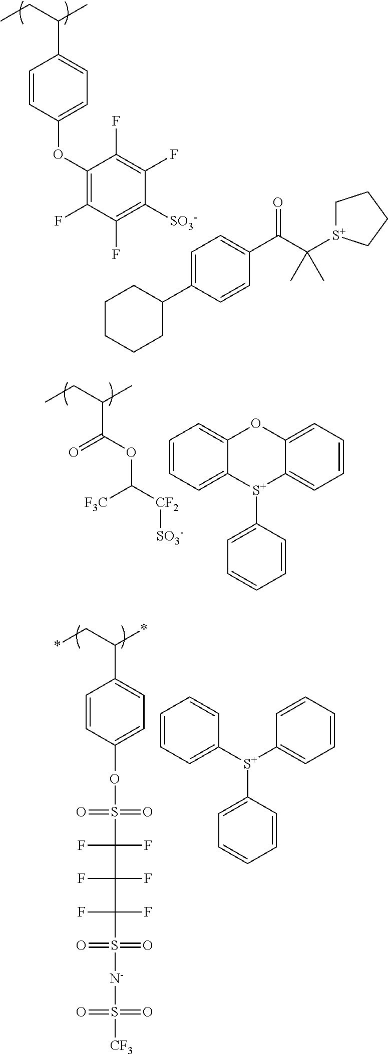

[3] Solvent

The composition of the present invention normally contains a solvent.

Examples of solvents which are able to be used when preparing the composition of the present invention include alkylene glycol monoalkyl ether carboxylate, alkylene glycol monoalkyl ether, alkyl lactate ester, alkyl alkoxypropionate, cyclic lactone (preferably with 4 to 10 carbon atoms), monoketone compounds which may have a ring (preferably with 4 to 10 carbon atoms), alkylene carbonate, alkoxy acetate alkyl, and organic solvents such as alkyl pyruvate.

Specific examples of the solvents include the solvents described in [0441] to [0455] in US2008/0187860A.

In the present invention, a mixed solvent where a solvent which contains a hydroxyl group as an organic solvent in the structure and a solvent which does not contain a hydroxyl group are mixed may be used.

It is possible to appropriately select the examplary compounds described above as a solvent which contains a hydroxyl group and a solvent which does not contain a hydroxyl group; however, the solvent which contains a hydroxyl group is preferably alkylene glycol monoalkyl ether, alkyl lactate, and the like, and more preferably propylene glycol monomethyl ether (PGME, also called 1-methoxy-2-propanol) and ethyl lactate. In addition, the solvent which does not contain a hydroxyl group is preferably alkylene glycol monoalkyl ether acetate, alkyl alkoxy propionate, monoketone compounds which may contain a ring, cyclic lactone, alkyl acetate, and the like, particularly preferably propylene glycol monomethyl ether acetate (PGMEA, also called 1-methoxy-2-acetoxy propane), ethyl ethoxypropionate, 2-heptanone, y-butylolactone, cyclohexanone, and butyl acetate, among these, the most preferable are propylene glycol monomethyl ether acetate, ethyl ethoxypropionate, and 2-heptanone.

The mixing ratio (mass) of the solvent which contains a hydroxyl group and the solvent which does not contain a hydroxyl group is 1/99 to 99/1, preferably 10/90 to 90/10, and more preferably 20/80 to 60/40. A mixed solvent which contains the solvent which does not contain a hydroxyl group at 50 mass % or more is particularly preferable in terms of coating uniformity.

The solvent preferably includes propylene glycol monomethyl ether acetate and is preferably a propylene glycol monomethyl ether acetate single solvent or a mixed solvent of two or more types which contains propylene glycol monomethyl ether acetate.

[4] Hydrophobic Resin (D)

The composition of the present invention may contain a hydrophobic resin (also referred to below as “hydrophobic resin (D)” or simply “resin (D)”). Here, the hydrophobic resin (D) is preferably different from the resin (A).

Due to this, in a case where the hydrophobic resin (D) is unevenly distributed on the film surface layer and the liquid immersion medium is water, it is possible to improve the static/dynamic contact angle of a resist film surface with respect to water and improve the immersion liquid conformance.

The hydrophobic resin (D) is preferably designed so as to be unevenly distributed on an interface as described above but, unlike a surfactant, does not need to have a hydrophilic group in the molecule and need not contribute to the even mixing of polar/non-polar substances.

The hydrophobic resin (D) preferably has any one or more types of a “fluorine atom”, a “silicon atom”, and a “CH₃ partial structure which is contained in a side chain portion of a resin” from the viewpoint of being unevenly distributed on the film surface layer and more preferably has two or more types.

The weight average molecular weight of the hydrophobic resin (D) in standard polystyrene conversion is preferably 1,000 to 100,000, more preferably 1,000 to 50,000, and even more preferably 2,000 to 15,000.

In addition, the hydrophobic resin (D) may be used as one type or a plurality thereof may be used together.

The content of the hydrophobic resin (D) in the composition is preferably 0.01 mass % to 10 mass % with respect to the total solid content of the composition of the present invention, more preferably 0.05 mass % to 8 mass %, and even more preferably 0.1 mass % to 7 mass %.

While the hydrophobic resin (D) naturally has few impurities such as metals in the same manner as the resin (A), the residual monomers or oligomer components are preferably 0.01 mass % to 5 mass %, more preferably 0.01 mass % to 3 mass %, and even more preferably 0.05 mass % to 1 mass %. Due to this, a chemical amplification resist composition where the foreign matter in the liquid and the sensitivity or the like does not change over time is obtained. In addition, from the viewpoint of the resolution, the resist shape, the side wall of the resist pattern, the roughness, and the like, the molecular weight distribution (Mw/Mn, also referred to as the dispersity) is preferably in a range of 1 to 5, more preferably 1 to 3, and even more preferably in a range of 1 to 2.

It is also possible to use various types of commercial products for the hydrophobic resin (D) and it is possible to synthesize the resin using typical methods (for example, radical polymerization). Examples of typical synthesizing methods include a collective polymerization method for performing polymerization by dissolving monomers and an initiator in a solvent and heating the result, a dripping polymerization method for dropwise adding a solution of monomers and an initiator to a heated solvent over 1 hour to 10 hours, and the like, of which the dripping polymerization method is preferable.

The reaction solvent, the polymerization initiator, the reaction conditions (temperature, concentration, and the like), and the purifying method after reaction are the same as the content described in the resin (A); however, in the synthesis of the hydrophobic resin (D), the reaction concentration is preferably 30 mass % to 50 mass %. For more detail, refer to paragraph [0320] to paragraph [0329] and the surrounding text in JP2008-292975A.

Specific examples of the hydrophobic resin (D) will be given below. In addition, the molar ratio of repeating units in each resin (corresponding to each repeating unit in order from the left), the weight average molecular weight, and the dispersity will be shown in the table below.

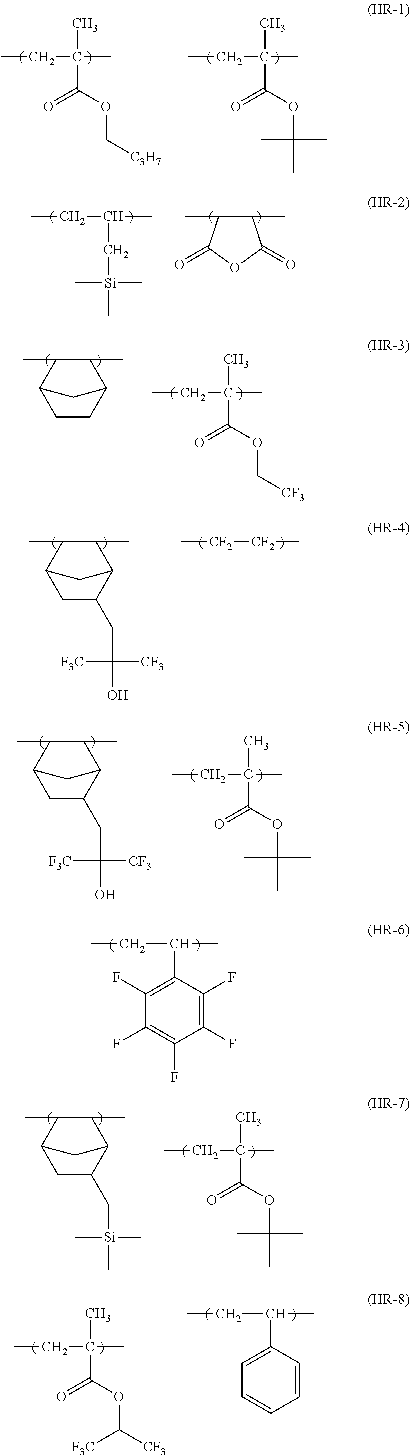

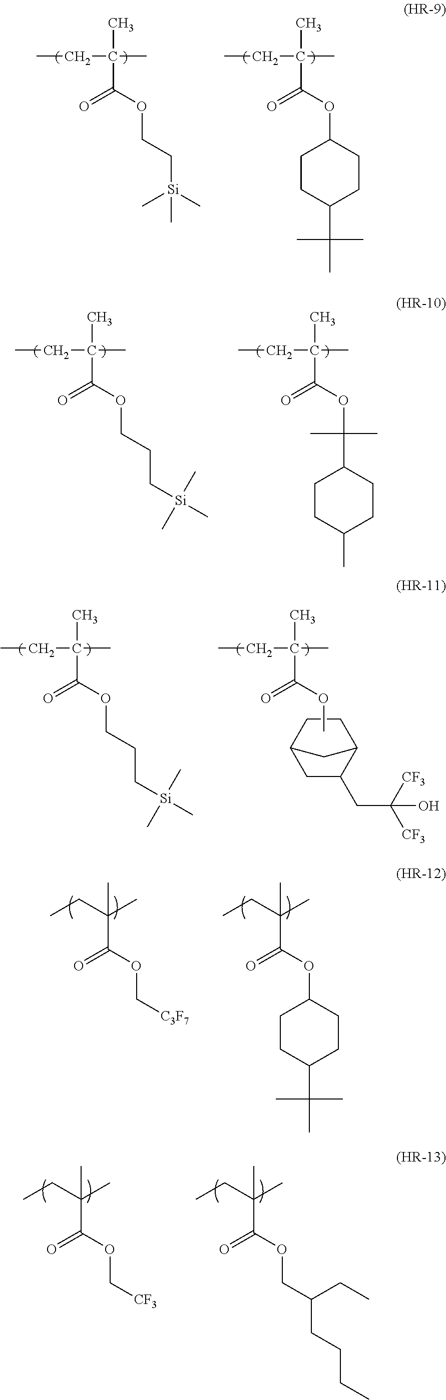

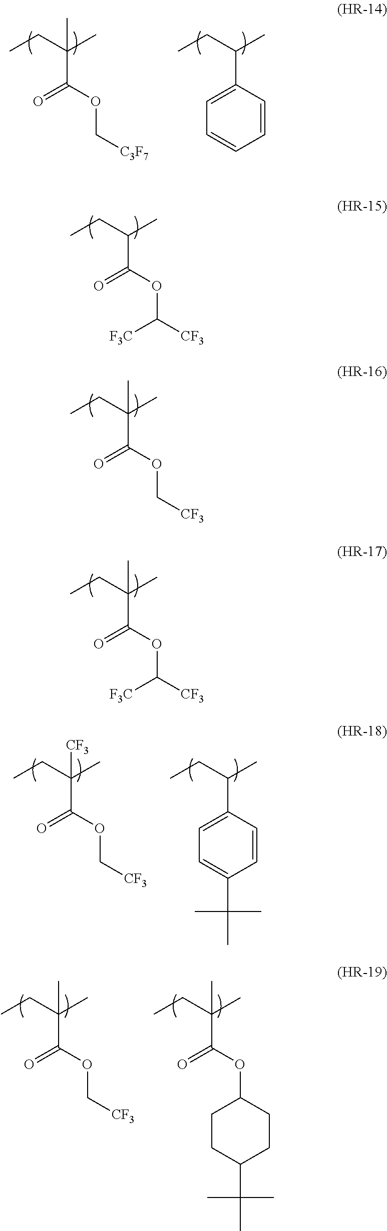

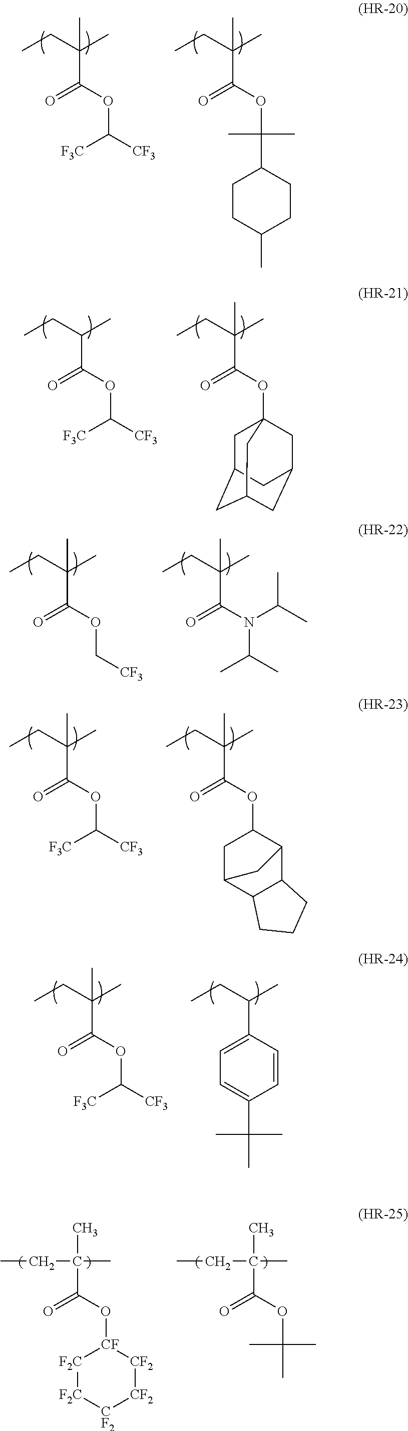

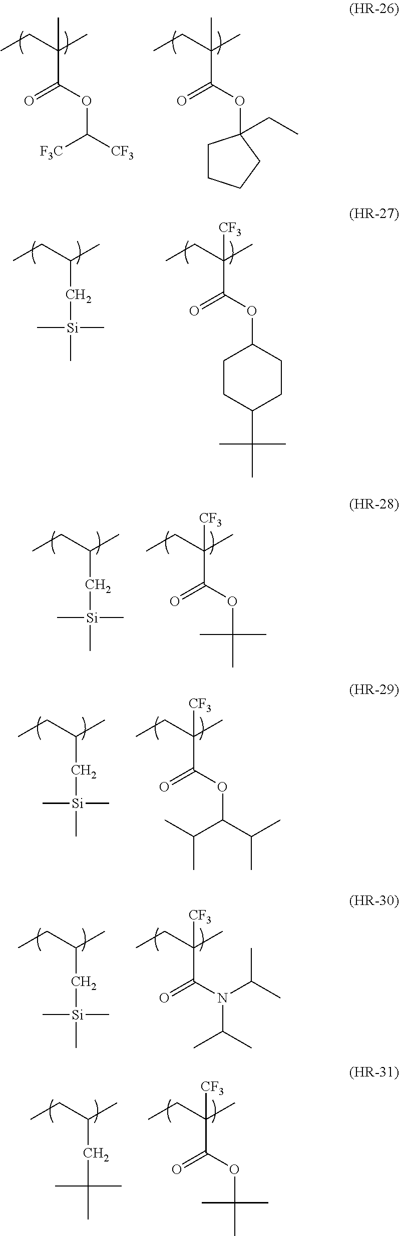

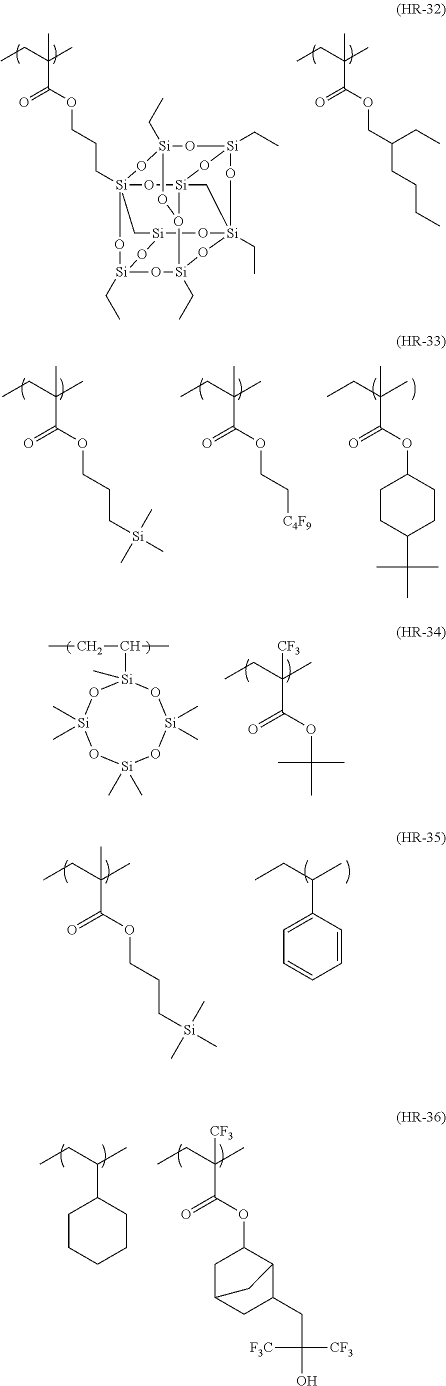

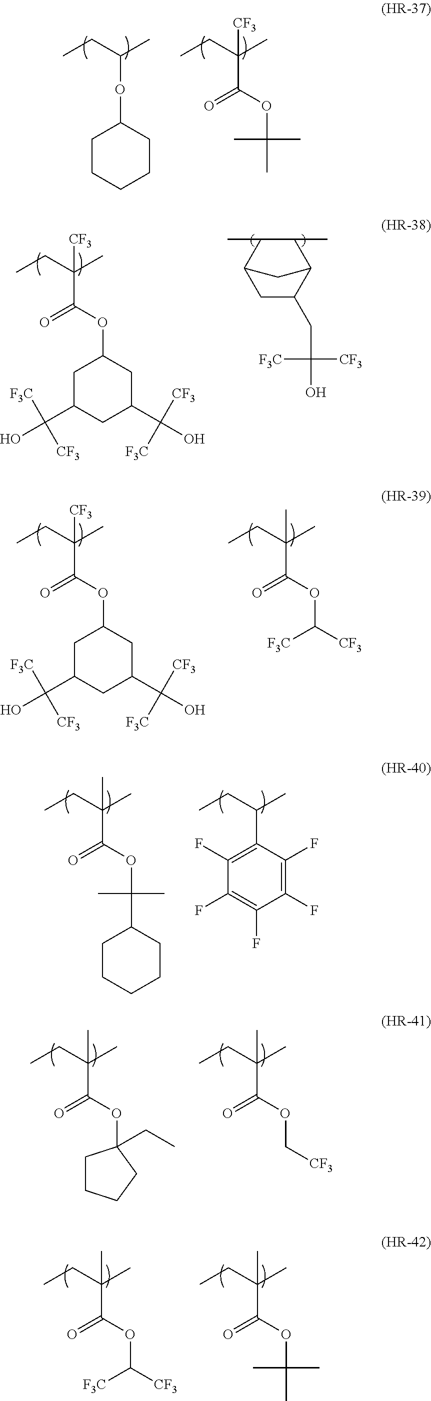

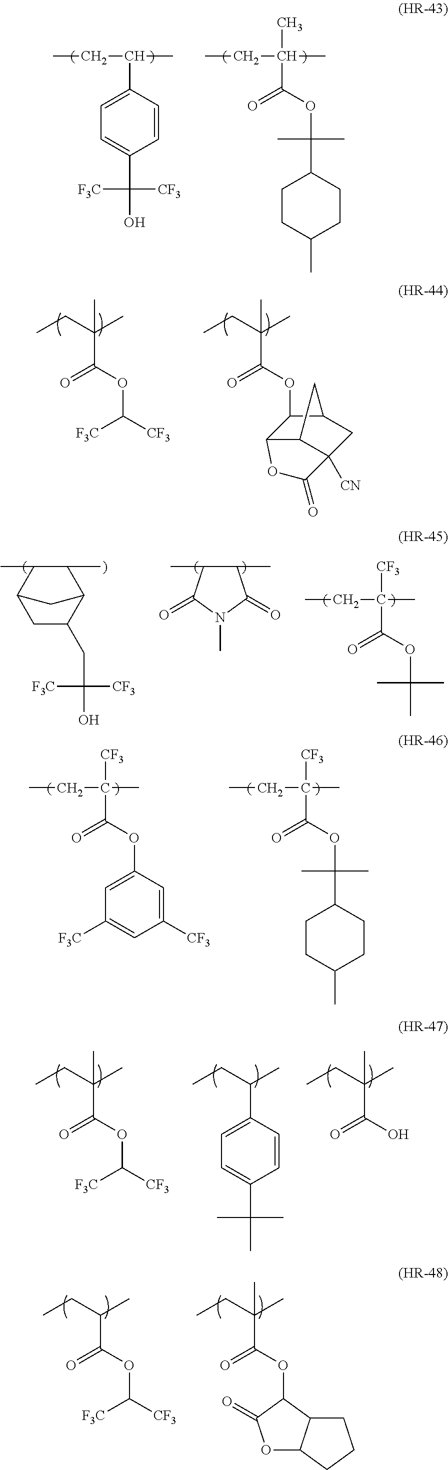

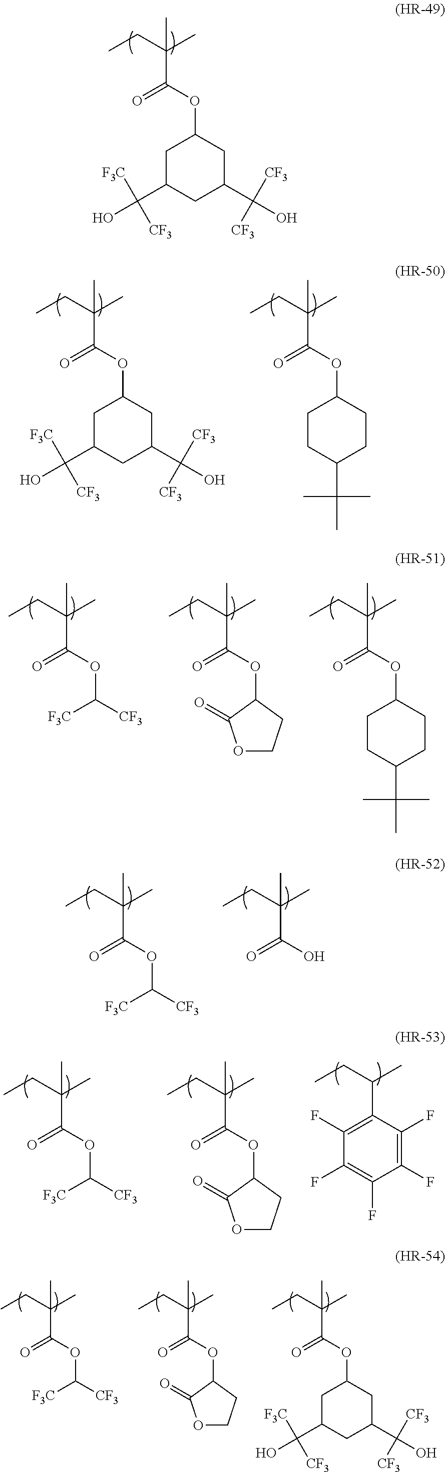

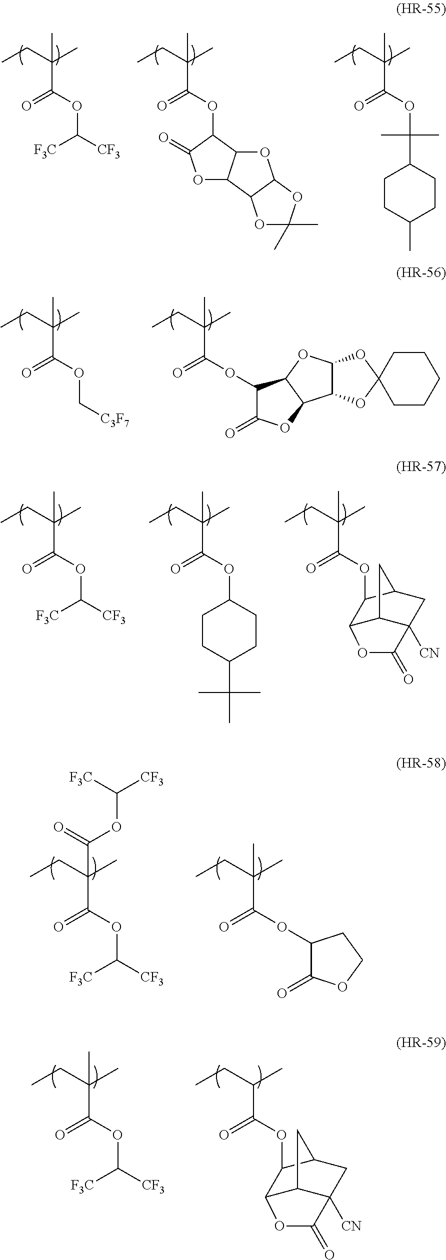

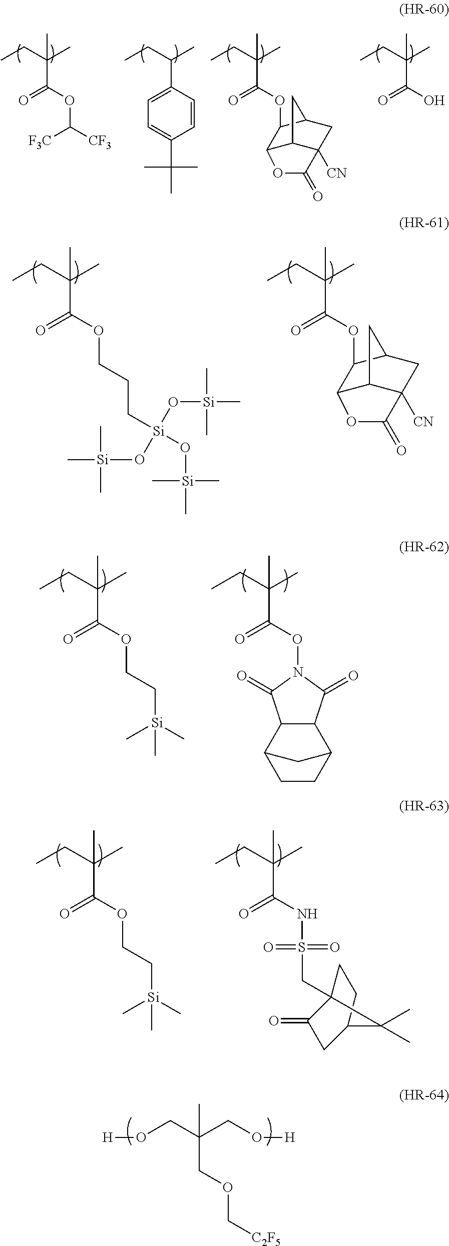

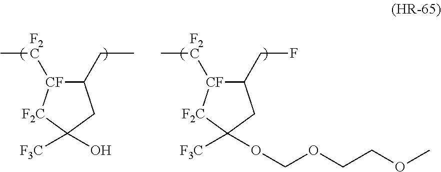

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

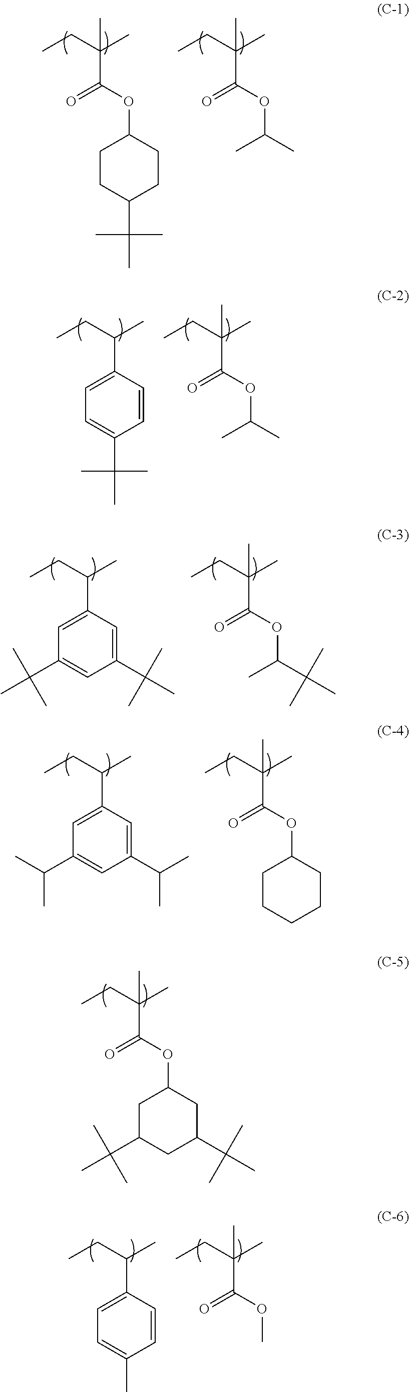

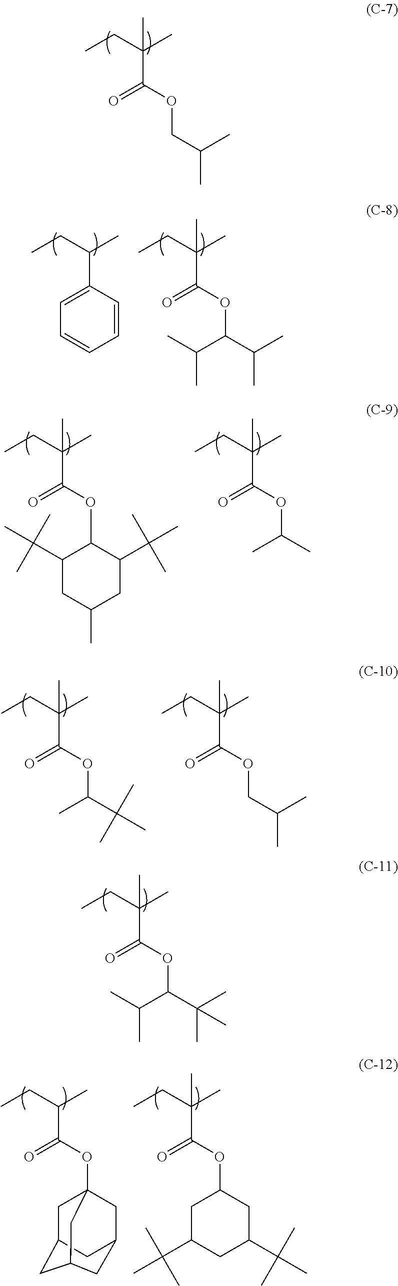

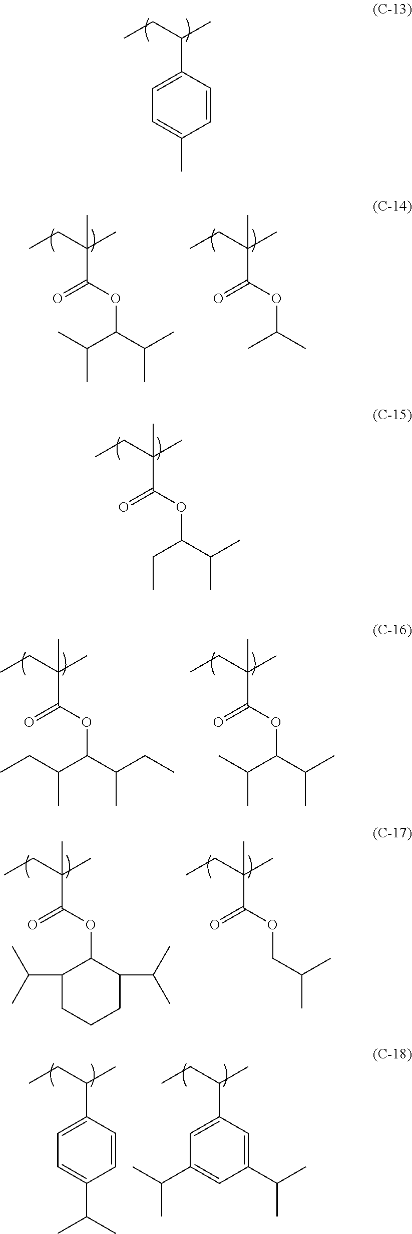

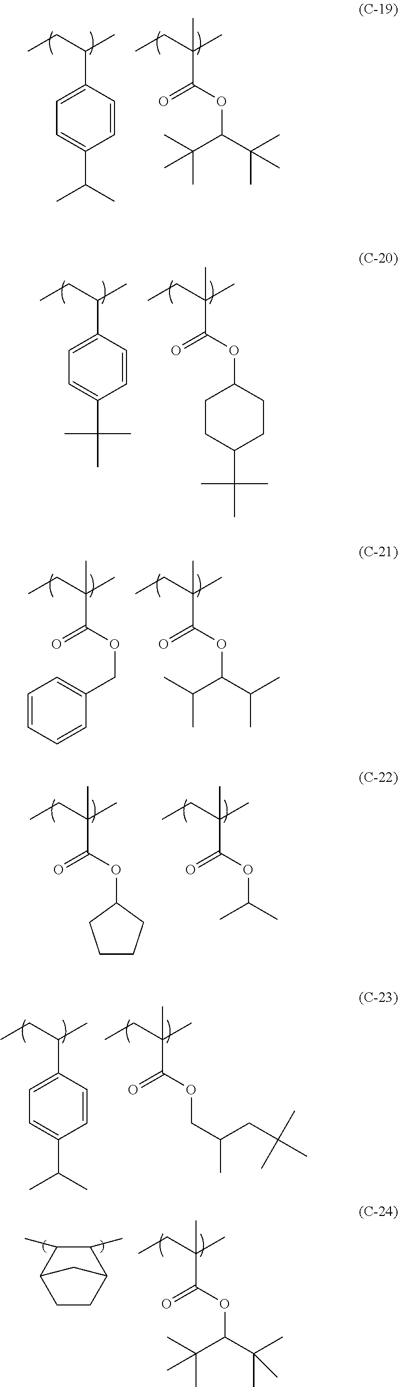

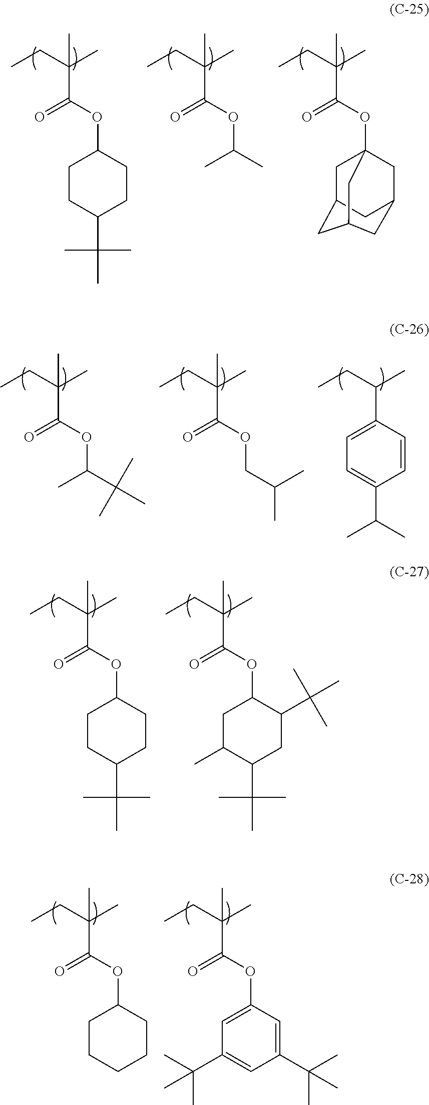

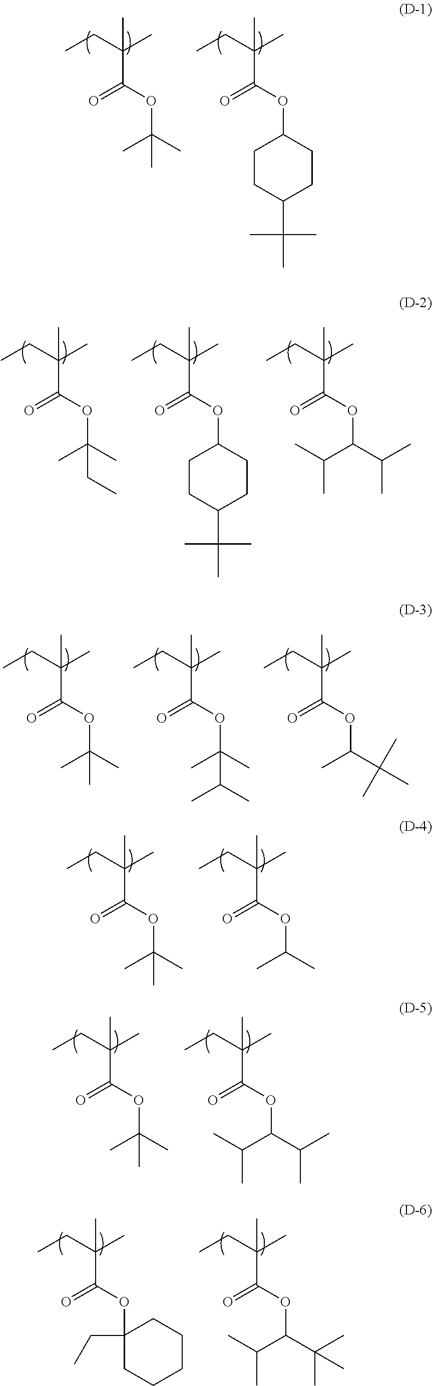

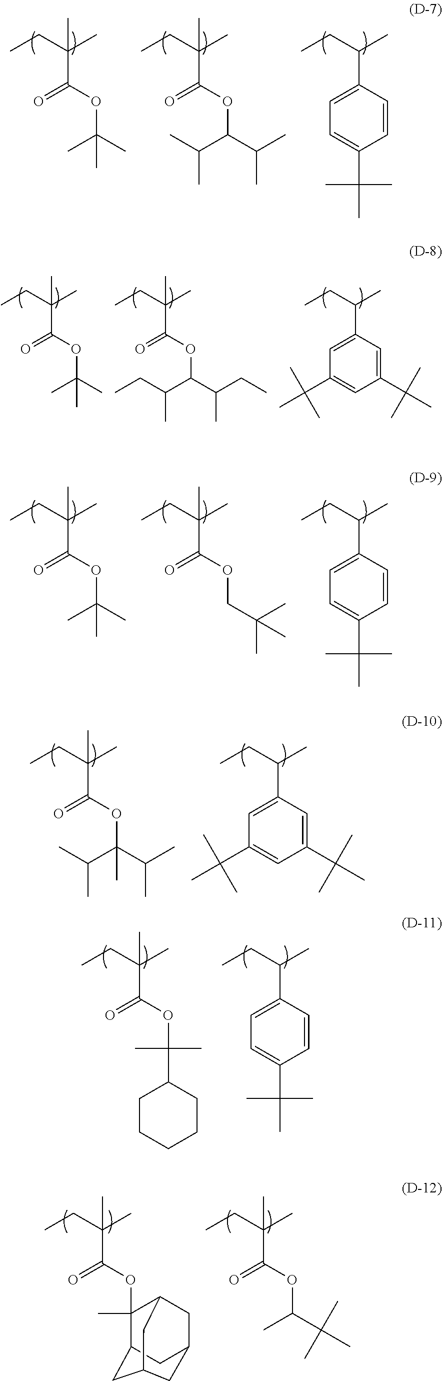

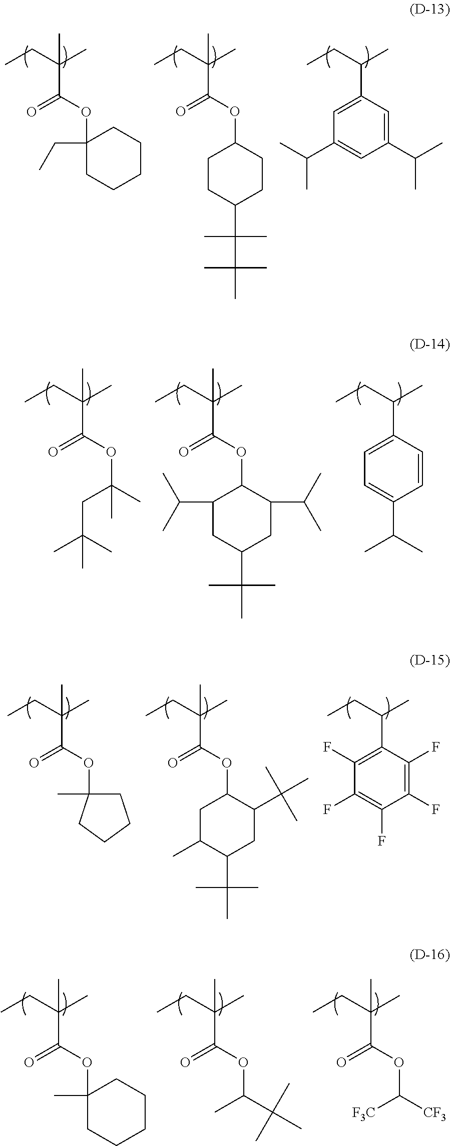

TABLE 2

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 3

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5] Basic Compound

The composition of the present invention preferably contains a basic compound.

(1) In one aspect, the composition of the present invention preferably contains a basic compound or an ammonium salt compound (also referred to below as “compound (N)”) where the basicity decreases when irradiated with actinic rays or radiation as a basic compound.

The compound (N) is preferably a compound (N-1) which has a basic functional group or an ammonium group and a group which generates an acid functional group when irradiated with actinic rays or radiation. That is, the compound (N) is preferably a basic compound which has a basic functional group and a group which generates an acid functional group when irradiated with actinic rays or radiation, or an ammonium salt compound which has an ammonium group and a group which generates an acid functional group when irradiated with actinic rays or radiation.

Specific examples of the compound (N) include the following. In addition, other than the compounds given below, it is also possible to preferably use, for example, the compounds in (A-1) to (A-44) described in US2010/0233629A or the compounds (A-1) to (A-23) described in US2012/0156617A as the compound (N) in the present invention.

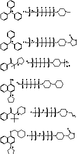

It is possible to synthesize the compound on the basis of the synthesis examples described in JP2006-330098A and the like.

The molecular weight of the compound (N) is preferably 500 to 1000.

The composition of the present invention may or may not contain the compound (N); however, when contained, the content ratio of the compound (N) is preferably 0.1 mass % to 20 mass % on the basis of the solid content of the composition and more preferably 0.1 mass % to 10 mass %.

(2) In another aspect, the composition of the present invention may contain a basic compound (N′) which is different from the compound (N) as the basic compound in order to reduce changes in performance over time from the exposure to the heating.

Preferable examples of the basic compound (N′) include compounds which have structures represented by the following Formulas (A′) to (E′).

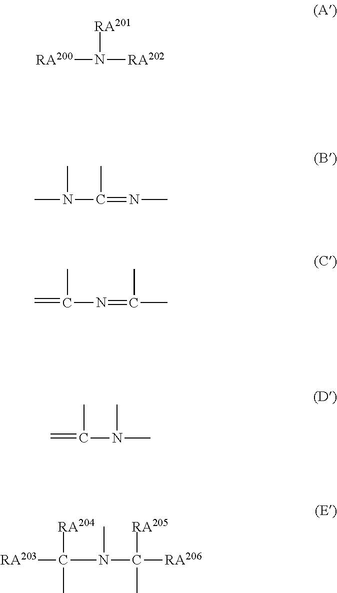

In General Formulas (A′) and (E′), RA²⁰⁰, RA²⁰¹ and RA²⁰² may be the same as or may be different from each other and represent a hydrogen atom, an alkyl group (preferably with 1 to 20 carbon atoms), a cycloalkyl group (preferably with 3 to 20 carbon atoms), or an aryl group (with 6 to 20 carbon atoms). Here, RA²⁰¹ and RA²⁰² may form a ring by bonding with each other. RA²⁰³, RA²⁰⁴, RA²⁰⁵, and RA²⁰⁶ may be the same as or may be different from each other and represent an alkyl group (preferably with 1 to 20 carbon atoms).

The alkyl group described above may have a substituent and the alkyl group which has a substituent is preferably an aminoalkyl group with 1 to 20 carbon atoms, a hydroxylalkyl group with 1 to 20 carbon atoms, or a cyanoalkyl group with 1 to 20 carbon atoms.

The alkyl group in General Formulas (A′) and (E′) is more preferably unsubstituted.

Preferable specific examples of the basic compound (N′) include guanidine, aminopyrrolidine, pyrazole, pyrazoline, piperazine, aminomorpholine, aminoalkyl morpholine, piperidine, and the like, and more preferable specific examples include compounds which have an imidazole structure, a diazabicyclo structure, an onium hydroxide structure, an onium carboxylate structure, a trialkylamine structure, an aniline structure, or a pyridine structure, an alkylamine derivative which has a hydroxyl group and/or an ether bond, an aniline derivative which has a hydroxyl group and/or an ether bond, and the like.

Examples of the compound which has an imidazole structure include imidazole, 2,4,5-triphenyl imidazole, benzimidazole, and the like. Examples of the compound which has a diazabicyclo structure include 1,4-diazabicyclo[2,2,2]octane, 1,5-diazabicyclo[4,3,0]nona-5-ene, 1,8-diazabicyclo[5,4,0]undeca-7-ene, and the like. Examples of the compound which has an onium hydroxide structure include triarylsulfonium hydroxide, phenacyl sulfonium hydroxide, sulfonium hydroxide which has a 2-oxoalkyl group, specifically, triphenyl sulfonium hydroxide, tris(t-butylphenyl) sulfonium hydroxide, bis(t-butylphenyl) iodonium hydroxide, phenacyl thiophenium hydroxide, 2-oxopropyl thiophenium hydroxide, and the like. The compound which has an onium carboxylate structure is a compound where an anion section of a compound which has an onium hydroxide structure is a carboxylate and examples thereof include acetate, adamantane-1-carboxylate, perfluoroalkyl carboxylate, and the like. Examples of the compound which has a trialkylamine structure include tri(n-butyl)amine, tri(n-octyl)amine, and the like. Examples of the compound which has an aniline structure include 2,6-diisopropyl aniline, N,N-dimethyl aniline, N,N-dibutyl aniline, N,N-dihexyl aniline, and the like. Examples of the alkylamine derivative which has a hydroxyl group and/or an ether bond include ethanol amine, diethanol amine, triethanol amine, tris(methoxyethoxyethyl)amine, and the like. Examples of an aniline derivative which has a hydroxyl group and/or an ether bond include N,N-bis(hydroxyethyl)aniline, and the like.

Examples of preferable basic compounds further include an amine compound which has a phenoxy group, an ammonium salt compound which has a phenoxy group, an amine compound which has a sulfonic acid ester group, and an ammonium salt compound which has a sulfonic acid ester group. Specific examples thereof include the compounds (C1-1) to (C3-3) exemplified in [0066] in US2007/0224539A; however, the present invention is not limited thereto.

(3) In another aspect, the composition of the present invention may contain a nitrogen-containing organic compound which has a group which is desorbed due to the effect of an acid as one type of the basic compound. As examples of the compound, for example, specific examples of compounds will be given below.

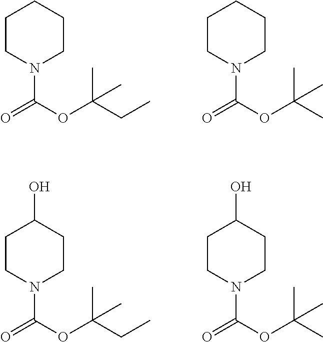

It is possible to synthesize the compounds described above on the basis of, for example, the method described in JP2009-199021A.

In addition, it is also possible to use a compound which has an amine oxide structure as the basic compound (N′). As specific examples of the compound, it is possible to use triethylamine pyridine N-oxide, tributylamine N-oxide, triethanolamine N-oxide, tris(methoxyethyl) amine N-oxide, tris(2-(methoxymethoxy)ethyl) amine=oxide, 2,2′,2″-nitrotriethyl propionate N-oxide, N-2-(2-methoxyethoxy) methoxyethyl morpholine N-oxide, and other amine oxide compounds exemplified in JP2008-102383A.

The molecular weight of the basic compound (N′) is preferably 250 to 2000 and more preferably 400 to 1000. From the viewpoint of further reduction of the LWR and local uniformity of pattern dimensions, the molecular weight of the basic compound is preferably 400 or more, more preferably 500 or more, and even more preferably 600 or more.

The basic compounds (N′) may be used together with the compound (N) and may be used individually or as two or more types together.

The chemical amplification resist composition in the present invention may or may not contain the basic compound (N′); however, when contained, the usage amount of the basic compound (N′) is normally 0.001 mass % to 10 mass % on the basis of the solid content of the chemical amplification resist composition and preferably 0.01 mass % to 5 mass %.

(4) In another aspect, the composition of the present invention may include an onium salt which is represented by General Formula (6A) or (6B) below as a basic compound. The onium salt is expected to control the diffusion of generated acid in a resist system in relation to the acid strength of a photoacid generator which is normally used in resist compositions.

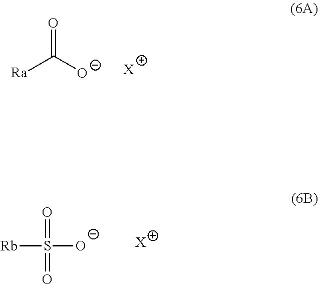

In General Formula (6A), Ra represents an organic group. However, organic groups where carbon atoms which are directly bonded with the carboxylic acid group in the formula are substituted with fluorine atoms are excluded.

X⁺ represents an onium cation.

In General Formula (6B), Rb represents an organic group. However, an organic group where carbon atoms which are directly bonded with the sulfonic acid group in the formula are substituted with fluorine atoms is excluded.

X⁺ represents an onium cation.

With regard to an organic group which is represented by Ra and Rb, atoms which are directly bonded with the carboxylic acid group or a sulfonic acid group in the formula are preferably carbon atoms. However, in this case, in order to make an acid relatively weaker than the acid which is generated from the photoacid generator described above, the carbon atoms which are directly bonded with a sulfonic acid group or a carboxylic acid group are not substituted with fluorine atoms.

Examples of the organic group which is represented by Ra and Rb include an alkyl group with 1 to 20 carbon atoms, a cycloalkyl group with 3 to 20 carbon atoms, an aryl group with 6 to 30 carbon atoms, an aralkyl group with 7 to 30 carbon atoms, a heterocyclic group with 3 to 30 carbon atoms, or the like. With regard to the groups, a part or all of the hydrogen atoms may be substituted.

Examples of a substituent which the alkyl group, the cycloalkyl group, the aryl group, the aralkyl group, and the heterocyclic group described above may have include a hydroxyl group, a halogen atom, an alkoxy group, a lactone group, an alkyl carbonyl group, and the like.

Examples of the onium cation which is represented by X⁺ in General Formulas (6A) and (6B) include a sulfonium cation, an ammonium cation, an iodonium cation, a phosphonium cation, a diazonium cation, and the like, and a sulfonium cation is more preferable among these.

The sulfonium cation is preferably, for example, an arylsulfonium cation which has at least one aryl group and more preferably a triarylsulfonium cation. The aryl group may have a substituent and the aryl group is preferably a phenyl group.

Preferable examples of the sulfonium cation and the iodonium cation also include the structures described in the compound (B).

Specific structures of the onium salt which is represented by General Formulas (6A) and (6B) will be shown below.

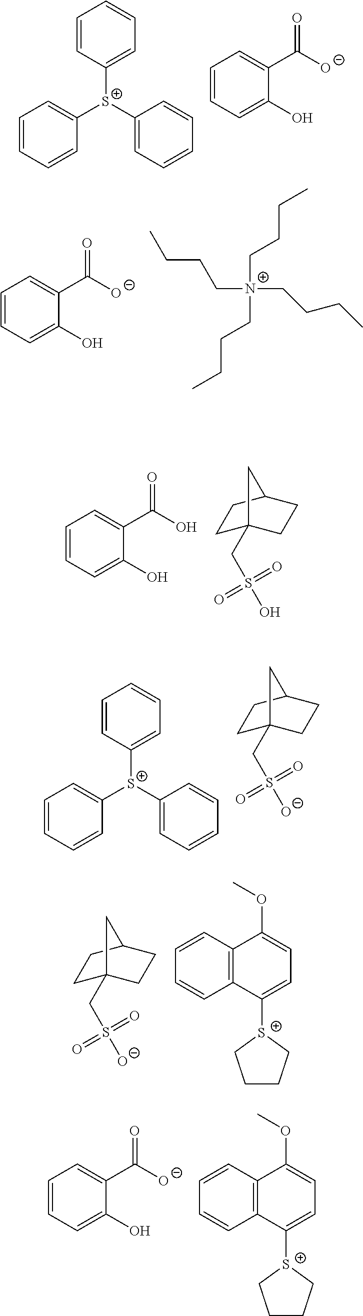

(5) In another aspect, the composition of the present invention may contain compounds (also referred to below as “betaine compounds”) which have both an onium salt structure and an acid anion structure in one molecule such as the compounds which is included in Formula (I) in JP2012-189977A, the compounds which are represented by Formula (I) in JP2013-6827A, the compounds which are represented by Formula (I) in JP2013-8020A, and the compounds which are represented by Formula (I) in JP 2012-252124A as a basic compound. Examples of the onium salt structure include sulfonium, iodonium, and ammonium structures and a sulfonium or iodonium salt structure is preferable. In addition, an acid anion structure is preferably sulfonic acid anion or carboxylic acid anion. Examples of the compounds include below.

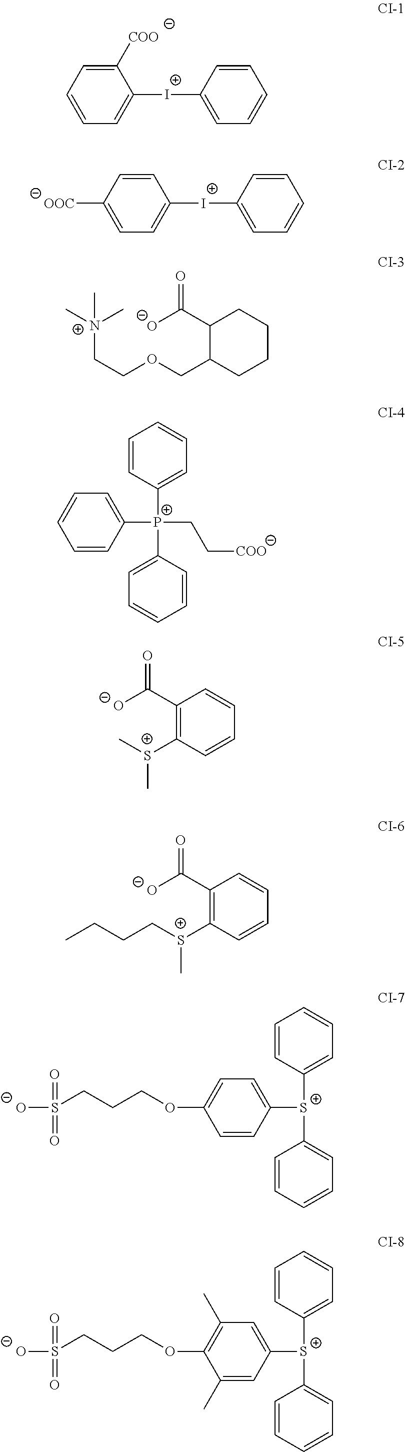

[6] Surfactant

The composition of the present invention may further contain a surfactant. In a case where the composition of the present invention contains a surfactant, it is preferable to contain either of a fluorine and/or silicon-based surfactant (a fluorine-based surfactant, a silicon-based surfactant, or a surfactant which has both fluorine atoms and silicon atoms) or two or more types thereof.

By the composition of the present invention containing a surfactant, it is possible to impart a resist pattern with adhesion and fewer developing defects with a favorable sensitivity and resolution while using an exposure light source of 250 nm or less, particularly 220 nm or less.

Examples of the fluorine-based and/or silicon-based surfactants include the surfactants described in [0276] in US2008/0248425A and are, for example, Eftop EF301 and EF303 (manufactured by Shin-Akita Kasei Co., Ltd.), Fluorad FC430, 431, and 4430 (manufactured by Sumitomo 3M Inc.), Megaface F171, F173, F176, F189, F113, F110, F177, F120, and R08 (manufactured by DIC Inc.), Surflon S-382, SC101, 102, 103, 104, 105, 106, and KH-20 (manufactured by Asahi Glass Co., Ltd.), Troyzol S-366 (manufactured by Troy Chemical Industries, Inc.), GF-300 and GF-150 (manufactured by Toagosei Co., Ltd.), SurfIon S-393 (manufactured by Seimi Chemical Co., Ltd.), Eftop EF121, EF122A, EF122B, RF122C, EF125M, EF135M, EF351, EF352, EF801, EF802, and EF601 (manufactured by Jemco Inc.), PF636, PF656, PF6320, and PF6520 (manufactured by OMNOVA Corp.), FTX-204G, 208G, 218G, 230G, 204D, 208D, 212D, 218D, and 222D (manufactured by Neos Co., Ltd.), and the like. In addition, it is also possible to use polysiloxane polymer KP-341 (manufactured by Shin-Etsu Chemical Co., Ltd.) as a silicon-based surfactant.

In addition, as a surfactant, other than the surfactants known in the art as described above, it is possible to use a surfactant which uses a polymer which has a fluoro aliphatic group which is derived from a fluoro aliphatic compound which is produced by a telomerization method (also referred to as a telomer method) or an oligomerization method (also referred to an oligomer method). It is possible to synthesize the fluoro aliphatic compound using the method described in JP2002-90991A.

Examples of surfactants which correspond to the described above include Megaface F178, F470, F473, F475, F476, and F472 (manufactured by DIC Inc.), a copolymer of acrylate (or methacrylate) which has a C₆F₁₃ group and (poly(oxyalkylene))acrylate (or methacrylate), a copolymer of acrylate (or methacrylate) which has a C₃F₇ group, (poly(oxyethylene))acrylate (or methacrylate), and (poly(oxypropylene))acrylate (or methacrylate), and the like.

In addition, in the present invention, it is also possible to use other surfactants than the fluorine-based and/or the silicon-based surfactants described in [0280] in US2008/0248425A.

The surfactants may be used individually or may also be used in various combinations.

In a case where the composition of the present invention contains a surfactant, the usage amount of the surfactant is preferably 0.0001 mass % to 2 mass % with respect to the total amount of the composition (excluding a solvent) and more preferably 0.0005 mass % to 1 mass %.

On the other hand, by setting the added amount of the surfactant to 10 ppm or less with respect to the total amount of the actinic ray sensitive or radiation sensitive resin composition (excluding a solvent), the surface uneven distribution characteristics of a hydrophobic resin are increased and, due to this, it is possible to make the resist film surface more hydrophobic and it is possible to improve the water conformance at the time of the liquid immersion exposure.

[7] Other Additives (G)

The composition of the present invention may contain carboxylic acid onium salt. Examples of the carboxylic acid onium salt include the carboxylic acid onium salts described in [0605] and [0606] in US2008/0187860A.

In a case where the composition of the present invention contains carboxylic acid onium salt, the content ratio is generally 0.1 mass % to 20 mass % with respect to the total solid content of the composition, preferably 0.5 mass % to 10 mass %, and more preferably 1 mass % to 7 mass %.

It is possible to further contain a compound which promotes the solubility with respect to a dye, a plasticizer, a photosensitizer, a light absorption agent, an alkali-soluble resin, a dissolution inhibitor, and a developer (for example, a phenol compound with a molecular weight of 1000 or less, an alicyclic or aliphatic compound which has a carboxyl group), and the like in the composition of the present invention as necessary.

From the viewpoint of improving the resolving power, the composition of the present invention is preferably used with a film thickness of 30 nm to 250 nm and more preferably used with a film thickness of 30 nm to 200 nm.

The concentration of solid contents of the composition of the present invention is normally 1.0 mass % to 10 mass %, preferably 2.0 mass % to 5.7 mass %, and more preferably 2.0 mass % to 5.3 mass %. By setting the concentration of solid contents to this range, it is possible to uniformly coat a resist solution on a substrate.

The concentration of solid contents is a weight percentage of the weight of other resist components excluding solvents with respect to the total weight of the chemical amplification resist composition.

The composition of the present invention is used by coating on a predetermined support body (a substrate) after dissolving the components described above in a predetermined organic solvent, preferably the mixed solvent, and carrying out filtration with a filter. The filter which is used for the filtration with a filter is preferably made of polytetrafluoroethylene, made of polyethylene, and made of nylon with a pore size of 0.1 μm or less, more preferably 0.05 μm or less, and even more preferably 0.03 μm or less. In the filter filtration, for example, cyclic filtration may be performed or filtration may be performed by connecting a plurality of types of filters in series or in parallel as JP2002-62667A. In addition, the composition may be filtered a plurality of times. Furthermore, a degassing process or the like may be performed with respect to the composition before or after the filter filtration.

### EXAMPLES

Detailed description will be given below of the present invention using examples; however, the content of the present invention is not limited thereby.

<Resist Preparation>

An actinic ray sensitive or radiation sensitive resin composition (a resist composition) was prepared by dissolving 3.5 mass % solid content of the components shown in the table below in the solvent shown in the same table and filtering each thereof using a polyethylene filter which has a pore size of 0.03 μm.

TABLE 4

| | | Acid | | Hydro- | | |
|---|---|---|---|---|---|---|
| | Resin | generating | Basic | phobic | | Solvent |
| | (A) | agent (B) | compound | resin (D) | Surfactant | (mass |
| Composition | (g) | (g) | (g) | (g) | (g) | ratio) |
| 1 | A-1 | PAG-1 | C-3 | D-3 | W-1 | SG-1 |
| | (10) | (0.80) | (0.17) | (0.28) | (0.003) | |
| 2 | A-2 | PAG-2 | C-3 | D-1 | W-2 | SG-1/SG-2 |
| | (10) | (0.85) | (0.14) | (0.4) | (0.003) | (80/20) |
| 3 | A-3 | PAG-3 | C-2/C-4 | D-2 | W-1 | SG-1/SG-2 |
| | (10) | (0.88) | (0.06/0.25) | (0.2) | (0.003) | (95/5) |
| 4 | A-1 | PAG-1 | C-1 | D-3 | W-1 | SG-1 |
| | (10) | (0.80) | (0.14) | (0.28) | (0.003) | |
| 5 | A-2 | PAG-3 | C-2/C-5 | D-1 | W-2 | SG-1/SG-2 |
| | (10) | (0.88) | (0.06/0.14) | (0.4) | (0.003) | (80/20) |

<Resin (A)>

A-1 to A-3 shown below were used as the resin (A). Here, the resins were synthesized and purified by radical polymerization known in the art.

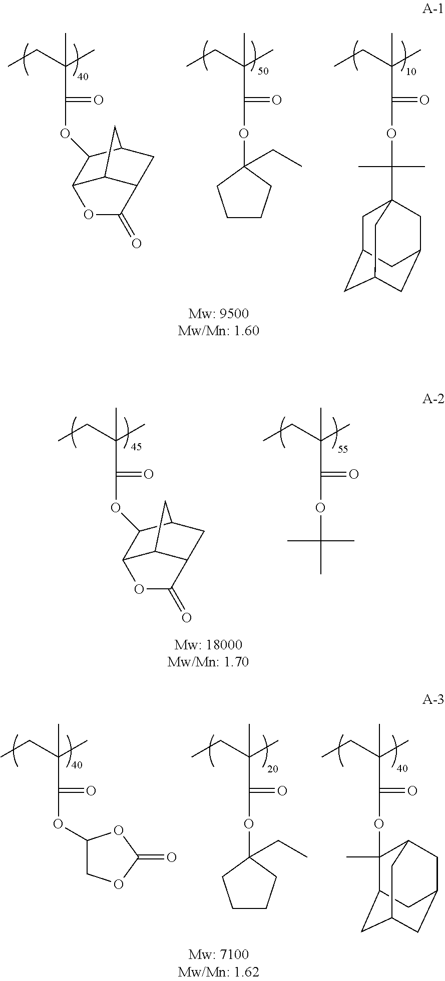

<Acid Generating Agent (B)>

PAG-1 to PAG-3 shown below were used as the acid generating agent (B).

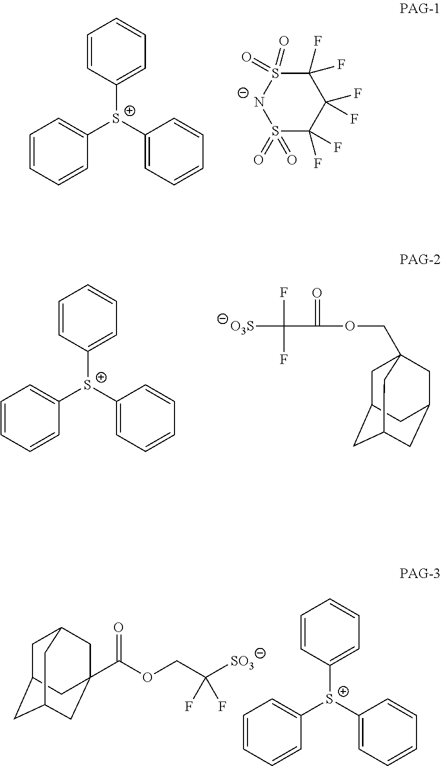

<Hydrophobic Resin (D)>

D-1 to D-3 shown below were used as the hydrophobic resin (D).

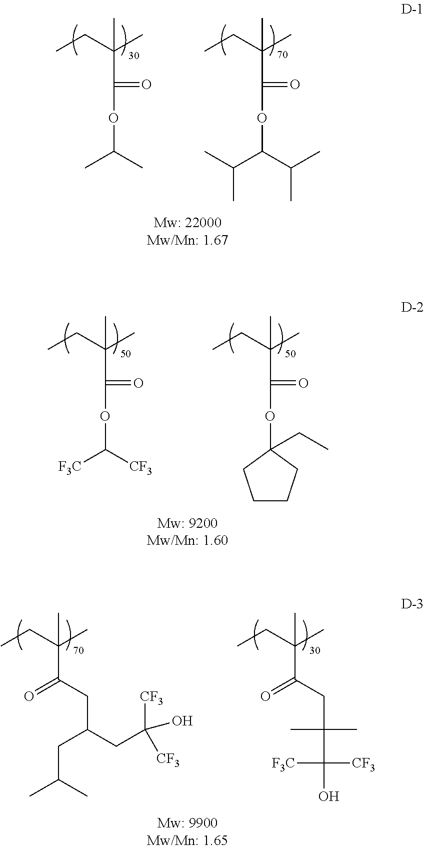

<Basic Compound>

Compounds C-1 to C-5 shown below were used as a basic compound.

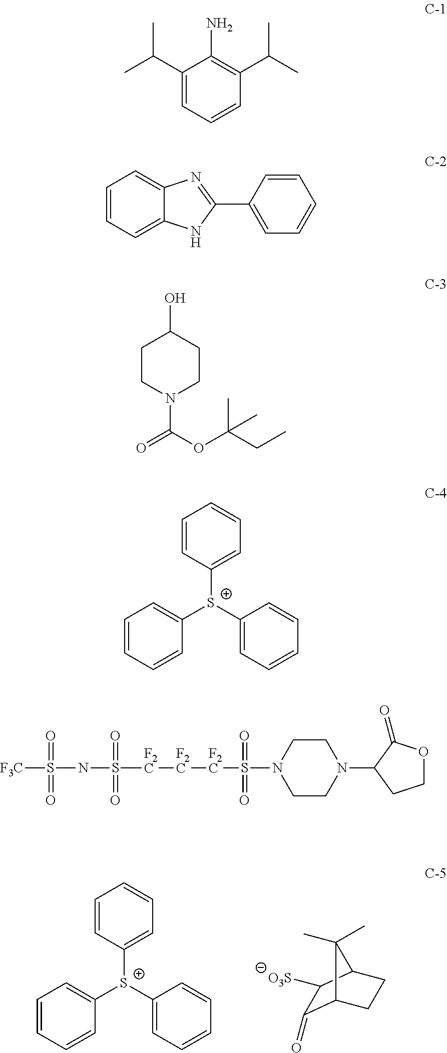

<Surfactant>

W-1 and W-2 shown below were used as a surfactant.

W-1: Megaface F176 (manufactured by DIC Inc.; fluorine-based)

W-2: PolyFox PF-6320 (manufactured by OMNOVA Solutions Inc.; fluorine-based)

<Solvent>

SG-1 and SG-2 shown below were used as a solvent.

SG-1: Propylene glycol monomethyl ether acetate

SG-2: Cyclohexanone

<Creating Resist Film>

Using a coater/developer, an organic antireflection film ARC29SR (manufactured by Nissan Chemical Industries, Ltd.) was coated on a silicon wafer of 300 mm, baking was performed at 205° C. for 60 seconds, and an antireflection film with a film thickness of 95 nm was formed. An actinic ray sensitive or radiation sensitive resin composition was coated thereon, baking (PB: Prebake) was performed at 100° C. for 60 seconds, and a resist film with a film thickness of 85 nm was formed.

<Cleaning>

In each of the examples, one of the two types of cleaning methods shown below was used as the cleaning before the exposing and/or the cleaning after the exposure (Table 5).

Cleaning (1)

After discharging a pure water rinse at a flow rate of 25 ml/second for 9 seconds onto the obtained wafer while rotating the obtained wafer at a rotation speed of 10 rpm in a cleaning unit of the coater/developer, a paddle state was maintained at a rotation speed of 30 rpm for 6 seconds. Subsequently, while rotating the wafer at a rotation speed of 30 rpm, N₂ gas was blown to the wafer center for 5 seconds. Subsequently, spin drying was performed at a rotation speed of 3000 rpm for 15 seconds.

Cleaning (2)

While rotating the obtained wafer at a rotation speed of 2000 rpm in the cleaning unit of the coater/developer, a pure water rinse was ejected onto the wafer center at a flow rate of 5 ml/second for 1 second. Subsequently, while discharging a pure water rinse at a flow rate of 5 ml/second for 9 seconds with the wafer rotation speed kept at 200 rpm, a pure water rinse nozzle was moved from the wafer center in the direction of the periphery. After that, spin drying was performed at a rotation speed of 3000 rpm for 15 seconds.

Pure water was used.

<Liquid Immersion Exposure>

Pattern exposure was performed on the obtained wafer using an ArF excimer laser liquid immersion scanner (manufactured by ASML Corp., XT1700i, NA1.20, Dipole-X, outer sigma 0.981, inner sigma 0.895, Y deflection) via a half-tone mask with a pitch of 90 nm and a mask width of 45 nm. Ultra-pure water was used as the immersion liquid.

<PEB and Developing>

After that, heating was carried out at 105° C. for 60 seconds. Subsequently, the developing was carried out by paddling in butyl acetate for 30 seconds and, when rinsing, the rinsing was carried out using 4-methyl-2-pentanol for 30 seconds, and a 1:1 line and space pattern of 45 nm was obtained.

[Residual Water Bridge Defect Evaluation]

In the measurement of the line and space pattern which was resolved with the optimum exposure amount when resolving a line and space pattern with a line width of 45 nm, after performing a pattern defect examination with a pixel size of 120 nm and Horizontal polarization illumination and a Cell to Cell mode using UVision 3+ (manufactured by Applied Materials Inc.), developing defects were observed in a region with a width of 35 mm at the outermost periphery of a wafer of 300 mm using SEMVision G4 (manufactured by Applied Materials Inc.). Evaluation was carried out by selecting and extracting residual water bridge defects from the forms of the defects on the wafer and counting the number thereof. The evaluation results are shown in the table below.

TABLE 5

| | | | | | Residual |
|---|---|---|---|---|---|
| | | | | | water |
| | | Cleaning | Cleaning | Rinsing | bridge |
| | Com- | before | after | after | defects |
| | position | exposing | exposing | developing | (No.) |
| Example 1 | 1 | (1) | (1) | Absent | 1 |
| Example 2 | 1 | (2) | (2) | Absent | 2 |
| Example 3 | 1 | Absent | (1) | Absent | 4 |
| Example 4 | 1 | Absent | (2) | Absent | 3 |
| Example 5 | 2 | (1) | (1) | Present | 2 |
| Example 6 | 2 | (2) | (2) | Present | 3 |
| Example 7 | 2 | Absent | (1) | Present | 5 |
| Example 8 | 2 | Absent | (2) | Present | 5 |
| Example 9 | 3 | (1) | (1) | Present | 1 |
| Example 10 | 3 | (2) | (2) | Present | 3 |
| Example 11 | 3 | Absent | (1) | Present | 4 |
| Example 12 | 3 | Absent | (2) | Present | 5 |
| Example 13 | 4 | (1) | (1) | Absent | 2 |
| Example 14 | 4 | (2) | (2) | Absent | 3 |
| Example 15 | 4 | Absent | (1) | Absent | 4 |
| Example 16 | 4 | Absent | (2) | Absent | 4 |
| Example 17 | 5 | (1) | (1) | Present | 1 |
| Example 18 | 5 | (2) | (2) | Present | 2 |
| Example 19 | 5 | Absent | (1) | Present | 5 |
| Example 20 | 5 | Absent | (2) | Present | 4 |
| Comparative | 1 | Absent | Absent | Absent | 28 |
| Example 1 | | | | | |
| Comparative | 2 | Absent | Absent | Present | 37 |
| Example 2 | | | | | |
| Comparative | 3 | Absent | Absent | Present | 34 |
| Example 3 | | | | | |
| Comparative | 4 | Absent | Absent | Absent | 29 |
| Example 4 | | | | | |
| Comparative | 5 | Absent | Absent | Present | 33 |
| Example 5 | | | | | |

As is clear from the results shown in the table above, it is understood that the generation of residual water bridge defects is suppressed by including the cleaning process. In addition, it is understood that the effect of suppressing residual water bridge defects is increased by including both the cleaning process before the exposure and the cleaning process after the exposure.

In addition, when the evaluation was performed in the same manner as Example 1 apart from adding 2 mass % of tri-n-octylamine to the butyl acetate of the developer, it was confirmed that defect performance was also favorable in this evaluation.

In addition, when a developing process was further performed using 2.38 mass % of an aqueous solution of tetramethyl ammonium hydroxide after performing pattern forming in the same manner apart from forming a trench pattern with line:space=3:1 by changing a mask pattern in Example 1, it was possible to obtain a pattern where only regions with an intermediate exposure amount remained.

What is claimed is:

1. A pattern formation method comprising, in this order, the processes of:
forming an actinic ray sensitive or radiation sensitive film by coating a substrate with an actinic ray sensitive or radiation sensitive resin composition, the actinic ray sensitive or radiation sensitive resin composition containing a resin where the degree of solubility with respect to a developer which includes one or more types of organic solvents decreases due to an effect of an acid, a compound which generates an acid by irradiation with actinic rays or radiation, and a solvent;
exposing the actinic ray sensitive or radiation sensitive film via an immersion liquid;
heating the actinic ray sensitive or radiation sensitive film; and
developing the actinic ray sensitive or radiation sensitive film using a developer including an organic solvent,
wherein the method further comprises a process of cleaning the actinic ray sensitive or radiation sensitive film after the film forming process and before the exposing process and/or after the exposing process and before the heating process.

2. The pattern formation method according to claim 1,
wherein the method comprises the cleaning process after the exposing process and before the heating process, or both after the film forming process and before the exposing process and after the exposing process and before the heating process.

3. The pattern formation method according to claim 1,
wherein the cleaning process includes cleaning the actinic ray sensitive or radiation sensitive film using pure water.

4. The pattern formation method according to claim 3,
wherein the cleaning process includes removing the pure water from the actinic ray sensitive or radiation sensitive film after cleaning using pure water.

5. The pattern formation method according to claim 4,
wherein the removing the pure water is performed by inert gas blowing and/or spin drying.

6. The pattern formation method according to claim 1,
wherein the actinic ray sensitive or radiation sensitive resin composition further includes a hydrophobic resin.

7. The pattern formation method according to claim 1,
wherein a content ratio of the organic solvent in the developer is 90 mass % to 100 mass % with respect to a total amount of the developer.

8. An electronic-device manufacturing method comprising the pattern formation method according to claim 1.

9. An electronic device which is manufactured by the electronic-device manufacturing method according to claim 8.
